(19) United States
(12) Patent Application Publication
(10) Pub. No.: US 2009/0056802 A1
(43) Pub. Date: Mar. 5, 2009

(54) Practical method and means for mechanosynthesis and assembly of precise nanostructures and materials including diamond, programmable systems for performing same; devices and systems produced thereby, and applications thereof

(76) Inventor: Eli Michael Rabani, Woodland Hills, CA (US)

Correspondence Address: ELI RABANI, 20919 ABALAR ST., WOODLAND HILLS, CA, 91364-4502, US

(21) Appl. No.: 12/070,489

(22) Filed: Feb. 18, 2008

Related U.S. Application Data
(60) Provisional application No. 60/901,966, filed on Feb. 16, 2007.

(51) Int. Cl. H01L 31/04; H01L 31/00

(52) U.S. Cl. 136/256; 700/95; 290/55

(57) ABSTRACT

The present invention features compositions for mechanosynthetic tool molecules useful as mechanosynthetic tools and improving over those proposed heretofore, novel uses of extant materials as mechanosynthetic tools, novel methods for improving the design of mechanosynthetic tools, methods for attachment of mechanosynthetic tool molecules to structural support members, methods for mechanosynthesis of precise nanostructures, novel uses of extant materials as starting seeds for mechanosynthetic products, novel modifications of nanostructures and the formation of patterns thereof, and novel uses of modifications of nanostructures as electrically conducting nanowires useful in electronic devices, photovoltaic devices and communications devices. Related electromechanosynthetic deposition of a metal using similar methods and means are likewise disclosed. Methods and means are provided for the fabrication of devices for performing the mechanosyntheses of the present invention including systems themselves capable of the self- or allo-replication of such systems, and also of device growth or expansion via autofabrication and autoassembly. Additionally, the foregoing methods are applied in the fabrication and assembly of novel actuator devices, nanoelectromechanical digital logic devices, analyte detection devices including devices for performing biomolecular and chemical assays, including detection of specific polynucleotides, and fluidic devices. Combinations of the foregoing enable the production of novel materials processing devices and systems disclosed as aspects of the present invention, including materials processing systems useful in processing environmental pollutants or raw materials, particularly also such devices which either themselves are or are produced by self- or allo-replicated systems.

This application claims benefit of provisional patent application Ser. No. 60/901,966, filed 2007 Feb. 18 by the present inventor.

### FIELD OF THE INVENTION

This invention relates to the fields of nanotechnology, self-replicating systems, chemistry, biochemistry, information processing and electronics, electromechanical devices, solar energy, wind energy, materials processing, fabrication, assembly and robotics.

### BACKGROUND OF THE INVENTION

Despite growing interest in the mechanosynthesis of diamond, diamondoid materials and nanostructures, and attention to theoretical questions as to the possibility thereof, practical methods for the positional mechanosynthesis of diamondoid nanostructures remain elusive.

A particular barrier to the development of the field of advanced nanoscale mechanosynthesis is that innovations in multiple areas are required, but in advance of these innovations it is not obvious what the final result will look like, nor even which area is most critical to achieving the final goal of precise and efficient positional mechanosynthesis of nanostructures, and many observers question whether or not this goal will ever be feasible. The present invention provides these innovations, circumventing issues associated with more established notions of what mechanosynthetic tools would look like, how difficult it would have to be to produce them, and what kinds of system topologies are likely to be necessary. Because scanning probe microscopes are the only existing instruments that perform motions with about the required accuracy, there is a widespread opinion that early mechanosynthetic fabrication devices (popularly but imprecisely termed “assemblers” or “nanoassemblers”) would have similar topologies. For example, [Pen06] and earlier work by these and associated workers repeatedly emphasizes the aspect ratio of supporting structures on which carbon dimer insertion tools are to be apically situated, in direct but misplaced analogy to SPMs. Such structures, as they conceive their optimal forms, appear to be products of advanced mechanosynthesis, which at least prior to the present invention remains hypothetical. Aspect ratios may be important for cases where a C-dimer is to be inserted in a well or valley type structure or the like, but a great many useful structures would not necessitate this for their fabrication

Other heretofore proposed nanoassembler types involve the use of robot-arms or similar manipulators to manipulate building blocks or parts, but as realized heretofore either the “robot arms” are so simplified as to not be useful in many applications, or are so complex to fabricate using current technology as to pose significant challenge, or depend for their use on building blocks which themselves are either prohibitively complicated or are not generally useful (due to their properties or lack of ready availability) for wide scale application; self-replicative fabrication of similar nanoassemblers of this class has, with only one exception [Mos01], resorted to special cases which essentially defer the complexity of the problem to complexity of building blocks. (For example the special case of using MEMs devices for assembling micromachined parts into similarly capabable MEMs devices neither eliminates the need for a micromachining facility nor introduces any new capability not already posessed by the micromachining facility given that this facility fabricated the first such system—the facility remains the limiting factor or bottleneck for supplying parts, and could as easily fabricate the final system in similar quantity, speed and cost as the parts not assembled into final working systems could be assembled by like systems. However, the notable accomplishment of this case is the demonstration of a “toy example” of machine self-replication to finally falsify the doubts of those who categorically rejected the possibility of non-biological self-replication of complex systems. To put this rather differently, one only need ask the question, “would you ever, or even could you, build a bridge or a building or a car using this?”)

The challenges facing the development of advanced mechanosynthetic nanotechnology may be circumscribed as the heretofore unknown or incomplete concrete answers to the heretofore mainly unanswered big question, “How can we get started in any direct way?” in forms useful to experimental scientists or technologists.

Theoretical work has been done on various proposed molecular tool for carbon dimer (C2) addition or insertion reactions, but in most cases the molecules proposed for use as tools would pose formidable or daunting synthetic challenges for conventional chemical techniques.

Disclosed theoretical work includes various analyses done by K. E. Drexler [Dre92] [All05], R. C. Merkle [Mer97][Mer03], R. A. Freitas [Fre04][Fre04b][Man04][Pen04] and others, focusing on tools comprising six membered rings which comprise at least four carbon atoms with carbon dimer reactant fragments bridging opposite atoms (1,4 positions.) With only one exception (DCB-As in [Mer03] which was mentioned only in passing, in connection with tool-aspect ratios,) all of these feature atoms from group 14 of the periodic table at the 1,4 positions. Only one heterobinuclear tool, still only comprising group 14 atoms, is only depicted once in passing (DCB6SiGe in FIG. 4 of [Mer03].)

Among the above, excluding [All05], all of the DCB tools analyzed in detail comprise an iceane core (i.e. a hexagonal diamond structure such as of lonsdalite) which means that two distinct carbon phases would need to be synthesizeable therewith if the goal of self-replication in the strict sense was desired. Note that [Man04] finds that an added carbon dimer has a greater probability of being retained by the DCB tool than the bare (dehydrogenated) C(110) surface according to their calculations. Some of the analyses of the DCB-type tools were dynamics done at high levels of theory and should be regarded as both demanding and rigorous, however some questions arise regarding suitability of approximations made (which may seem reasonable in the context of the high computational costs of these methods but in the context of my own observations based on calculations mainly at semi-empirical theory levels might not address the issue of stress-induced product rearrangement.) In particular, the most refined and elaborate analyses reported in [Pen06] of the most effective DCB tool investigated (DCB6Ge) take the measure of retracting the DCB deposition tools immediately as a transition geometry for carbon dimer deposition is reached (“[f]rom this moment onward we pulled the tool upward,”) despite the fact that no method nor means is provided for directly detecting this condition in a real physical implementation nor for definitely accomplishing the corresponding controlled motions on the relevant sub-ps timescale, nor is there an obviously effective means for accomplishing this. Recourse to this strategy is apparently adopted by these workers to avoid the formation of partial dimer addition products where one carbon dimer atom is bonded to a target carbon on the C(110) surface while another is bound the a tool heteroatom (i.e. Si, Ge or Sn); note that within the present invention, methods are provided for remedying this condition to obtain the desired addition product from analogous intermediates. Because internuclear distances are only provided for certain transition states and not provided for all of the various configurations of interest for this question, it is not possible to directly compare these results with those presented below, but a few comments are possible. Because carbon dimers, whether bound to a tool or to a diamond surface most closely resemble alkynes there is substantial strain both in the loaded tools discussed here and in the formation of the desired reaction products. This strain is in fact partly exploited in various tool designs of interest. There is therefore a natural tendency to “switch-blade” to a linear conformation whenever the minimum energy structure is disturbed. Factors favoring sp2-like electronic hybridization of the carbon atoms of the dimer would favor formation of the desired product. Instantaneous retraction of a tool from a favorable transition geometry may accomplish precisely this in quantum chemistry calculations, but in a non-physical way. Concerning use of this family of iceane-core tools, [Fre04b] proposes growing a diamond handle by conventional CVD on the isolated molecule bound “tip-down” to a CVD-inert surface, which would then require pick-and-place type operations and nanomaniputators or nanogrippers to assemble or use these. A further comment regarding this work is that the system spin multiplicities at which theoretical calculations were performed were not explicitly stated. In my own work I have noticed first that the lowest energy spin multiplicity of the two colocalized structures (support bound charged tool molecule and workpiece) is not always the same as expected from the lowest energy spin multiplicities of these in isolation; second, that in some cases at various points along an addition-retraction trajectory the particular lowest-energy spin multiplicity may change, suggesting that if there is sufficient time for intersystem crossing to occur during the contemplated physical operations then this possibility should be accounted for in cases where this applies; and third, that reactivities may differ markedly at different spin multiplicities. I find no mention of this issue in these workers' publications regarding addition reactions.

D. G. Allis and K. E. Drexler [All05] propose a tool which on discharge yields a strained aromatic ring, yielding favorable discharge energetics. The particular molecule proposed (designated DC10c), however, features several fused 5-membered aliphatic rings surrounding the highly strained central six membered ring, posing significant challenge to synthesis, but which also does not itself offer any clear attachment of the corresponding minimal molecule to any presently existing surface, although a structure formed by a hypothetical advanced mechanosynthetic nanotechnology apically integrating this tool was presented. Further, since this structure deviates from the diamond lattice, it is not clear that, even given the as yet elusive advanced machine-phase mechanosynthetic technology shown to be within the bounds of known physical laws [Dre92], that a tool and system capable of generic diamond mechanosynthesis could produce this structure; at least upon close inspection the specific mechanosynthetic steps required from carbon dimers are not immediately apparent.

Turning from dimer addition tool chemistry and design to another challenge which must be met, to be useful for precise positional mechanosynthesis, molecular tools must be securely fastened to structural support members capable of withstanding the potentially high forces involved, most preferably with predetermined geometry at predetermined locations or sites. Silicon and related materials are well-known for their useful semiconducting properties, and additionally feature high hardness and tensile strength. This particular combination of properties has been exploited in the arts of MEMS and NEMS, and makes these materials useful for the present invention. The silicon (100) surface undergoes a primitive 2×1 reconstruction which is stable to H passivation. Another material which has been attracting increasing interest is the cubic-, adamantine-, 3C- or beta-phase of silicon carbide. The surface chemistry of beta-SiC is more complex than that of silicon, not least because the (100) surface may be either Si or C terminated. Fortuitously, Si terminated beta-SiC(100) (Si-beta-SiC(100)) reconstructs to a primitive 2×1 configuration on reaction with hydrogen, which was found by V. Derycke et al. [Der01] to occur robustly for the clean (4×2) reconstructed surface. Significantly, this surface structure resembles Si(100)2×1:H, having columns of Si-dimers. It is also significant to note that beta-SiC can have mechanical properties superior to pure silicon, facilitating more vigorous mechanosynthetic operations due to the higher forces which may be applied, favoring the use of this material for some aspects of the present invention. As used herein, these materials are generally preferably doped to impart semiconductivity or conductivity.

Within the arts of semiconductor surface chemistry there has been increasing interest in modifications of surfaces with organic molecules which might be useful for molecular scale electronics. The chemistries of a number of systems studied may be adapted for use as tools for the present invention, and in a few cases, the same molecules themselves may also be used.

Positional control for nanomanipulation is by now routine with apparatuses such as scanning probe microscopes (SPMs.) The feedback controlled lithography (FCL) method of [Her02] is a useful method employing STM for hydrogen abstraction from silicon surfaces, representing a particularly useful example as discussed below.

STM nanolithography methods include processes for abstracting hydrogen atoms from hydrogen terminated silicon surfaces. M C Hersam, N P Guisinger and J W Lyding refined a process for hydrogen abstraction from Si(100)2×1:H surfaces, which they term feedback controlled lithography (FCL) [Her02]. These workers and others have successfully bonded organic molecules to dangling bonds or surface atoms with radical character with the resulting surface modifications having varying degrees of definition. For example, it was initially thought [Abe97][Lyd98] that norbornadiene would bond to Si(100)2×1 via a bis-[2+2]cycloaddition forming two four-membered rings involving reactant double-bonds and surface Si-dimers. In earlier work (unpublished) I considered tools for mechanosynthesis designed on this basis. Later, it was shown that norbornadiene chemisorption is at least disordered [Hov97] and likely only one single-bond is formed and the organic moiety is capable of rotation [Bil03]. Therefore, for complete positional control and orientational definition, it is necessary to use compounds which form more definite surface bonded structures.

It is noted here that in the art of scanning probe microscopy, a technique related to scanning tunneling microscopy performed with this type of instrument has been found for the nanoscale and atomic scale surface imaging of diamond, which was surprising because this material is generally held to be an insulator. [Bob01] found that resonant electron injection at specific biases which relate to the electronic band structure of diamond (5.9 V being the principal bias, and being above the diamond work function of 5.3 V, with the microscope thus operating in the near-field regime (rather than the tunneling regime) permits the exploitation of the long electron diffusion length in diamond to enable near-atomic resolution of the clean, dehydrogenated C(100)2×1 surface, in the absence of doping, and without charging. This technique will likely be useful to optimization of aspects of the present invention, and would be expected to apply also to other diamond surfaces.

Useful information concerning the Diels-Alder reactivity of acenes is to be found in [Bie80].

The field of self-replicating systems both serves as important background to the present invention and also may be enhanced through the innovations of the present invention.

A demonstration self-replicating system comprising a few types of preformed plastic parts was designed, constructed and operated by M. Moses. [Mos01] This system was not itself autonomous and required external control, in large measure due to insufficiently tight tolerances of parts used and the resulting flexibility and hence positional uncertainty. This work did contemplate improvements in design and some of the considerations necessary for autonomous operation and information processing means therefor, although that was not implemented. Although there were further speculations on approaches to molecular self-replicating machines in that disclosure, none of these are sufficient to enable any actual implementation.

C. M. Collins disclosed an invention for self replicating systems built from puzzle pieces comprising fabrication tools for retrieving, placing and processing puzzle pieces. [Col97] Despite descriptions elaborating wideranging application of that invention, these apparently did not reach fruition in the intervening years. As seen in the work of M. Moses, imprecise tolerances, particularly those which give rise to additive errors during construction, pose significant limitations to reliable autonomous operation of such a system. Further, for applications involving fluid or gas handling or involving pressurized fluids, even microscopic gaps can impair or vitiate functionality; the paint coatings suggested for creating seals are of limited use for reactive or corrosive materials or extremes of operation. Also, although some devices for performing operations such as melting and molding are described, suitable materials for high temperature operations or processing themselves susceptible to processing by the same system were not identified, such that an important class of operations of particular usefulness are not enabled therein.

In earlier work disclosed [Rab97] methods and means for fabrication and replication on surfaces involving microfabrication methods, pattern replication, molecular binding and deposition, and the fabrication of useful devices thereby.

Lackner and Wendt [Lac95] analyzed factors related to the mathematics and thermodynamics of the exponential growth of large-scale self-replicating systems with bulk materials processing, but although these workers proposed some interesting and novel chemistries, that work was principally one of analysis and no methods nor means enabling implementation were provided.

Modular robotics based on a cellular automata paradigm have also been combined into extremely simplified self-replicating systems. [Zyk05] These systems take each module as preformed input parts, so accordingly the replication of such systems is limited by the provision of those parts, and capabilities and properties thereof.

Useful information concerning the Diels-Alder reactivity of acenes is to be found in [Bie80].

The art of topological chemistry pertaining to the constitution and synthesis of [n]catenanes, [n]rotaxanes and related compounds is reviewed in [Die03] and [Hub00].

### SUMMARY OF THE INVENTION

The present invention addresses several conceptual and practical challenges posed by the foregoing problem and utilizes compounds including organic compounds and organic-inorganic compounds, the synthesis of many of which has been accomplished decades ago, as molecular tools therefor, enabled by methods and means for securely anchoring these to supports in useful configurations. Application of similar methods and means in different reactions permits mechanosynthesis of graphenoid molecules and nanostructures. Additional applications of these methods and means and modifications thereof are elaborated. Among these are nanomanipulation, actuator devices, nanoelectromechanical logic devices, positioning devices, photovoltaic collectors, optical signal detectors, all of which may be fabricated and assembled according to the present invention. The foregoing list of devices being sufficient for systems for mechanosynthetic fabrication and nanoassembly, self- and allo-replicating systems, such systems are disclosed.

The present invention identifies existing chemical compounds and material compositions useful as tools for positionally controlled mechanosynthetic operations for forming molecules and nanostructures including diamondoid, graphenoid and silicon compositions with novel and precise control whereby a vast variety of structures may be programmably fabricated. In particular, compounds thus useful are adducted to support members to serve as platform moieties. Platform moieties (especially of oligo- or poly-acene composition) may alternatively themselves also serve as support members, and may comprise group 14 and group 4 atomic substitutions among other atomic substitutions. As the present invention has been elaborated, the wideranging flexibility of this class of compounds used as platform moieties has been realized and applied to a wide range of uses far beyond the initially desired use as addition tool. A number of disclosed platform moieties may directly bind precursor reactants (including but not limited to many diatomic and heterodiatomic reactant fragments (including C₂, CB, CN, CP, CSi, Si₂, SiB, SiP, Ge₂, Sn₂,) but also C₃, C₄, C₅, Cₙ, CₙN, oligoynes, polyynes, oligocumulenes, polycumulenes, to serve as addition tools for positional mechanosynthetic addition operations, including for fabrication of doped materials. Platfrom moieties may be bound to conductive or semiconductive (or superconductive) supports whereby electrooxidation or electroreduction may be performed, particularly of tool-reactant-workpiece intermediates; in the present invention this was fount to exert important and useful effects in many cases, and in some cases was indispensable to formation of desired products or to avoid tool-failure events; introduction of redox reactions to positional mechanosynthesis and nanoassembly is novel to the present invention and has broad applicability. [Kon00] and references therein, and also [Hov97], teach methods for the formation of adducts (of molecules comprising unsaturated compounds) with Si(100) such as are useful in the present invention for forming adducts between platform moieties or molecules useful therefor and supports, including supports of other compositions such as beta-SiC or diamond; those teachings are incorporated herein by reference and are used in many instances of the present invention. Platform moieties may be modified with other functional groups (e.g. basic groups or ethyne groups) or metals or metal hydrides to serve platform moieties for tool groups for hydrogen abstraction operations, deprotonation operations, positional electrodeposition operations for deposition of individual metal atoms or ions at precise locations, positional reductive hydrogenation reactions among others in addition to positional mechanosynthetic addition operations. Platform moieties adducted to structural supports with suitable compositions for usefulness as binding tools including reactant binding tools for addition of reactant fragments to workpiece target sites are disclosed. Platform moieties useful for directly or indirectly binding workpieces, workpiece precursors or workpiece intermediates either to hold these during mechanosynthetic fabrication operations of manipulate these for nanoassembly operations for precisely assembling workpieces together are also disclosed. Modifications of tool molecules for improving performance and avoiding undesired products are disclosed, including atomic substitutions and functional (side-group) modification of tool molecules. Structural support members may be in communication with actuators or positioners, which may themselves be fabricated according to the present invention, to yield devices and systems for performing the methods of the present invention including under digital electronic preprogrammed control. Methods for avoiding failure-products concerning maintaining patterns of workpiece hydrogenation relative to addition target sites are disclosed. Included are recycling reactions for recharging tools with reactant moieties or eliminating waste products. Fabrication of simple devices including actuators, positioners and relays embody aspects of the present invention. According to the positional mechanosynthetic fabrication and nanoassembly methods disclosed herein, devices for performing the methods of the present invention may themselves be fabricated and assembled, enabling self- or allo-replicating systems as well as self-extending or growing fabrication and assembly systems. Various addition tools herein capable of synthesizing doped materials enable the fabrication of materials and component nanostructures for electronic devices and photoelectronic devices including conventional semiconductor electronic devices including photovoltaic devices or quantum-dot based devices including photovoltaic devices for energy production; also, at least one material which may be fabricated according to the invention, boron-doped diamond has superconducting and metallic properties as well as semiconducting properties and also optical transparency under different conditions or compositional ranges, and has additionally attracted considerable interest in electrochemistry as an electrode because of superior stability and large overpotential for electrooxidation of water whereby electrochemical reactions in water which are otherwise precluded by electrooxidation of water are enabled. According to the positional mechanosynthetic fabrication and nanoassembly methods disclosed herein, novel devices and methods for the fabrication and assembly thereof are disclosed, including novel nanowires, actuators, positioners, nanorelays and logic gates based thereupon, detection means for detecting analytes including biomolecules and especially oligo- or poly-nucleotides, novel electrochemical devices including energy storage means (fuel cells and galvanic cells) and phototovoltaic devices. Systems capable of self- or allo-replication or self growth comprising energy production means, particularly photovoltaic devices for solar energy conversion, electrochemical means for converting chemical compounds, and programmable information processing and storage means in communication with actuators, positioner and sensors comprised by these systems and means for effecting mass transport (e.g. pumps driven by actuators or electrophoreses means comprising electrodes) may be fabricated and assembled according to the methods of the present invention, and may, if designed and programmed to do so, fabricate and assemble similar systems; when these systems are designed and operated to perform electroreduction of carbon dioxide or carbonate (and possibly also water) to other chemical compounds including useful feedstocks or chemical precursors (e.g. syngas,) driven by energy converted by photovoltaic devices comprised by these systems. This class of embodiments of the present invention may be realized by several combinations of alternatives disclosed herein (but may also comprise devices, methods, means and compositions of existing technology,) and represents a significant answer to the challenges posed by the accumulation of carbon dioxide and other greenhouse gases in the Earth's atmosphere, as well as transformation or reduction of other environmental pollutants.

Addition operations according to the present invention comprise forming a structure comprising a platform support member, a platform moiety and a reactant fragment in communication with said platform moiety, providing a positioner for positioning said platform support, providing a workpiece or workpiece seed for fabrication, contacting said reactant fragment with said workpiece by means of said positioner, and withdrawing said platform support from said workpiece. Preferably, hydrogens are abstracted from particular sites on said workpiece.

Platform supports preferably comprise electrically conducting or semiconducting or superconducting materials.

Platform moieties may form binding sites for atoms or functional groups for other positional mechanosynthetic operations such as deprotonation, hydrogen abstraction, reductive hydrogenation, positional electrodeposition, or positioning of catalysts for positionally catalyzing chemical reactions or transformations.

Platform moieties and numerous variations or extensions thereof may additionally serve to bind workpieces for manipulation operations including nanomanipulation, whereby two or more workpieces may be assembled into an assemblage, device, subsystem or system.

First platform moieties may bind to other platform moieties or precursors thereof, or to other molecular tools of the present invention, and cause said other platform moieties or precursors thereof, or to other molecular tools of the present invention bound to said first platform moieties to second platform support members.

Reactants and reagents are preferably delivered to mechanosynthesis tools near the sites of their operation during fabrication; this is favorably accomplished by situating reactants, reactant precursors or reagents on feed chains for delivering same to tools. Polymer chains, and more preferably polycatenane chains, most preferably in pairs with delivered material suspended therebetween and routed into and out of a volume or enclosure for mechanosynthesis or fabrication or assembly fitted with actuators or pulleys for translating said feed chains represent preferred means for this function.

It should be understood throughout the present invention, that as desired, methods and means herefore may and are often preferably provided and done in parallel, including on plural workpieces. For example, multiple types of tools, provided multiply may operate simultaneously on a plurality of workpieces, manipulate a plurality of workpieces and assemble a plurality of assemblies for producing multiple products simultaneously. In some instances or embodiments, this may be in analogy to [Rab97] although other topologies and arrangements, particularly on gridworks or frameworks of [n]acenes, for example, are also possible with the present invention.

### DEFINITIONS

Fabrication—for additive fabrication, to form a material by adding molecules, atoms or chemical reactants thereto. The material formed may itself be a molecule. In the example of a mechanical watch, individual cogs may be fabricated by molding molten metals or by electroforming, however these fabrication techniques themselves are not generally operable for fabricating a functional watch assembly. Additive fabrication generally involves the formation of covalent, ionic, intermetallic or hydrogen bonds or van der Waals contacts or combinations of these (e.g. as in supramolecular complexes) between at least one molecule, ion, atom, complex, reactant, particle, colloid and another, or more frequently between a plurality of these.

Assemble—(verb) to place parts together in suitable spatial arrangements so that parts may make up a group of parts (an assemblage or assembly, the term used as a noun to denote sets of parts assembled together) which thereby may thereby operatively interact at least upon completion of assembly to accomplish some desired function or make up some desired object. Assembly operations need not form covalent bonds (or other bonds such as formed by fabrication,) although they may. Assembly operations frequently form mechanical linkages, e.g. the assembly of two puzzle-pieces together. Upon assembly, parts remain distinct. This definition carries over to nanoassembly operations herein comprising nanomanipulation operations.

Part—an object to be assembled into an assembly of two or more parts. Herein, parts may be individual molecules or supramolecular complexes or nanostructures or colloids or particles. In the special case where an individual atom serves as a discrete component (e.g. a metal atom bonded to dehydrogenated carbons on a diamond surface to serve as a binding site or a catalytic site) atoms and ions may be considered to be parts. One criterion for whether something is justifiably considered a part is whether, upon disassembly of an assembly, it can be uniquely determined which atoms or molecules were necessarily assembled into the assembly or a subassembly thereof as constituents of different parts. For example, a metal atom in a cog of a mechanical watch is comprised by a distinct object from a metal atom in comprised by spring in a mechanical watch, whereas two metal atoms in the same cog. Another criterion is that in understanding the composition, structure and function of a system, it is generally preferable to minimize the number of parts the system could be deemed to have been assembled from. For further illustration, we may consider an atomically perfect, perfectly symmetrical diamond cog; upon rotation we cannot distinguish a large number of atoms comprised by this cog, so it is not useful to describe these as distinct parts, however it is very useful to the understanding of how a watch operates and is assembled to consider two intermeshing cogs to be different parts. Note that this definition remains sensible even in the special case where a part is fabricated in-situ with respect to an assembly or subassembly because function is embraced.

“Adduct—[ . . . ][(2)] n. Chemistry[.] A chemical compound that forms from the addition of two or more substances.” [AHD00]

Adducted—caused to form together with or to in an adduct.

### DESCRIPTION OF THE FIGURES

FIG. 1 depicts various synthetic schemes for synthesizing tools and performing mechanosynthetic operations according to the present invention. Note that in many instances, the following schemes as well as other synthetic schemes disclosed herein involve mechanosynthesis reactant fragment precursor loading reactions which may be performed similarly either on support bound addition tools or platform moieties or on the precursors thereof in solution or in gas or vacuum phase.

FIG. 1.a. shows the synthesis of a 2,3,5,6-tetramethylene-1,4-dimethyl-1,4-dichloro-1,4-disila-cyclohexane from 2,3-dilithio-buta-1,3-diene and methyltrichlorosilane, followed by S_{N}2 reaction with dilithium acetylide. Below is shown the structures of this molecule adducted to two Si dimers via Diels-Alter reactions of this bis-diene, before and after mechanosynthetic dimer addition discharging the carbon dimer arising from dilithium acetylide addition, yielding the aromatic-like 1,4-silicon substituted six-membered ring.

FIG. 1.b. shows a synthetic scheme for a 2,3,6,7-tetrahydro-9,10-diphenyl-9,10-disila-anthracene addition tool precursor via 2,3,6,7-tetrahydro-9,10-diphenyl-9,10-dichloro-9,10-disila-anthracene, synthesized from dichlorosilylbenzene and a 2-chloro-lithiobenzene, the product of which is condensed with another molecule of itself by palladium catalyzed hydrosylylation. The condensation product is preferably separated into isomers and the cis product is caused to undergo S_{N}2 reaction with dilithium acetylide. Note that other metal acetylides including metal acetylides comprising metals coordinated by ligands could replace dilithium acetylide.

FIG. 1.c. shows a synthetic scheme alternative to that of FIG. 1.b. for synthesizing the same product; in this case 1,2-dilitiobenzene and excess trichlorosilylbenzene are reacted to form an intermediate which is then reacted with more 1,2-dilitiobenzene. The product is a dihalide modified unloaded binding tool precursor, which is then reacted with vinyl-1,2-dilithium, an alternative carbon dimer loading reaction which could equally well be used in FIG. 1.a, but which does require hydrogen abstraction of the carbon dimer before mechanosynthetic addition reactions; ethyl-1,2-dilithium could likewise be used as a carbon dimer source at the expense of additional hydrogen abstractions.

FIG. 1.d. shows a synthetic scheme for binding a propyl-1,3-di-yl fragment to an anthraquinone or oligo- or poly-acene-quinone tool molecule or precursor, followed by 2 hydrogen abstraction operations from carbon 2 of the propyl fragment to yield a carbon, useful, for example, in a mechanosynthetic step described herein for forming initial adamantine cages from starting 4-methyladamantanyl workpiece seeds. Note that in some embodiments of the present invention, oligo- or poly-acene based tools may serve as both tool and structural member supporting tool atoms involved in mechanosynthetic operations including mechanosynthetic addition operations. Note also that unless otherwise indicated, the use of the term oligo-acenes herein embraces molecules comprising as few as 3 6-membered rings, i.e. anthracene, tetracene, pentacene, hexacene, heptacene, etc. are comprehended by this term; which arises from the equivalence of these in many uses according to the present invention.

FIG. 1.e. shows an alternative and generalized scheme related to that of FIG. 1.c. for the palladium catalyzed (e.g. hydrosilylation, hydrogermylation, hydrostannylation, etc.,) loading of 1,3-dichloropropane to an oligo- or poly-acene comprising a 1,4 substituted 6 membered ring.

FIG. 1.f. shows a synthetic scheme related to that of FIG. 1.d. but for adding a 1,3-dilithio-s-trans-buta-1,3-diene reactant fragment precursor to an anthraquinone or oligo- or poly-acene-quinone tool molecule or precursor.

FIG. 1.g. shows a synthetic scheme related to that of FIG. 1.f. but for synthesizing a tool for adding nitrogen substituted reactants to workpieces. In this case 2-aza-2,4-dilithio-buta-3-ene is the reactant fragment precursor to be loaded, and after loading, a hydrogen is abstracted from carbon 3 of the reactant fragment to yield an electron-delocalized fragment.

FIG. 1.h. shows a synthetic scheme related to that of FIG. 1.f. but for synthesizing a tool for adding 5-carbon reactants to workpieces, especially to edges of graphene workpieces or to edges of diamond (110) workpiece surfaces. In this case 2,4-dilithio-penta-1,4-diene is the reactant fragment precursor to be loaded, and after loading, a hydrogen may be abstracted (not shown) from carbon 3 of the reactant fragment to yield an electron-delocalized fragment.

FIG. 1.i. depicts various loading reactions for generalized oligo- or poly-acenes comprising a 1,4-substituted 6 membered ring. The first two reactions involve a S_{N}2 mechanism and yield molecules which may serve as precursors for deprotonation tools and hydrogen abstraction tools comprising ethyne groups projecting approximately perpendicular to a support to which these precursors may be adducted. The last two reactions involve Diels-Alder-type additions.

FIG. 1.j. depicts various loading reactions similar to those of FIG. 1.i. for the case of all-carbon oligo- or poly-acenes. Note that the third reaction shows an aluminum-halide bound by two ligands replacing lithium, which when said ligands are bound to or capable of binding to a support member yields an intermediate product useful for nanomanipulation and positionally controlled adduct formation of abstraction tool precursors or deprotonation tool precursors. Alternatively, this reaction can yield a tool or tool precursor for adding aluminum complexes to target sites, alternatively for manipulating aluminum ligands including the special case of carbide dianions, extracting these from calcium carbide crystals.

FIG. 1.k. shows the structures of 9,10-disilanone-anthracene (9,10-disilaanthraquinone,) the loaded dihydroxy-derivative thereof, the alternative, loaded unprotonated derivative, and the corresponding unsubstituted unprotonated loaded oligo-acene-quinone.

FIG. 1.l. shows reaction schemes for forming metal hydrides bound to oligo- or poly-acene tools or tool precursors. Note that similar reactions could be done for the corresponding terminal bis-dienes (e.g. in the case of anthracene this is the 2,3,5,6-tetrahydro derivative.) Oligo- or poly-acenes comprising at least one six membered ring which is lithiated at positions 1 and 4 are provided (e.g. prepared by treatment of corresponding dihalides with lithium or alternatively other alkides either as metal or in solution) and contacted with metal halide hydrides. The first reaction is a generalized case, while the second is for forming a bridging stannylane and the third is for forming a bridging alumane. Note that the alumane tool is expected to be quite similar in reactivity to the commonly used strong reducing agent diisobutyl-aluminum hydride. Upon use in reductive hydrogenation operations, these tools may be recharged by treatment with molecular hydrogen, or alternatively, may be used for positional electrodeposition for forming metal nanostructures or quantum dots or nanowires.

FIG. 1.m. shows a generalized scheme for binding a cumulene reactant precursor to a platform moiety. In this case, the platform moiety is adducted to a support before reaction with cumulene to avoid Diels-Alder reaction with cumulene double-bonds. AM1 calculations (not shown) predict that up to 7 carbon cumulenes form stable desired loaded tools with 9,10-disilanoxide platform moieties. In this scheme, X and Y may be borane derivatives and tandem Suzuki-Murimaya type couplings may be catalyzed by palladium complexes, in which case R1 and R2 would be halides and would be eliminated.

FIG. 1.n. depicts the “Chinese-lantern” structures of [Cu(II)]₂(acetate)₄, [Cu(II)]₂(acetate)₃(benzoate-yl), and instances thereof bound to ethynyl groups. Note that other [Cu(II)]₂(carboxylate)₄ could be utilized similarly, and that the benzoate-yl ligand is preferably directly bound or at least indirectly linked to a support.

FIG. 1.o. shows a copper promoted deprotonation of an ethyne group related to that studied by [Cli63] by an amide anion (e.g. sodium amide, lithium-diisopropylamine [LDA], etc.,) or secondary amines (e.g. piperidine as in [Cli63]) or tertiary amines. Preferably, amine or other base moieties are bound to a support, and more preferably, the copper complex is a Cu(I) complexed by one or more carboxylate group and/or carboxylic acid group bound to a support.

FIG. 1.p. shows a deprotonated ethyne ion (ethide group) complexing with a “Chinese-lantern” [Cu(II)]₂(carboxylate)₄, which is preferably bound to a conductive or semiconductive support to which an oxidizing potential is applied, preferably after binding (or alternatively bound to a non-conductive support and electron transfer is accomplished by oxidizing species in solution, e.g. in [Cli63] Cu(I)Acetate accomplishes this.) R to which the ethyne group being modified is bound is then withdrawn (pulled) from the copper complex to yield the desired ethynyl radical group useful for hydrogen abstraction. Where the support member (not shown) to which R in FIG. 1.p. is bound is in communication with an actuator comprised by a relay type switch of other embodiments of the present invention, a low electrical potential bias for actuation of the pulling motion insufficient to break the ethide-group-Cu bond but sufficient to break the corresponding bond in the weakened, oxidized or electrooxidized complex, may be applied prior to application of said oxidizing potential to said conductive or semiconductive support, such that, firstly, the desired ethynyl radical group is withdrawn immediately upon formation, and secondly, that this event may be detected and an electrical signal resulting from relay closure signifying this communicated to control circuitry, whereby it may be determined that the desired deprotonated tool and the desired tool electronic-state has been attained. If R is instead withdrawn immediately upon application of said low electrical potential bias for actuation, and an electrical signal resulting from relay closure signifying this communicated to control circuitry prior to application of said oxidizing potential, then it is determined that deprotonation did not occur, and the tool may be returned to undergo another deprotonation step. Note that this reaction permits recycling of hydrogen abstraction tools when multiple base molecules are available or themselves recycled.

FIGS. 2.a. and b. illustrate two views of the AM1 predicted optimal structures of 4-methyl-adamantene adducted to a 9,10-dihydroxy-9,10-disila-anthracene platform adducted to an Si nanostructure which may model the similar adduct to two dimers of a Si(100)2×1 surface. This structure shows how a platform moiety used in other embodiments of the present invention may be used to bind a molecule which may serve as a seed for fabricating diamond nanostructures. Synthesis may commence by hydrogen abstraction from the methyl group on carbon 4 and from carbon 9 to yield two radical sites across which a carbon dimer may be added. Thereafter a hydrogen is abstracted from carbon 10 and a 2-dehydropropene (a 2-carbene) is added to bridge carbon 10 and the carbon atom of said carbon dimer bound to the methyl at carbon 4 to yield a dimethyl-diamantane, yielding a product which may undergo similar dimer addition between a dehydropropene derived carbon atom and adamantene derived carbon 8 after suitable hydrogen abstraction, whereby fabrication of diamondoid molecules and nanostructures form a 4-methyl-adamantene precursor is enabled.

FIGS. 2.c. and d. illustrate two views of the AM1 predicted optimal structures of an ethyne group substituted onto a 9-anthrone platform adducted to an Si nanostructure which may model the similar adduct to two dimers of a Si(100)2×1 surface.

FIGS. 2.e. and f. illustrate two views of the AM1 predicted optimal structures of an ethyne group adducted onto a 9-chloro-10-hydro-anthrone platform (e.g. via S_{N}2 attack of NaCCH at the halide substituted carbon) adducted to an Si nanostructure which may model the similar adduct to two dimers of a Si(100)2×1 surface. Note that the structures depicted in FIGS. 2.c-e. comprise ethyne groups which may be deprotonated or undergo hydrogen abstraction and are accordingly useful as deprotonation (base) tools or hydrogen abstraction tools. Additionally, especially if the atom to which said ethyne group is bonded to in the structures shown (anthracene carbon 9) is substituted by a group 14 atom or a group 4 atom other than carbon, such tools or modifications or substitutions thereof may be subjected to hydrogen abstraction from said ethyne group and serve as tools for addition of ethyne groups to workpiece target atoms, since, for example, the structure formed by attack by an ethyne radical on a workpiece atom featuring unsaturated bonding to any other workpiece atom results in a structure highly analogous to the switchbladed intermediates formed in many cases herein; in this class of addition operations, the support and platform moiety are then retracted from said workpiece to break the bond between said platform and said ethyne group to yield an ethyne-radical modified workpiece; optionally with electrooxidation to weaken the platform-ethyne bond. If it is desired to instead bridgingly add a tool-borne ethyne group (e.g. such as the foregoing) then before withdrawing said support for said platform, said support is advanced towards said workpiece whereby the ethyne group carbon atom directly bonded to said platform may be forced into contact with a second target atom of said workpiece, with bending of said ethyne group, and with pressure applied to said ethyne group carbon atom directly bonded to said platform by another atom of or bonded to the same ring of said platform moiety to which said ethyne group is bonded; an analogous switchbladed reactant configuration is seen in FIG. 5.a., and in the present case may be forced to contact the desired workpiece atom by forces or pressures exerted by platform moiety atoms as said support is advanced towards said workpiece; this mode of addition may be termed dagger-mode addition to distinguish from addition of a reactant bonded to a tool or platform via two bonds as in proposals in the literature.

FIG. 2.g. illustrates the AM1 predicted optimal structure of a boron substituted dimer loaded onto a tetramethylene-cyclohexadiene tool (equivalently, 7-boro-8-dehydro-2,3,5,6-tetramethylene-bicyclo-oct-7-ene) adducted onto a diamond nanostructure which may model three dimers of a C(100)2×1 surface. This structure represents a loaded dimer addition tool for fabricating boron doped diamond molecules or nanostructures.

FIG. 2.h. illustrates the AM1 predicted optimal structure of a nitrogen substituted dimer loaded onto a tetramethylene-cyclohexadiene tool (equivalently, 7-aza-8-dehydro-2,3,5,6-tetramethylene-bicyclo-oct-7-ene) adducted onto a diamond nanostructure which may model three dimers of a C(100)2×1 surface. This structure represents a loaded dimer addition tool for fabricating nitrogen doped diamond molecules or nanostructures.

FIG. 2.i. illustrates the AM1 predicted optimal structure of 3-didehydro-penta-1,5-diene (a 3-carbene) loaded via carbons 2 and 4 to a 9,10-dihydroxy-9,10-disila-anthracene platform from which hydroxyl hydrogens have been removed, said platform adducted to an Si nanostructure which may model the similar adduct to two dimers of a Si(100)2×1 surface.

FIG. 2.j. illustrates the starting geometry for adding the reactant fragment of FIG. 2.i. to the edge of a diamond nanostructure whereby workpiece shrinkage or narrowing is avoided during addition of multiple layers of carbon. Note also that this arrangement also enables the fabrication of slanted regions or members, such as are useful in fabricating, for example, compliant members or spring, which are, for example, useful in some of the actuators of the present invention.

FIG. 2.k illustrates the AM1 predicted optimal structure of a laterally directed ethyne tool, in the dehydrogenated radical state useful for hydrogen abstraction, formed by Diels-Alder reaction of 2,3-didehydro-5-ethynyl-naphthalene with an anthracene platform moiety adducted to an Si nanostructure which may model the similar adduct to two dimers of a Si(100)2×1 surface. This tool is expected to be of particular use in hydrogen abstraction steps in graphene mechanosyntheses. Also, in the reduced or anionic form (as results from deprotonation without subsequent electrooxidation, wherein the ethyne would be termed an acetylide or ethide group,) this tool is useful for scavenging or removing cations from workpieces or intermediates.

FIG. 2.l illustrates the AM1 predicted optimal structure of a laterally directed ethyne tool, in the dehydrogenated radical state useful for hydrogen abstraction, formed by Diels-Alder reaction of 2,3-didehydro-5,8-diethynyl-naphthalene with an anthracene platform moiety adducted to an Si nanostructure which may model the similar adduct to two dimers of a Si(100)2×1 surface. Because this structure is symmetrical, mechanosynthetic deprotonation may determine the precise location of the desired radical or anion atom, or alternatively, both ethyne groups may be used for hydrogen abstraction or deprotonation (according to whether electrooxididation is done after deprotonation or not, respectively.) This tool is expected to be of particular use in hydrogen abstraction steps in graphene mechanosyntheses.

FIG. 2.m illustrates the AM1 predicted optimal structure of a tetradehydrogenated silyl dimer bridgingly bound to the germanium atoms of a 9,10-dimethyl-9,10-digermyl-anthracene, useful for silicon mechanosynthesis.

FIG. 2.n illustrates the AM1 predicted optimal structure of a silene bridgingly bound to the germanium atoms of a 9,10-dimethyl-9,10-digermyl-anthracene, useful for silicon mechanosynthesis.

FIG. 2.o. depicts the synthetic scheme for the reactant loaded tool of FIG. 2.n and related tools.

FIG. 2.p. depicts the synthetic scheme for the reactant loaded tool of FIG. 2.m and related tools, including tools for fabricating boron and phosphorus doped silicon molecules and nanostructures, including quantum dots.

FIG. 2.q. depicts alternative and generalized unloaded tools for binding silene or silicon dimers or silicon-dopant dimers related to those of FIGS. 2.m-p. as well as the tools of FIGS. 2.r-v.

FIG. 2.r. depicts the synthetic scheme for a CB reactant loaded tool similar to that of FIG. 2.g but based on an anthracenyl platform. Anthracene carbons 9 and 10 are carbanions (in lithiated form) which attack a reactant fragment precursor which comprises leaving groups such as halogens. Here, further halogens (chlorine atoms) from the reactant precursor are abstracted, e.g. by tools comprising ethynyl radicals to expose the dimer atoms for reaction with workpiece target atoms. Note that with phosphorus replacing boron in a synthetic scheme identical to this, CP reactant loaded tools (e.g. for fabricating P-doped n-type diamond materials and nanostructures) may be obtained from Cl₂PCCl₃. Likewise, CSi reactant loaded tools (e.g. for fabricating Si-substituted diamond materials and nanostructures) may be obtained from Cl₃SiCCl₃. according to a synthetic scheme otherwise identical to this.

FIG. 2.s. depicts the synthetic scheme for a CN reactant loaded tool similar to that of FIG. 2.h but based on an anthracenyl platform. In this case an imine reactant fragment precursor forms a Diels-Alder adduct with an anthracen platform moiety, and three hydrogens are then abstracted to expose the dimer atoms for reaction with workpiece target atoms.

FIG. 2.t. depicts the synthetic two schemes for forming platform bound workpiece seeds similar to those of FIGS. 2.a-b. The first is a Diels-Alder reaction of adamantene with a 9,10-disubstituted anthracene or 9,10-disubstituted anthracene-derivative platform moiety. The second concerns reaction of a 1,2-dihalo-adamantane with a 9,10-dianion anthracene derivative (in dilithiated form;) this would be expected to proceed via an S_{N}1 reaction at adamantane carbon 1 and an S_{N}2 reaction at adamantane carbon 2.

FIG. 2.u. depicts the synthetic two schemes for forming platform bound workpiece seeds similar to those according to FIG. 2.u. The first is a Diels-Alder reaction of adamantene with a anthracene or anthracene-derivative platform moiety. The second concerns reaction of a 1,2-dihalo-adamantane with a 9,10-dicarbanion anthracene derivative (in dilithiated form;) this would be expected to proceed via an S_{N}1 reaction at adamantane carbon 1 and an S_{N}2 reaction at adamantane carbon 2.

FIGS. 2.v.1-3. illustrates the AM1 predicted optimal structure of a reductive hydrogenation tool comprising an aluminum atom bonded to carbons 9 and 10 of a 9,10-dimethyl-anthracene derived platform moiety adducted to an Si nanostructure which may model the similar adduct to two dimers of a Si(100)2×1 surface. FIG. 2.v.1. shows the dihydrogenated, anionic state; FIG. 2.v.2. shows the monohydrogenated, anionic state; and, FIG. 2.v.3. shows the nonhydrogenated, monocationic singlet state. Note that the nonhydrogenated, monocationic singlet state is also useful for positioning of an aluminum atom as a reactant for positional electrodeposition onto aluminum nanostructures whereby aluminum nanostructures including conductive nanostructures including quantum dots and nanowires may be fabricated.

FIGS. 2.w.1-3. illustrates the AM1 predicted optimal structure of a 2,4-didehydro-adamantane adducted to a Si nanostructure which may model the similar adduct between two dimers of different rows of a Si(100)2×1 surface. As can be seen in FIG. 2.w.1., one of said two dimers is completely dehydrogenated while another comprises a distal hydrogen modification. This structure represents an alternative means for binding an adamantane derivative (including other adamantane derivatives than that shown here, including methyl substituted adamantanes such as that of FIGS. 2.a-b.) for serving as a workpiece precursor molecule or seed for fabricating diamond molecules or nanostructures.

FIGS. 2.x-z. depict schemes for synthesizing tools or tool precursors comprising metal-hydride functionalities, as are useful for protonating workpieces, reductively hydrogenating workpieces, and, upon dehydrogenation, for positioning metal atoms for positional electrodeposition. Due to the wide variety of metals, including transition metals, which form complexes with aromatic rings (especially η-6 bound complexes, which are expected to result upon dehydrogenation, as seen in FIG. 2.v.3.,) this scheme is highly general and yields tools and tool precursors which are highly and widely useful. Note that, especially in these instances but as in many of the synthetic schemes disclosed herein for synthesizing molecular tools, reactions may be performed on the free platform moiety precursor molecule in solution or in the gas phase, or may be performed on the platform moiety adducted to a support such as a structural member or a surface of a solid. FIG. 2.x. depicts the generalized scheme for forming metal-hydride bridging atoms 9 and 10 of the anthracene or oligoacene or polyacene skelleton. FIG. 2.y. depicts the generalized scheme of FIG. 2.x. for the case of stannyldichloride for forming dihydrostannylene bridging atoms 9 and 10 of the anthracene or oligoacene or polyacene skelleton. FIG. 2.z. depicts the generalized scheme of FIG. 2.x. for the case of dichloroalumane for forming an alumane bridging atoms 9 and 10 of the anthracene or oligoacene or polyacene skelleton; this may be subsequently treated with reducing reagents such as LiH to yield the dihydride. Other metals of interest include scandium, titanium, vanadium, chromium, manganese, iron, cobalt, nickel, halfnium zirconium, gallium, indium, molybdenum, tungsten, ruthenium, rhodium, palladium, silver, iridium, and platinum. Additionally, ligands known in the art of organometallic chemistry may subsequently be ligated to metal atoms bound to platform moieties whereby catalytic centers may be bound to support members and positioned according to the present invention for performing positional catalytic reactions on workpieces. Also note that metals including Al bound to binding tools may also form bonds to radical sites on workpieces, such as those formed by hydrogen abstraction therefrom, and such bonds may be weakened by electroreduction; thus, a tool such as that depicted in FIG. 2.v.3. may additionally serve as a nanomanipulation tool, particularly where tandem addition to a workpiece to be manipulated is not desired.

FIG. 3.a. depicts an overall arrangement for fabrication by mechanosynthesis according to early or simplified implementations of the present invention. This figure clearly shows the unimportance of tool and tool support aspect ratios and that mechanosynthetic fabrication is accomplished in an apparatus distinctly different from a the arrangement of a typical scanning probe microscope, and also the presence of multiple tool features on the same support member. This figure shows an arrangement useful for addition operations, abstraction operations and recharging of tools for these operations, as well as binding of a workpiece such as may subsequently be useful in nanomanipulation operations. Dimer addition tool 2 loaded with a reactant dimer, and hydrogen abstraction tool 4 comprising an ethynyl radical, along with reductive hydrogenation tool 8 and metal atom binding tool 10, are situated on support member 6. Binding tools 12 bind workpiece 16 to support 14. Deprotonation tool (base tool, e.g. a secondary amine or a secondary metal amide, MNR₂) 20 for removing protons from ethyne groups and oxidation or electrooxidation tool 22 which may comprise support bound [Cu(II)]₂(Carboxylate)₄ for converting ethide groups to ethynyl radical groups are bound to support 14. A carbon dimer 18 already added to workpiece 16 is shown. Reactant magazine 24 for loading addition tool 2 passes between 6 and 14. and comprises polymer strands 26 which bind metal atoms 28 for binding carbide reactant precursors 30; metal atoms 28 from which carbide molecules have been transferred are shown as 28b. Controllable three dimensional positioning means (not shown) translates 6 relative to 14 and 24. Note that this reaction permits recycling of hydrogen abstraction tools when multiple base tools 20 are provided or base moieties are themselves recycled, e.g. by deprotonation by another base. Note also that in undehydrogenated form (or the “used” form R—CCH,) hydrogen abstraction tool 4 may serve as a probe tip (since accurate three dimensional nanopositioning is available in this setup and may readily be combined, as in the nanorelays disclosed herein, with positional sensing) by scanning 6 relative to 14 in a Scanning Force Microscopy (SFM) type operation, which is useful, e.g. for troubleshooting the design of mechanosynthetic operation sequences or investigating intermediate or product properties (although this is not an absolute requirement for the present invention.) Optional structural member 41, which is preferably independently translatable from 6 and 14, provides a countersurface which may facilitate reactant loading from 24 to a discharged addition tool 2; a reactant 30 is suspended near 41, 2 is translated near a reactant 30 to be loaded, 2 is pressed into 30 which is pressed against 41 until a loading reaction takes place driven by the forces thus applied. Note that more vigorous loading reactions do not require resort to inclusion of 41 but in some cases may still be accelerated by this measure, or sub-nanometer position of a reactant 30 more fully locally constrained against thermal motion may serve to increase the local concentration of a reactant 30 to the tool 2 to be loaded in a loading operation apart from forces applied to the tool 2 onto which a reactant 30 is to be loaded.

FIG. 3.b.1. shows a suitable formula for metal-binding polymer 26 comprising 1,10-phenanthroline-3,8-di-yl monomers copolymerized (preferably alternatingly) with ethyne groups, which may be synthesized similarly to p-polyphenylacetylene, the synthesis of which is known in the art of polymer chemistry. As known in the art of organometallic chemistry, a wide range of metals are bound strongly by phenanthroline. Trivalent metals such as iron, boron, aluminum, gallium, or indium may be used. Alternatively, FIG. 3.b.2. shows a carbide bound to a metal such as lithium ions bound by pendant ethylene-diaminine-yl groups, related to the complex of lithium acetylide with ethylene diamine, which is commercially available, which may exchange acetylide onto a single strand of such a polymer, which in turn, preferably, may be tensioned, treated with metallic lithium, and contacted with another pendant diamine modified polymer; here n may be ≧0 in which case the polymer backbone is a poly-p-phenylene.

FIG. 3.c. depicts the arrangement for suspending a reactant magazine 24 between or near support members 6 and 14 most directly involved in mechanosynthetic operations. Polymer strands of magazine 24 are bound (preferably at their termini) by platform moieties 34b and 34c, and 34 and 34d; platform moieties 34 and 34b are bound to support 38 and platform moieties 34c and 34d are bound to support 36. Optional controllable positioning means (not shown) translates 36 and 38 relative to 14 and 6 as carbide molecules are consumed. Note that other arrangements of 36 and 38 relative to 6 and 14 are possible, including inverting the assembly of 36, 24, 38 and platform moieties 34 relative to the arrangement of 6 and 14 such that 36 and 38 are closer to 6 than to 14.

FIG. 4 concerns the use of binding tools to bind binding tool precursor molecules to support members. FIGS. 4.a-k. illustrate the deposition of a 2,3,5,6-tetramethylene-bicyclooct-2-ene tool on dehydrogenated C(100)2×1-type dimers using a didehydroacetylene charged 9,10-dioxide-9,10-disilaanthracene tool on a Si(100)2×1 support; shown are AM1 structures from the reaction sequence predicted by AM1 calculations to occur. The tool precursor-loaded-tool-binding-tool has undergone deprotonation from oxygens to yield the dianion favorable to this reaction sequence; the starting system is in the quintuple, predicted to be the ground state, likely due to workpiece dehydrogenation. FIG. 4.a. illustrates the approaching tool precursor-loaded-tool juxtaposed to three adjacent dimers in an appropriate configuration. FIG. 4.b. illustrates the formation of two covalent bonds (as via a Diels-Alder reaction) after the tool has been pushed 30 pm towards the workpiece relative to FIG. 4.a., FIG. 4.b. illustrates the onset of bond formation at one methylene after the tool has been pushed another 30 pm towards the workpiece relative to FIG. 4.b., while FIG. 4.d. shows formation of this bond and the onset of formation of a fourth bond between the tool precursor and the target site. FIG. 4.e. illustrates the formation of said fourth bond, while FIGS. 4.f and g. illustrate the converged geometry. FIGS. 4.h-k. illustrate bond cleavage between the tool-binding-tool carbon dimer and the tool-binding-tool to yield a target-bonded, charged, dimer binding tool. Between FIGS. 4.g and h., the support member has been pulled 270 pm with deformation of the complex. At this point, the system was subjected to two-electron oxidation (with the oxidation product still being a quintuplet system; this may be because although two electrons are being removed from the two oxygen atoms, dangling bonds of the workpiece have been saturated in the foregoing reactions.) Oxidation destabilizes the strained C—Si bonds adjacent to the oxygens, and without further retraction, forces already applied and stored as stresses within the system precipitate in tensile bond cleavage. FIGS. 4.i-j. illustrate transient intermediate structures, while FIG. 4.k. illustrates the converged geometry of the product. This desired product obtained features a carbon dimer-loaded binding tool situated on dehydrogenated C(100)2×1-type dimers, lacking hydrogens on the carbon dimer. Note that other support members could substitute for that shown, and also that the workpiece may be a molecule as small as the triadamantane derivative used in this calculation series, or a nanostructure, or the surface of a microscale colloid or microstructure, or a mesoscopic or macroscopic object.

FIGS. 4.l-n. depict synthetic schemes, alternative to that of [Gab80], for synthesizing 2,3,5,6-methylene-bicyclooct-7-ene and also especially the 7,8-dihalide or 7,8-dicarboxylic or 7,8-diacid-cycloperoxide derivatives thereof, which are capable of being activated (via photolysis of alkenyl halides by actinic radiation [e.g. 248 nm for alkenyl bromides or 260 nm for alkenyl iodides,] via reductive decarboxylation, or via thermal decomposition of carboxylic peroxides) for formation of adducts with tool-binding-tools of the present invention, such as support-adducted 9,10-dihydroxy-9,10-disila-anthracene, the dianionic dioxide derived therefrom by deprotonation of the two hydroxyl groups thereof, of 9,10-disilaketone-anthracene, whereby the support-bound, tool-loaded-tool of FIG. 4.a. may be formed. In FIG. 4.m., it should be noted that low concentrations of reactants must be maintained to avoid reaction of lithiated carhanions with acyl group substituents on the cyclic reactant. FIG. 4.n depicts formation of a complex with a support-bound metal atom of a tool precursor molecule; a similar pentaene-iron-tricrbonyl complex, not bound to any support, has been prepared and studied by x-ray crystallography [Nar79], as discussed in [Ave82]. In the first reaction set, the dihalide pentaene is formed by elimination of carboyl derivative groups, is permitted to complex with an iron atom bound to ligands which are themselves bound to a structural support, and the tool precursor complex is exposed to actinic radiation to cause photolysis of carbon-halide bonds and expose carbon dimer atoms activating these for forming an adduct with a tool-binding-tool. The resulting activated tool precursor in the resulting support bound complex is then translated into juxtaposing proximity with a suitable tool-binding tool for forming a tool-loaded-tool-binding tool; by this procedure, reaction between an activated tool precursor molecule and either another tool precursor molecule or a structural support may be avoided and the desired adduct-formation reaction facilitated. Note that the resulting dicarbon bridge may have biradical character or triple-bond character, but would in either event form adducts with suitable tool-binding-tools, i.e. by tandem radical attack on unsaturated bonds of tool-binding tool molecule in the former case and by Diels-Alder reaction in the latter case.

FIG. 5.a. illustrates the geometry of an intermediate in an addition sequence started with dimer-target-atom distances of 255 pm and with the addition tool-support pushed 150 pm towards the workpiece, where the switchbladed configuration of the carbon dimer is evident. Note that in calculation series where switchblading occurred (the case for the majority of starting positions,) the tool had to be pushed significantly further to form the second dimer-target bond than when clean dimer addition occurred in one advance of the tool towards the workpiece. This appears to be related to the evolution of alkyne-like structure which resists formation of the desired product geometry, requiring significantly greater pushing towards the workpiece to surmount this. A second dimer-target-atom bond forms after the tool is pushed a further 30 pm from this position.

FIG. 5.b. illustrates pulled 290 pm from the position where the second dimer-target bond formed. FIGS. 5.c-e. illustrates intermediates resulting when the addition tool is pulled a total of 320 pm from the position where the second dimer-target bond formed, showing clean dimer release to yield the desired product and the discharged tool which remains correctly bonded to an undamaged support member. FIG. 5.e. illustrates the tool in a form with methylene-silicon bonds which appear similar to double bonds and which have planar geometry.

FIG. 5.f. illustrates debonded product resulting when the undehydrogenated dimethyl substituted tool is withdrawn by 360 pm—a distance significantly greater than that for which dimer-workpiece-product release occurs for the dimethyl biradical substituted tool. This is the product representing a probable failure product in terms of diamond mechanosynthesis if healing does not occur upon dimer addition to debonded workpiece carbons (i.e. at adhacnt positions in adjacent troughs) but which also represents an initial step of hemitube formation, useful for fabricating devices based on this structure.

FIG. 6 illustrates the addition retraction cycle for carbon dimer addition using 7,8-didehydro-2,3,5,6-tetramethylene-bicyclo[2.2.2]oct-7-ene on a 3 dimer C(100)2×1:2 H support (neutral triplet) to a workpiece having hydrogens abstracted from target atoms along one trough but with adjacent surface atoms hydrogenated (Cdia110-66-565-66]-6H[+0m7]). FIGS. 6.a-b. illustrate Structure A of Table III. FIG. 6.c. illustrates Structure C of Table III. FIG. 6.d. illustrates Structure F of Table III. FIGS. 6.e-g. illustrate different views of the optimized structure formed after the structure illustrated in FIG. 6.d has been retracted a further 5 pm, which caused the desired tensile bond cleavages to occur resulting in reactant dimer release by the dimer addition tool.

FIG. 7 illustrates the addition-retraction cycle for adding a carbon dimer using a beta-SiC based carbon dimer addition tool. See also Table V and Table V. In this series of calculation, the dimer atoms started 252 pm from their respective target atoms. FIG. 7.a-b. illustrate the AM1 optimized structures at a point where the loaded SiC tool has been advanced towards workpiece target atoms before desired bonds have formed. FIG. 7.c-d. illustrates bond formation as the SiC tool is advanced further, a total of 30 pm from the starting position and after intersystem crossing of the septuplet to the quintuplet multiplicity. FIG. 7.c. illustrates a transient intermediate shortly after a first bond has formed and FIG. 7.d illustrates the optimized structure. (Table V, Structure V.E) FIG. 7.e-f. illustrate the optimized structure (Table V, Structure V.F) after retraction of 160 pm relative to FIG. 7.d., FIG. 7.g-h. illustrate the optimized structure after retraction of the SiC tool by 170 pm relative to FIG. 7.d. (Table V, optimized structure from Structure V.F pulled by a further 10 pm), by which point the desired tensile bond cleavages have occurred.

FIGS. 8.a-h. illustrate AM1 structures of a mechanosynthetic addition of a silicon dimer to a nonhydrogenated Si(100)2×1 surface or a nanostructure comprising the molecular structure shown which was shown to model the Si(100)2×1 surface. During initial attempts it was found that dimers markedly prefer to add to the edge of a pair of dimers of the same row rather than across dimers to form 3-membered rings, but this structure is preferred because subsequent required additions are not thereby blocked. It is expected that this mechanosynthetic scheme may require low temperature to obtain the required positional accuracy, so liquid nitrogen or even liquid helium temperatures are preferably used, although temperature used in various implementation of this embodiment of the present invention is subject to experimental optimization in any given system. The starting structure in FIG. 8.a. was obtained by positioning the silicon dimer loaded addition tool with reactant silicon atoms in the range of 258 to 260 pm from respective workpiece target atoms, holding the addition tool in place via hydrogens on the outer rings and calculating the AM1 optimized structure of the quintuplet multiplicity, which is shown. From this point, hydrogens on the outer rings of the addition tool were permitted to move normal to the plane of workpiece target atoms and optimization was reinitiated to proceed. Physically, this is the same as slowly approaching target sites and then permitting a rod or beam serving as a support for the addition tool to slide in an appropriate direction, or rather, providing an apparatus designed to permit these operations and trajectories; nanoactuators disclosed herein are suitable for this purpose. FIGS. 8.b-g. illustrate intermediates along the path from the held optimum to the optimum with sliding permitted, and FIG. 8.h. illustrates the AM1 optimum structure with tool sliding permitted roughly normal to the plane of target atoms, showing the resulting formation of the two desired 3-membered rings each comprising a silicon reactant atom and two silicon atoms of a workpiece dimer for each of two workpiece dimers. Note that added reactant dimer is in a plane perpendicular to the axis of target dimers.

Note that it is expected that the same tool would be useful for adding silicon dimers to Si(110) surfaces but that reaction is as yet to be studied; Si(100) was chosen for preliminary work because Si(110) has been found to undergo long range, 16×2 reconstructions whereas Si(100) does not undergo such long-range reconstructions, as clearly evidenced reproducibly by STM. Since it is possible that any such Si(110) surface reconstruction dereconstructs on multiple dimer addition in analogy to the healing process for C(110) on multiple dimer addition predicted by [Ste00], and also since such reconstruction, even if problematic, would likely not affect nanostructures with dimensions of 16 or fewer atoms, and would also not affect significantly hydrogenated surfaces (e.g. it is expected that various patterns of hydrogenation may serve as boundary conditions preventing this reconstruction, especially if this is used to suppress reconstructions during layer growth through mechanosynthesis at low temperatures.) Because the ground state of this addition tool in the loaded state is apparently a tetraradical, with radicals expected to localize to the silicon dimer, it is likely that addition to 110-type surfaces or related molecular structures would necessitate that at least one target atom adjacent atom be dehydrogenated to form a disilene-like double-bond or partial double bond to facilitate reactant dimer addition via a radical attack mechanism.

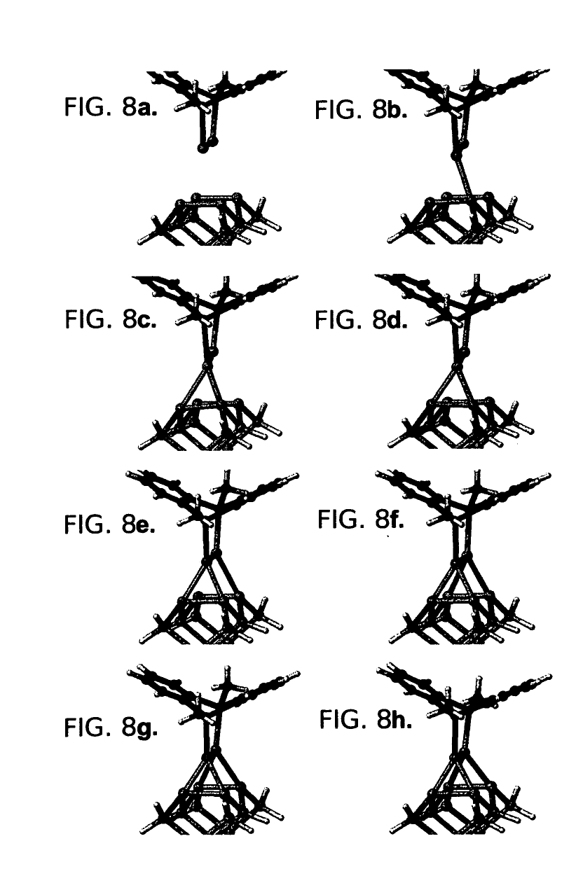

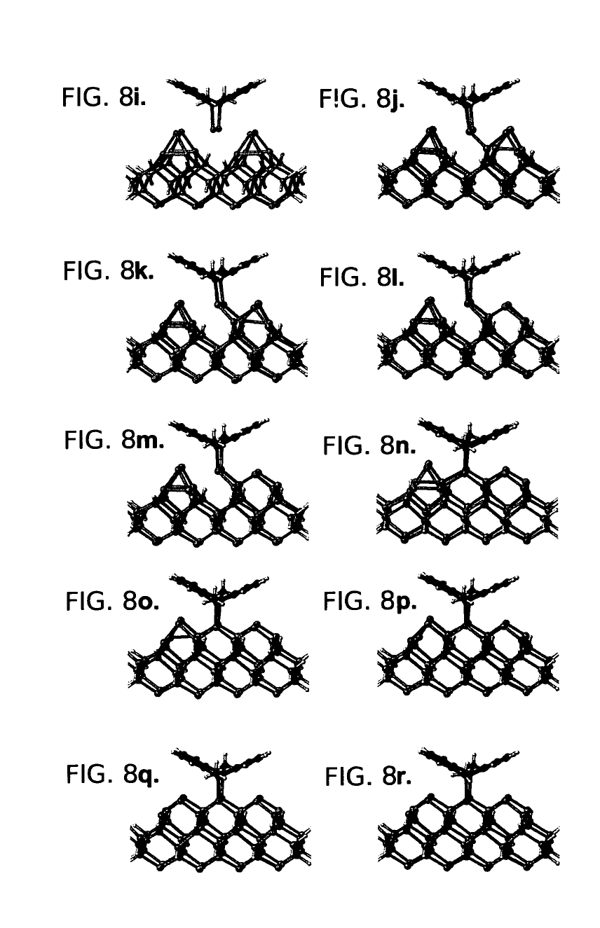

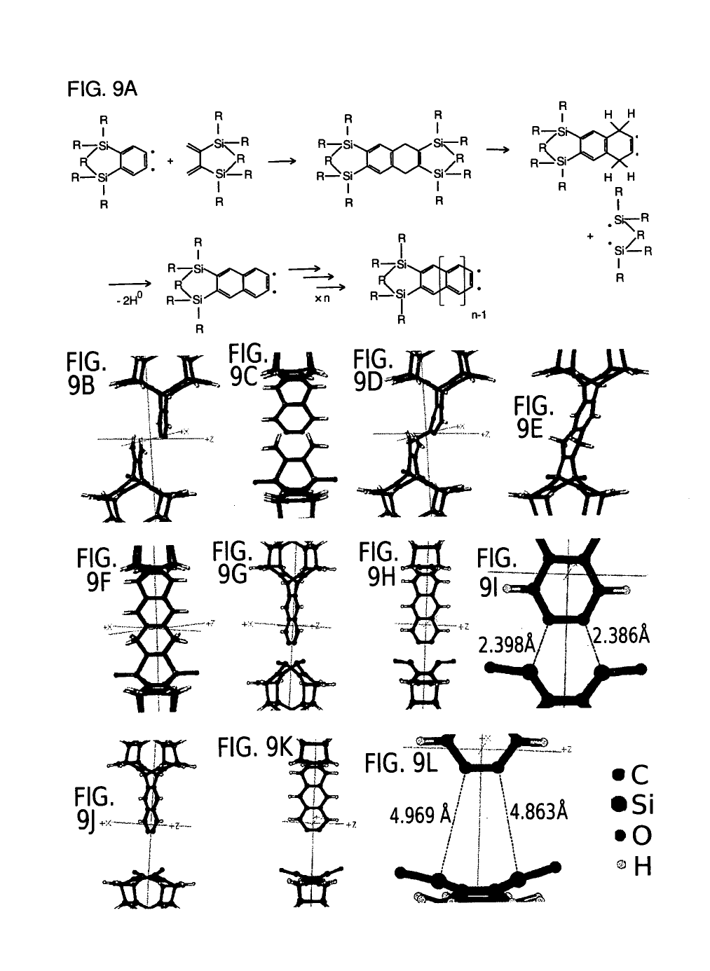

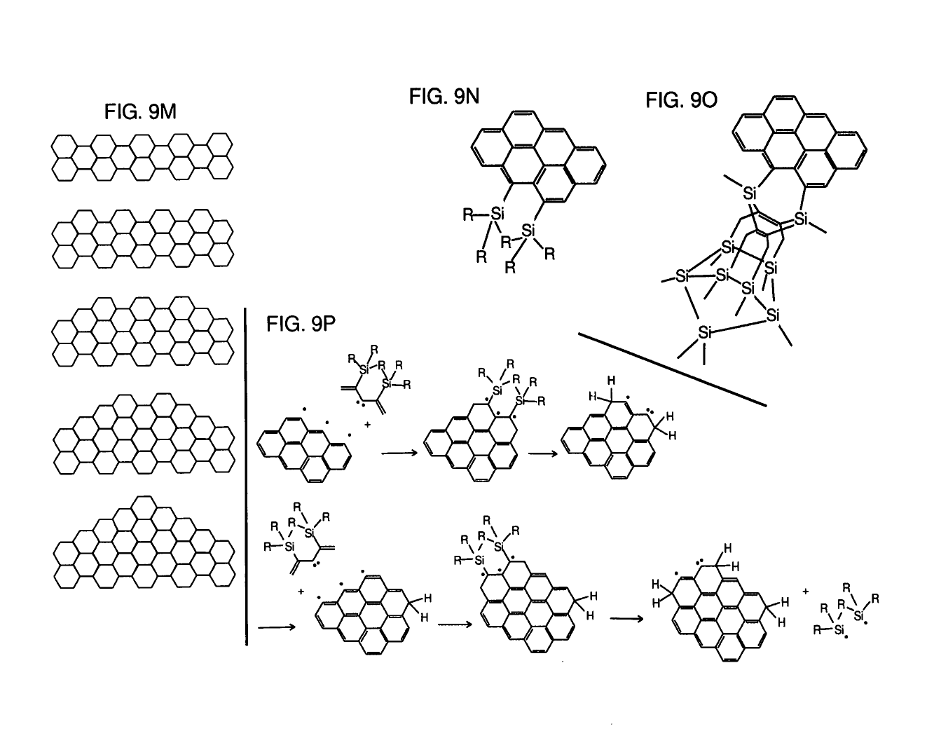

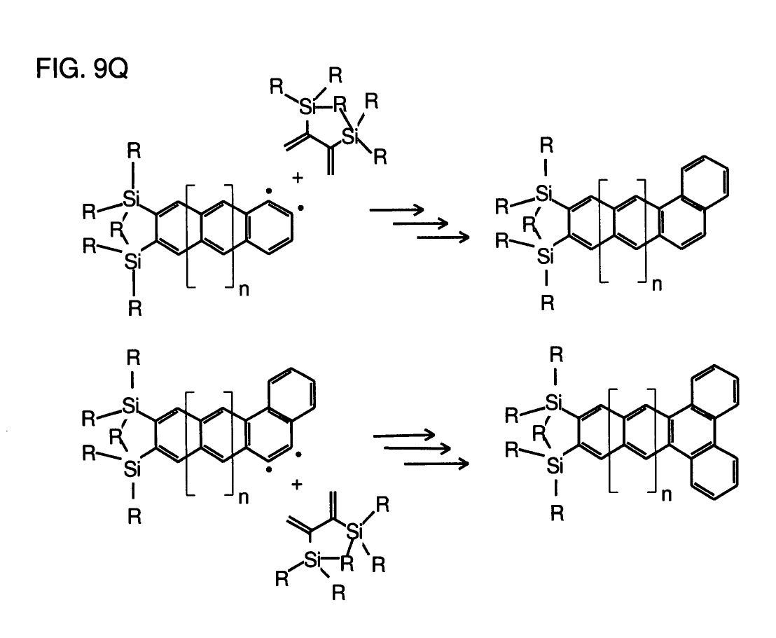

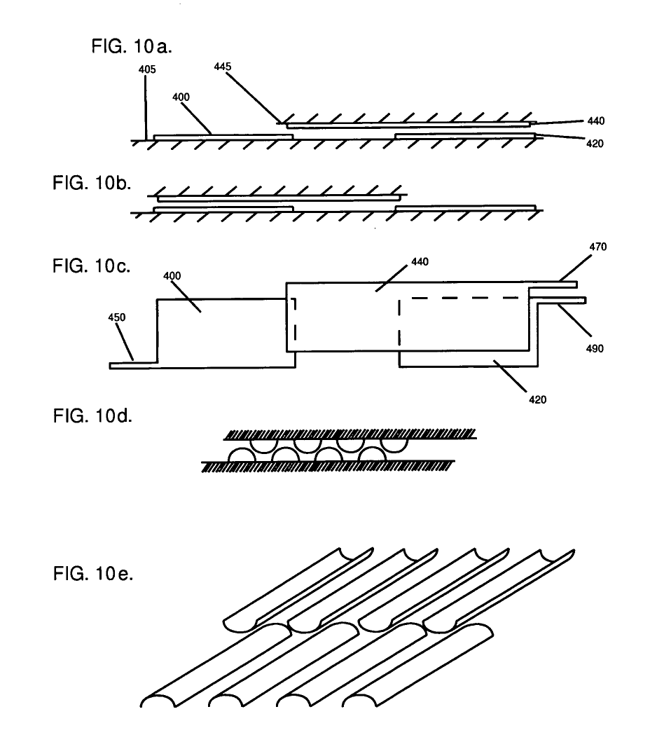

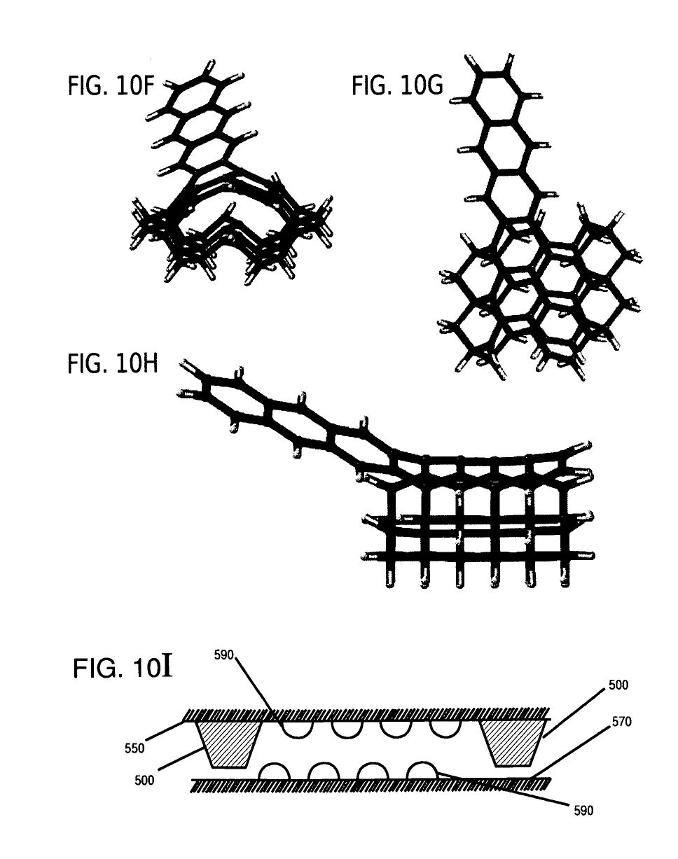

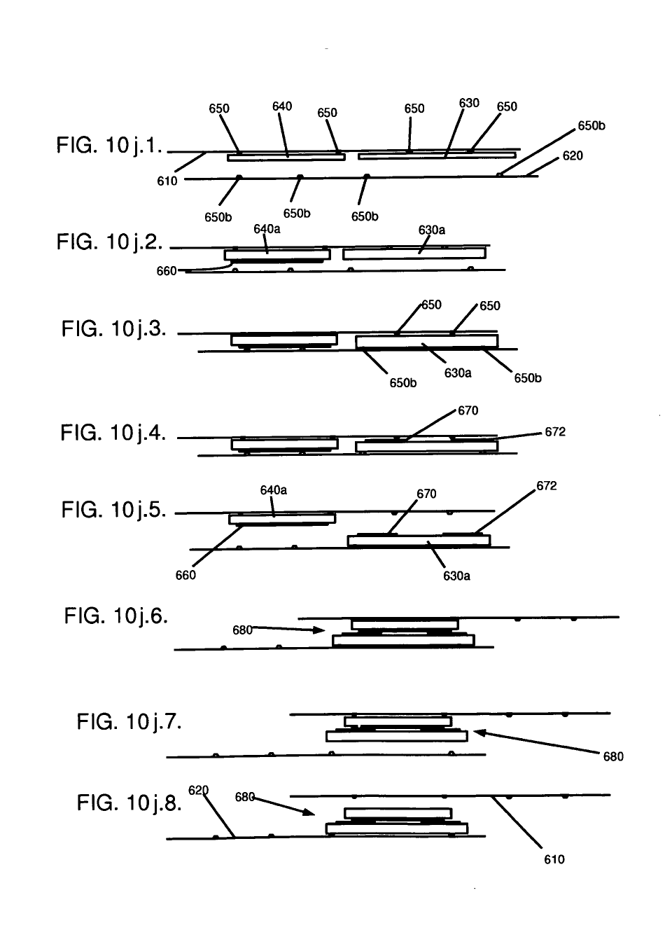

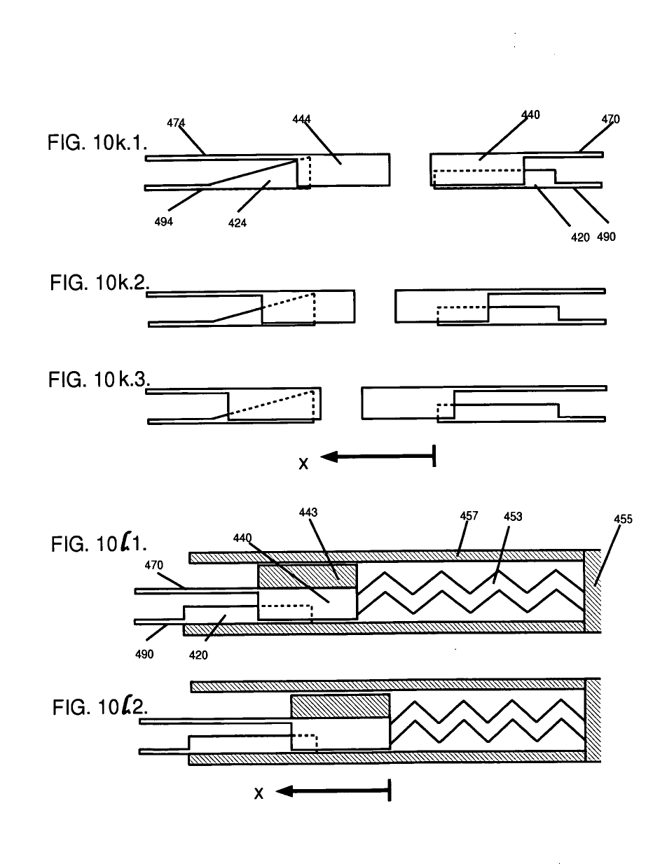

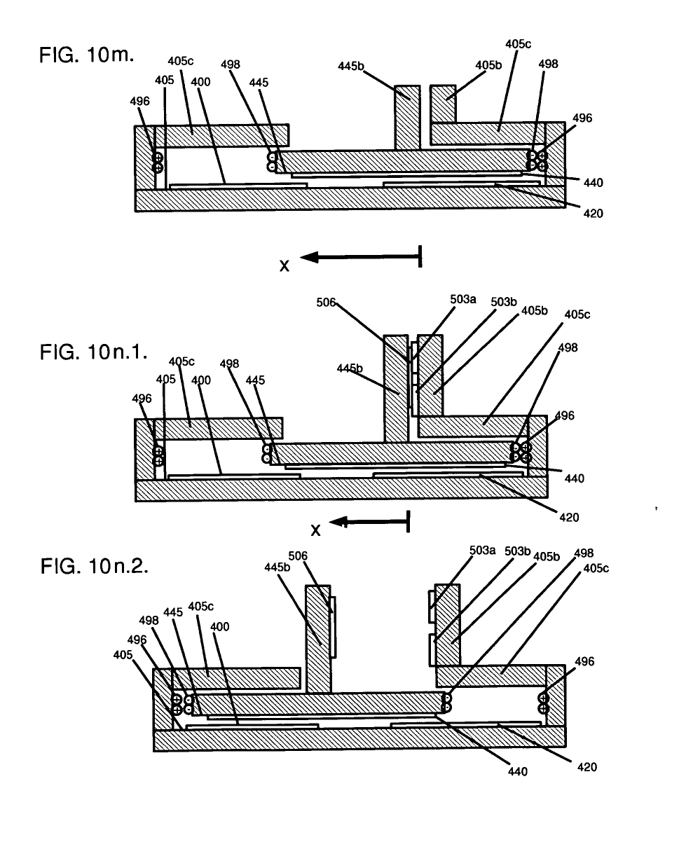

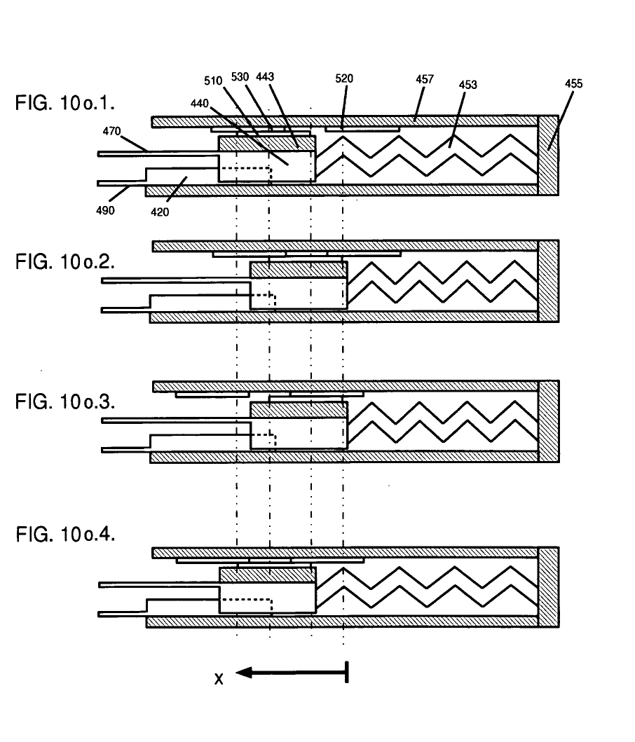

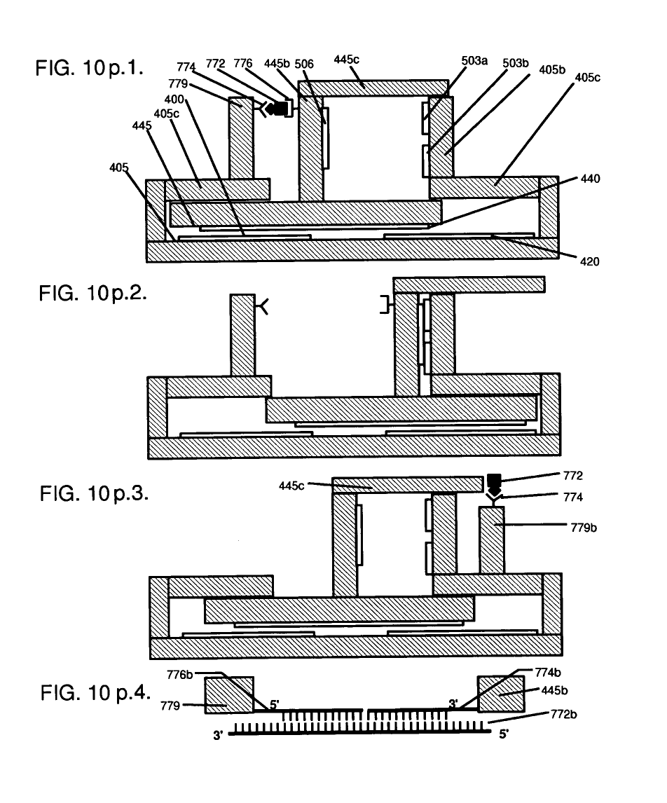

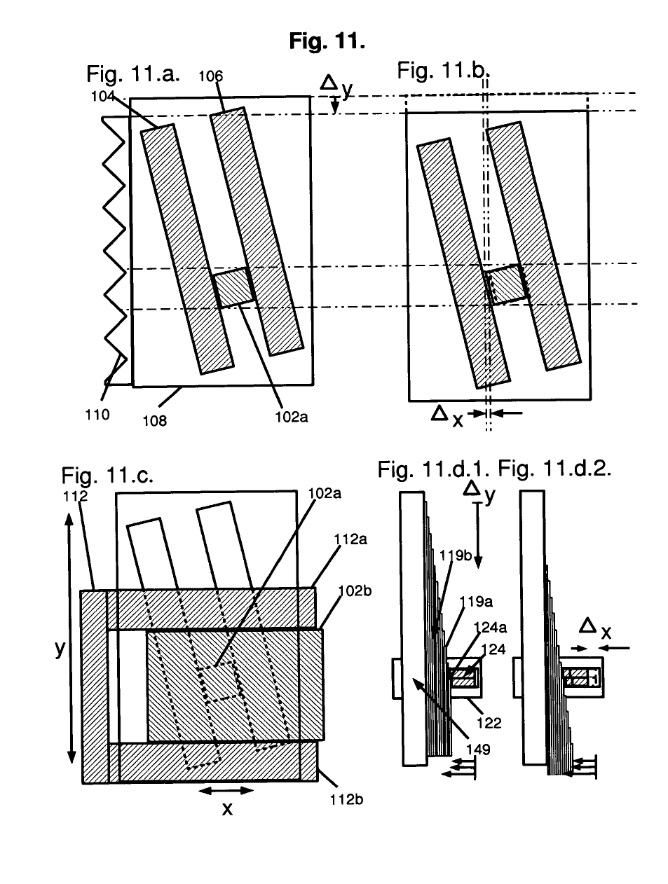

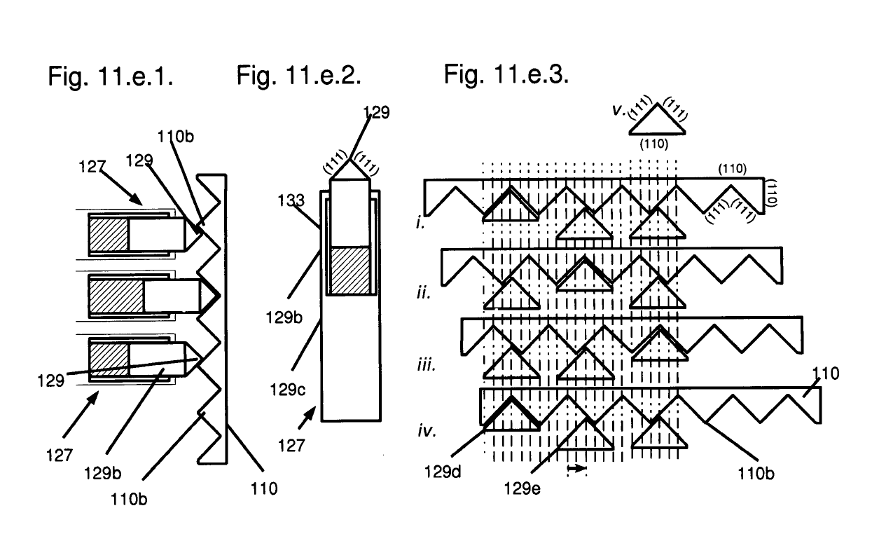

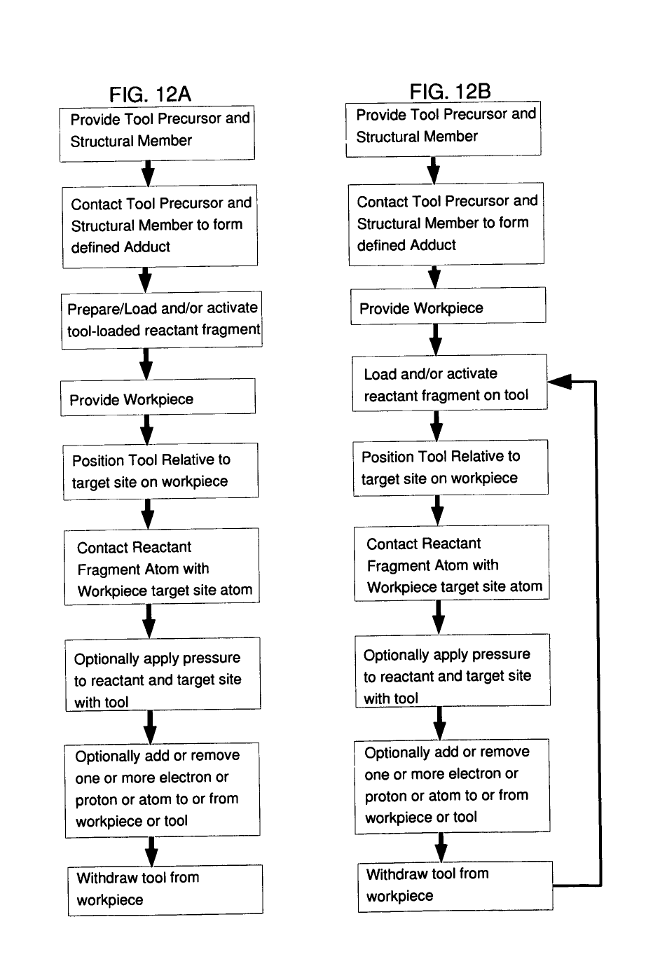

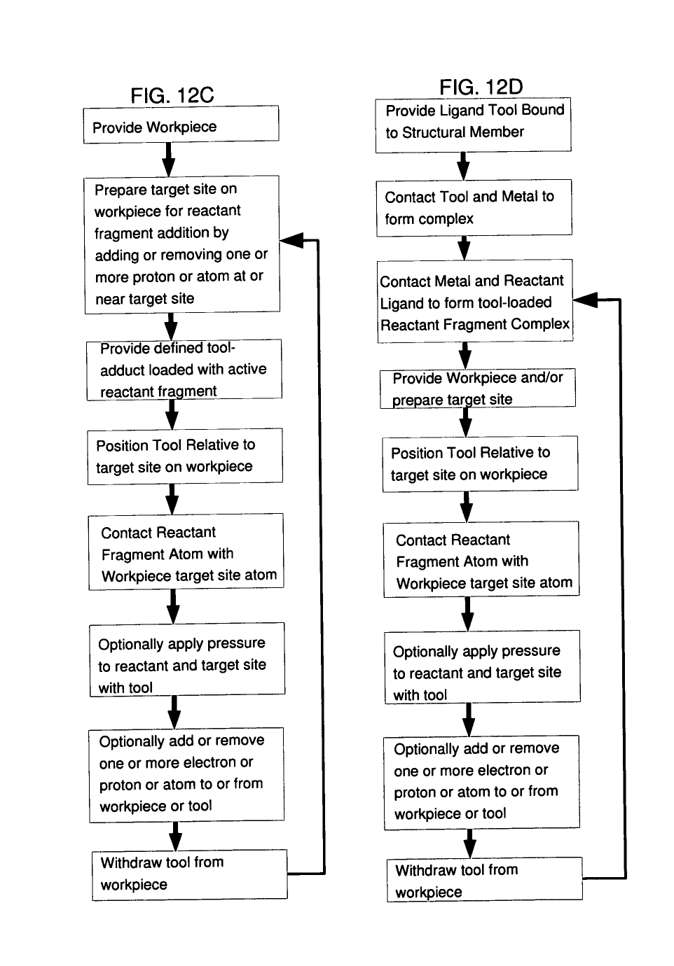

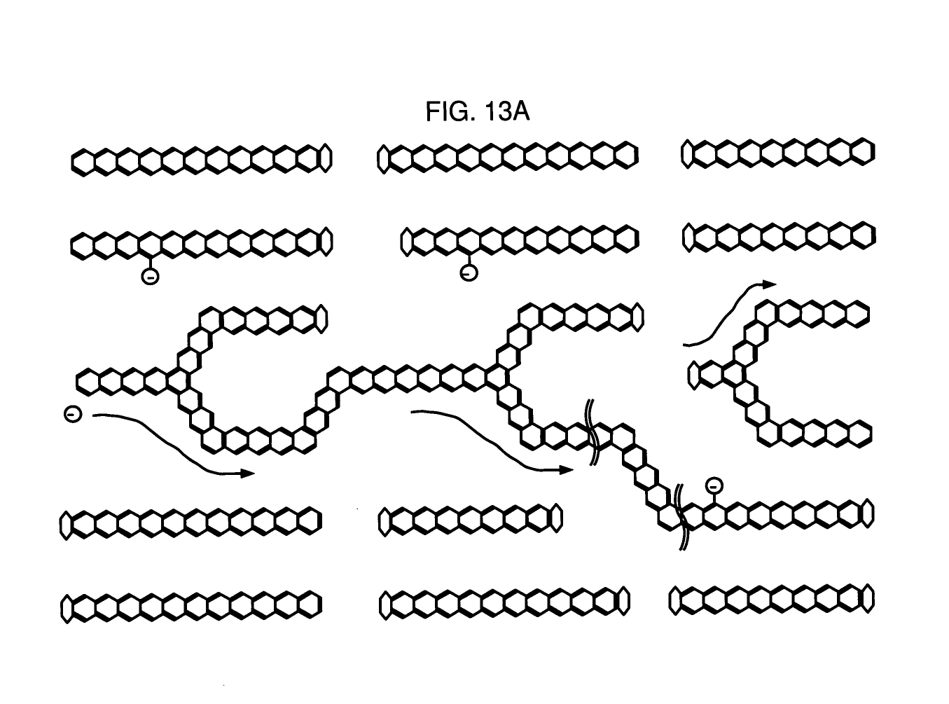

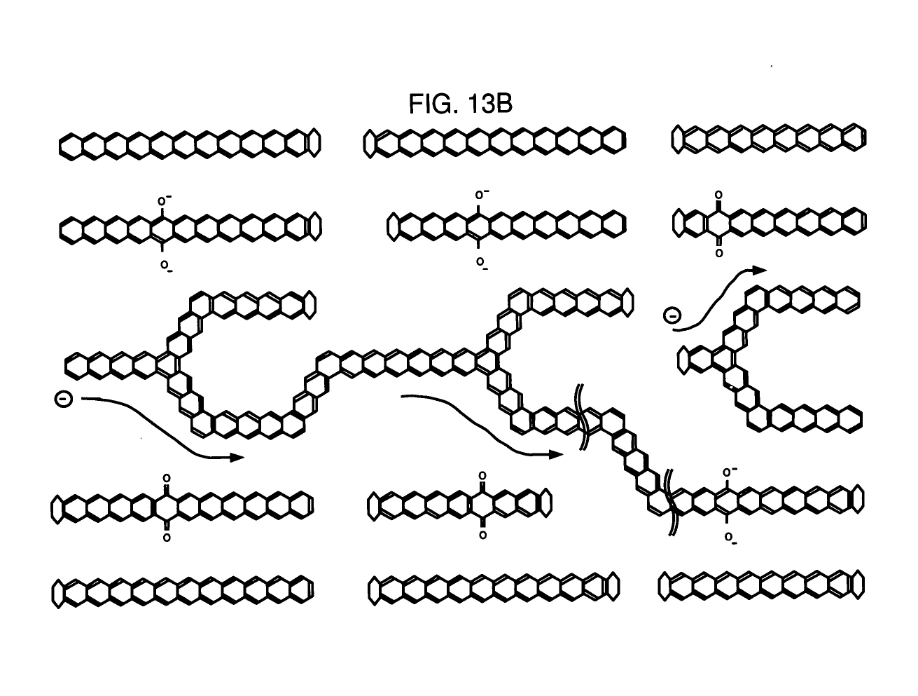

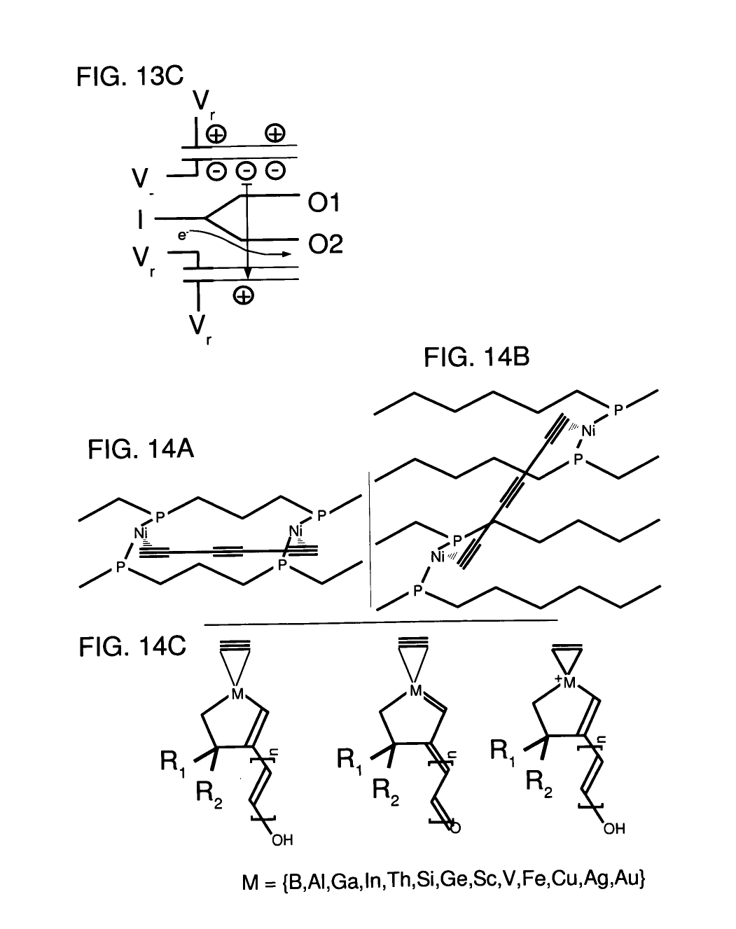

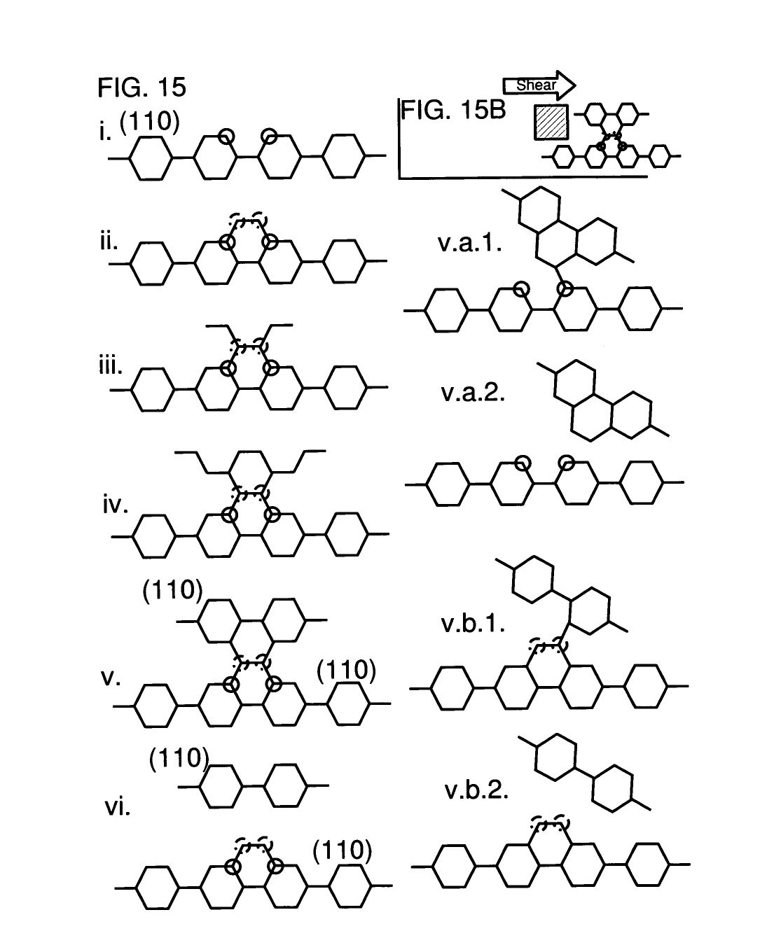

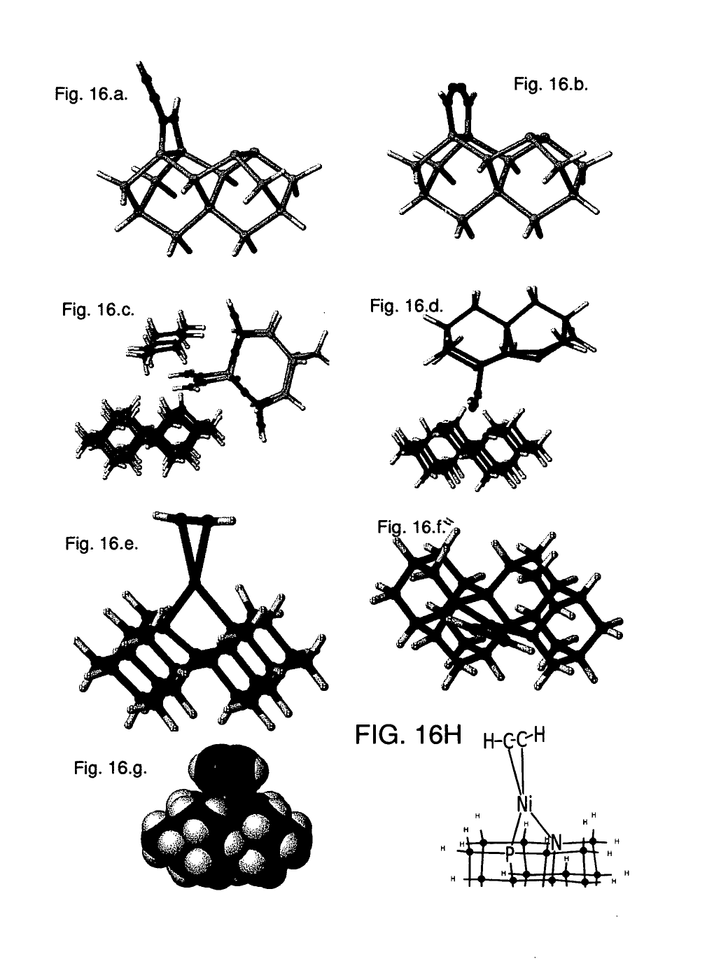

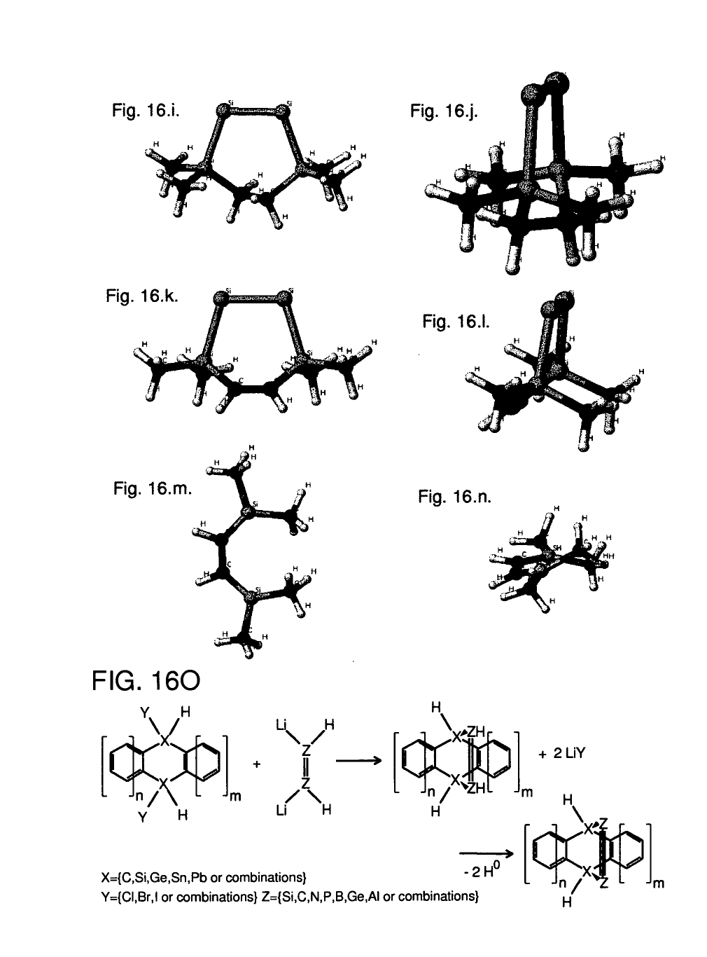

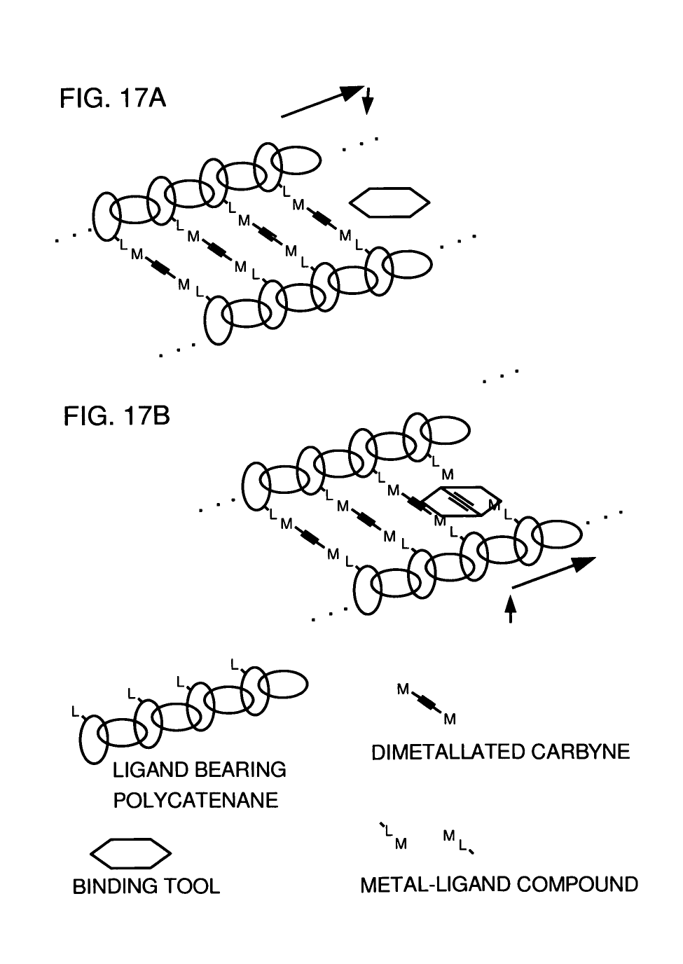

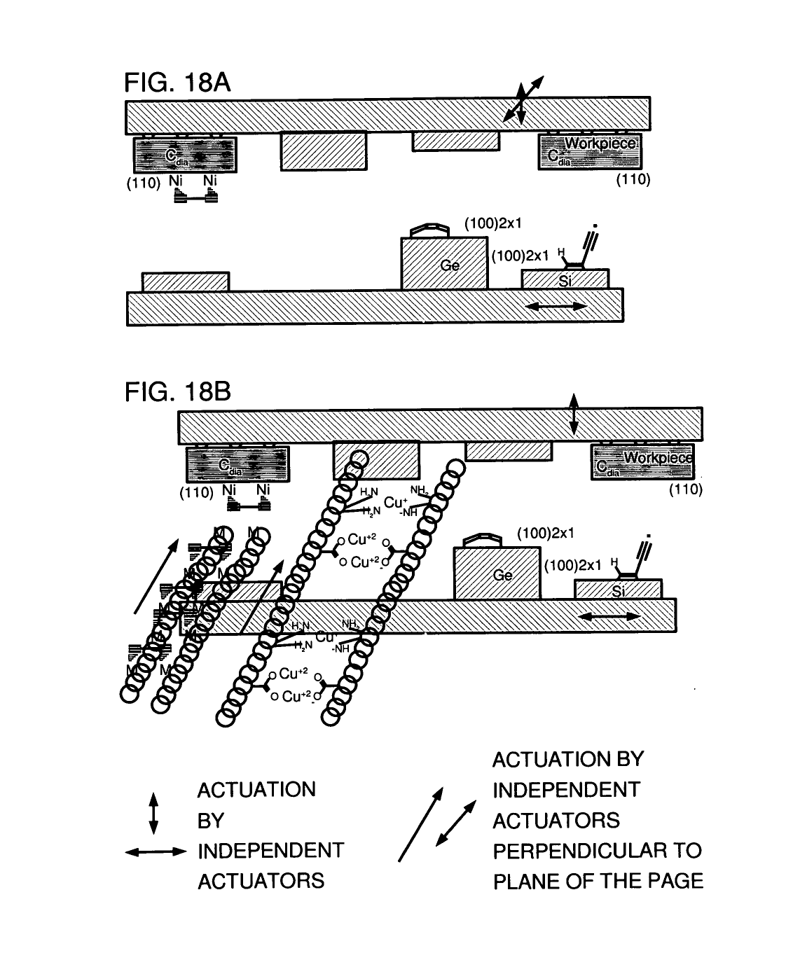

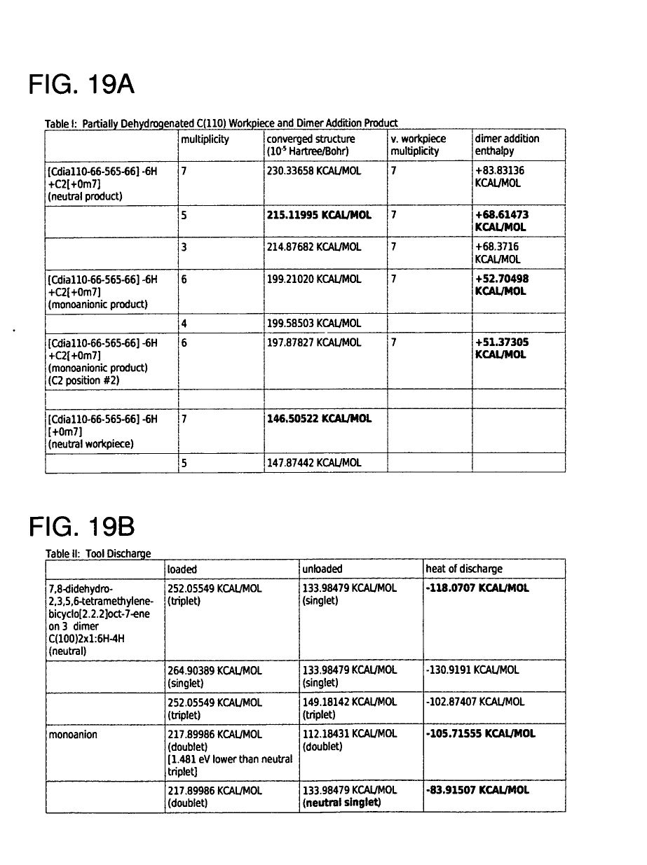

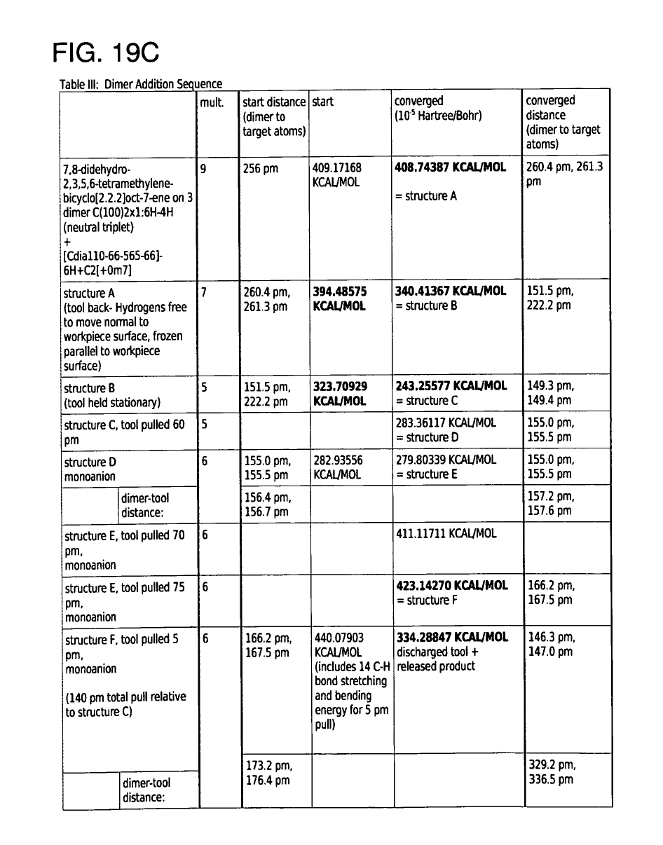

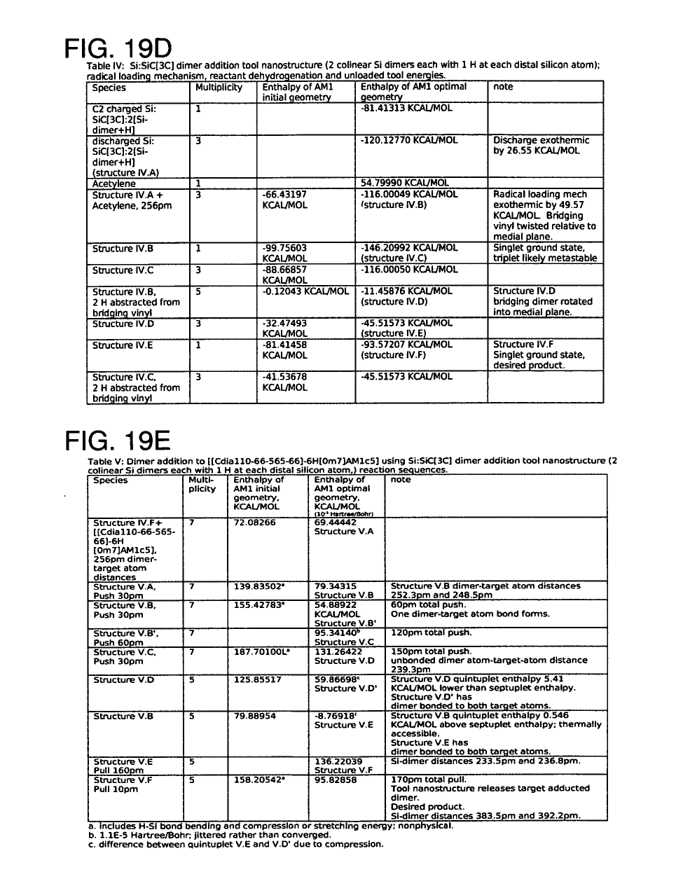

FIGS. 8.i-r. illustrate AM1 structures of a mechanosynthetic addition of a silicon dimer between two added dimer structures fabricated according to FIGS. 8.a-h. Again, this operation poses stringent positional accuracy requirements, and likely requires low temperatures for high yield of the desired product. The starting geometry in FIG. 8.i. is obtained by positioning the optimized tool with dimer atoms between 362 and 369 pm from respective target atoms and obtaining the AM1 optimum structure for the quintuplet state of the system (which is the lowest energy state for this starting geometry.) Thereafter, as in FIGS. 8.b-g., FIGS. 8.j-r. illustrate intermediate structures during the optimization from the optimum with the tool held in FIG. 8.i. as the tool is freed to slide roughly normal to the plane of any three target atoms, yielding formation of the desired two bonds between each reactant silicon atom and the respective two workpiece target atoms.

Note that multiple Si nanostructures fabricated according to the foregoing may be fabricated with contoured edges and assembled together to form porous membranes with well controlled pore sizes, structures and distributions. In one preferred embodiment, such nanostructures may be assembled together (by the nanomanipulation methods of the present invention) in water so that upon assembly, bonding by a wafer-bonding type mechanism involving oxide bridges occurs, which should be sufficiently strong for most filtration applications. Note that such bonding methods may also be used with Si nanostructures fabricated according to the present invention for other purposes as well. In another preferred embodiment, vacuum wafer bonding of clean Si surfaces may be performed to accomplish bonding of Si nanostructures or structures fabricated according to the present invention. Membranes and porous or nanoporous membranes thus may also be assembled and bonded according to this vacuum wafer bonding procedure as well. In this case, a further possible modification which may optionally be performed is to expose membranes to a gas comprising functional groups for modifying membrane surfaces or especially for modifying pore surfaces, so, for example, a membrane fabricated and assembled according to the foregoing are used to filter a gas comprising aminopropyltriethoxysilane to yield amino functionalized pores. Chromatography channels may similarly be fabricated, assembled and functionalized. Functionalized porous and nanoporous filters and chromatography channels functionalized according to the foregoing are expected to yield improved chemical selectivity in separation applications. Additionally, a significant need exists in the less developed world for inexpensive means for water filtration and purification, and filters fabricated and assembled according to the present aspect of the present invention could yield high-performance, low-cost filter membranes for use in water purification systems.

Note also that the foregoing mechanosynthesis of Si structures is expected to be amenable to modification by using addition tools binding to atomically substituted reactants, including such as those whose loading and structures are depicted in FIG. 8.p-q., whereby doped silicon structures may be fabricated, including rectifying junctions, diodes, bipolar transistors and field effect transistors and semiconductive wires may be fabricated. As is well known in the relevant arts, capacity to fabricate such devices, in particular in a form integrated in the same object, enables the fabrication of a vast array of analog and digital electronic devices including information processing and storage means and programmable computers. Accordingly, analog and digital electronic devices including information processing and storage means and programmable computers fabricated according to the present aspect of the present invention constitute distinct embodiments of the present invention. Further, such analog and digital electronic devices including information processing and storage means and programmable computers may be used to programmably control other devices, subsystems and systems of the present invention.

FIG. 9.a. depicts a scheme for mechanosynthesis of linear [n]acenes according to the present invention using a 1,3-butadiene-2,3-di-yl loaded disilicon binding tool. Note that tools are depicted only schematically and not literally, and that R-groups may represent any structures supporting reactants and seeds. In this example, the starting seed is a 4,5-benzyne-1,2-di-yl loaded onto another disilicon binding tool. The biradical character of the benzyne triple-bond is shown. Carbons at positions 1 and 4 of the 1,3-butadiene-2,3-di-yl reactant fragment are contacted with the carbons at positions 4 and 5 of the 4,5-benzyne-1,2-di-yl precursor, forming a 6 membered (1,4-diene) ring therewith; the reactant binding tool is withdrawn, breaking silicon-carbon bonds to leave carbon radicals at carbons arising from carbons 2 and 3 of the reactant butadiene fragment; hydrogens are abstracted from each of carbons arising from carbons 1 and 4 of the reactant butadiene fragment (using hydrogen abstraction tools, not shown) whereby a terminal 4,5-benzyne ring extends the precursor and is ready for subsequent addition cycles.

FIG. 9.b. through l. illustrate AM1 predicted structures for a similar addition pathway. In this sequence, seed benzyne is bound by an anthracene derived binding tool on a Si(100)2×1 support and reactant 1,3-butadiene-2,3-di-yl is bound by a 9,10-disilanone-anthracene (9,10-disila-anthraquinone) binding tool on a second Si(100)2×1 support; in loaded form, this tool is dianionic (9,10-disiloxide-anthracene;) the system of reactant, seed, tools and supports is in quintuplet spin multiplicity. In this particular sequence, hydrogens are abstracted from the newly formed 6-membered ring before reactant binding tool retraction. In FIGS. 9.b. and c. reactant and target atoms are at 267 pm internuclear distance. FIG. 9.d. illustrates an intermediate where one bond forms before a second bond. FIGS. 9.e. and f. illustrate the optimized (10⁻⁵ Hartree/Bohr) product of the addition step shown in b-d. FIGS. 9.g., h. and i. illustrate the optimized intermediate structure formed after tools are retracted by 270 pm from each other. At this point in the reaction sequence a one electron oxidation is performed, to place the system in a monoanionic sextuplet state, which causes the stretched silicon-carbon bonds to break, illustrated in FIGS. 9.j., k. and l. The reaction pathway appears more like a Diels-Alder reaction but a tandem radical attack on butadiene double-bonds cannot be excluded.

FIG. 9.m. depicts the growing-edge-shrinkage problem which arises if only dimers may be added to either a graphene structure or (viewed along Pandey chains) an adamantine (110) surface, e.g. a diamond C(110) surface.

FIG. 9.n. depicts a triply dehydrogenated graphene workpiece or workpiece seed bound to a schematically depicted binding tool, while FIG. 9.o shows the molecular structure of a tool consistent with FIG. 9.n., in particular a 2,3,5,6-tetramethylene-1,4-dimethyl-1,4-disila-cyclohexane bis-adducted (via two Diels-Alder [4+2]cycloadditions) to a support comprising a heptasila-norbornadiene structure, e.g. two adjacent Si dimers in the same dimer row of a Si(100)2×1 surface or a nanostructure comprising the corresponding structure.

FIG. 9.p. depicts the mechanosynthetic addition scheme for forming graphenoid molecules or nanostructures while avoiding the growing-edge-shrinkage problem depicted in FIG. 9.m. Here, the binding tool bound to the graphenoid workpiece is omitted for clarity. The addition tool is loaded with 3,3-didehydro-penta-1,4-diene-2,4-di-yl, and carbons 1, 3 and 5 are contacted with radicals on the graphenoid workpiece to form 2 fused 6-membered rings, whereafter the addition tool is withdrawn with cleavage of bonds between the tool and the reactant fragment derived atoms of the intermediate product. Not shown are hydrogen abstraction of four hydrogens and reductive hydrogen addition of two hydrogens prior to the subsequent 3,3-didehydro-penta-1,4-diene-2,4-di-yl addition, but the required hydrogenation state of the graphenoid workpiece, which entails the required abstractions and additions, is shown. 3,3-didehydro-penta-1,4-diene-2,4-di-yl is added and the addition tool is withdrawn.

FIG. 9.q. depicts the mechanosynthetic addition scheme for forming bent or branched acene structures. Ab oligo- or poly-acene workpiece terminally dehydrogenated at carbons 1 and 2 is provided and contacted with a carbons 1 and 4 of 1,3-butadiene-2,3-di-yl loaded on an addition tool whereafter the addition tool is withdrawn with cleavage of bonds between the tool and the reactant fragment derived atoms of the intermediate product. Subsequently, in the particular sequence shown, two reductive hydrogen additions are performed at radical sites on the workpiece intermediate, two hydrogens are abstracted from the workpiece intermediate at the sites shown as radicals, and the workpiece radicals are contacted with carbons 1 and 4 of 1,3-butadiene-2,3-di-yl loaded on an addition tool whereafter the addition tool is withdrawn with cleavage of bonds between the tool and the reactant fragment derived atoms of the workpiece product. Subsequent hydrogen abstractions, 1,3-butadiene-2,3-di-yl additions and hydrogen additions and sequences thereof permit the fabrication of arbitrarily branched oligo- and poly-acene structures.

FIG. 10.a. depicts a sectional view of a 3-conductor actuator. (Note that unless otherwise specified herein, conductive regions may comprise semiconducting materials having at least slight conductivity; also unless specifically noted otherwise, although hemitubes represent a convenient conductive structure, other conductive and semiconductive materials including especially graphene may serve to form conductive regions herein.) Conductive region 440 situated on structural support 445 is facingly juxtaposed to conductive region 420 situated on structural support 405 and is oriented in a plane which faces conductive region 400 situated on structural support 405. A preferred arrangement (the case for non-contact actuator devices) resembles a parallel plate capacitor with one plate free to slide to face one of at least two conductive regions serving as multiple opposed plates on a common facing support. For non-contact devices, device output force depends on incremental increase in area of 440 facing 420 during translation and operating potential difference voltage. Operating voltage is limited by field emission, which depends on the lowest work function (or lowest ionization potential) of any said conductive region, and also depends on applied electrical field strength, which depends on the gap separating 440 and 420. Conductive region 440 is drawn by electrostatic attraction to whichever of 400 or 420 has a greater electrical potential difference from 440. The device translated to the position depicted in FIG. 10.a. corresponds to the situation with the largest electrical potential difference between 440 and 420 and a lesser difference or no difference between the electrical potentials of 440 and 400.

FIG. 10.b. depicts a sectional view of the 3-conductor actuator of FIG. 10.a. with structural support 445 translated relative to the position of structural support 445 in FIG. 10.a. as results from actuation. Conductive region 440 situated on structural support 445 is facingly juxtaposed to conductive region 400 situated on structural support 405, and is oriented in a plane which faces conductive region 420. The device translated to the position depicted in FIG. 10.a. corresponds to the situation with the largest electrical potential difference between 440 and 400 and a lesser difference or no difference between the electrical potentials of 440 and 420.

FIG. 10.c. depicts a view rotated 90° from that in FIG. 10.a. showing a top view of the planes of conductive regions 400, 420 and 440 overlapped, with other members omitted for clarity, and additionally shows terminals for electrical connections. Terminal 450 provides for electrical communication with conductive region 400, terminal 490 provides for electrical communication with conductive region 420, and terminal 470 provides for electrical communication with conductive region 440.

FIG. 10.d. depicts a cross-sectional a C(100) hemitube based embodiment of the actuator of FIG. 10.a. In this particular variant, hemitubes situated on facing surfaces are in very close proximity permitting interdigitation and providing constraint to linear sliding motion of the actuator. In this variation, current may flow between hemitubes on different supports, but contact forces also contribute to device operational forces; in the absence of applied electrical potential, contact forces will favor maximization of contact area and therefore this structure may also serve as a constant-force spring in analogy to MWCNT based devices developed by the Zettl group.

FIG. 10.e. depicts an view of the hemitubes of FIG. 10.d.; supports and surfaces are omitted for clarity.

FIGS. 10.f., g and h illustrate different views of a single hemitube fabricated on a C(100) surface with an anthracene terminal adducted to a terminus thereof. Structures shown are geometries predicted to be an AM1 optimum. Other than on the anthracenyl substituent, hydrogens shown merely terminate the structure in calculations; in reality these would be replaced by bonds to the corresponding extended structure (i.e. bulk diamond, further extension of the hemitube, and (110) surface).

FIG. 10.i. depicts a cross-sectional view of a hemitube actuator featuring spacing members 400 for enforcing a gap between two juxtaposed conductive regions each comprising hemitubes 590. Shown is a variant with two spacing members 400 situated on the same surface 550.

FIG. 10.j. depicts a fabrication and assembly sequence for producing a nanoelectromechanical actuator according to the present invention. FIG. 10.j.1. depicts a first support 610 with binding tools 650 situated thereupon bound to seed slabs 640 and 630. (In the particular embodiment illustrated, binding tools are of a composition capable also of serving as addition tools, although it is possible to situate distinct addition tools and binding tools on each support member.) FIG. 10.j.2. depicts the arrangement of FIG. 10.j . . . 1. after mechanosynthetic additions expanding slabs 640 and 630 yielding expanded slabs 640a and 630a, and after conductive regions 660 (e.g. comprising hemitubes) have been fabricated on slab 640a; here, addition tools 650b for mechanosynthetic additions are situated on a second support 620. FIG. 10.j.3. depicts transfer of slab 630a lacking a conductive region thereon transferred to binding tools 650b on second support 620. FIG. 10.j.4. depicts the fabrication of conductive regions 670 and 672 on slab 640b transferred in FIG. 10.j.3. FIG. 10.j.5. depicts retraction of said first support 610 from said second surface 620 after conductive regions fabrication of FIG. 10.j.4. FIG. 10.j.6. depicts translation of said first support 610 relative to said second support 620 to facingly juxtapose conductive region 660 of said first slab 640a with conductive regions 670 and 672 of said second slab 630a. FIG. 10.j.7. depicts withdrawal of said first support 610 from said second support 620 with release of slab 630a by binding tools 650b situated on support 620; in the particular embodiment illustrated, adhesive contact forces exceed the aggregate force with which binding tools bind at least one slab to the respective support. FIG. 10.j.8. depicts transfer of the nanoelectromechanical actuator assembly 680 from said first support 610 to said second support 620.

FIG. 10.k. depicts a novel analog nanoelectromechanical positioner which may be fabricated and assembled according to the present invention, as depicted in FIG. 10.j. for nanoelectromechanical actuators. Support members omitted for clarity, including support members constraining motion to one dimension, but conductive regions 440 and 444 are maintained at a fixed distance from eachother, as is the case having both of these on the same first support member, and conductive regions 420 and 424, likewise, are maintained at a fixed distance from eachother, as is the case having both of these on the same second support member. Variable positional control is achieved by varying a dimension of at least one conductive region, preferably in a direction perpendicular to the dimension along which controllable positioning is desired. Conductive region 444 juxtaposingly faces variable width conductive region 424 situated on a different support. Terminal 474 provides for electrical communication with conductive region 444, and terminal 494 provides for electrical communication with conductive region 424. Other features are numbered as in FIG. 10.a., With a fixed electrical potential difference applied between terminals 474 and 494, a variable potential difference applied between terminals 470 and 490 is reduced in FIG. 10.k.2. from FIG. 10.k.1. yielding translation in the x direction of conductive regions 440 and 444 relative to conductive regions 420 and 424 (and therefore also relative translation of the support members [not shown] of these conductive regions, respectively.) Similarly, further reduction of said variable potential difference applied between terminals 470 and 490 causes further translation of conductive regions 440 and 444 relative to conductive regions 420 and 424 with corresponding relative translation of associated support members. During the course of the translation in the x direction depicted in FIG. 10.k.1, 10.k.2 and 10.k.3, the area over which conductive regions 444 and 424 face eachother normal to their respective surfaces increases but at a diminishing rate; concomitantly, the area over which conductive regions 440 and 420 face eachother normal to their respective surfaces decreases at a constant rate. Thus in the course of translation in the x direction, capacitance between 440 and 420 decreases linearly, while capacitance between 444 and 424 increases at a slower rate. With a fixed potential applied between terminals 474 and 494, charge on conductive regions 444 and 424 will vary directly with the capacitance between these, which in turn varies differentially with the width of 424 at the point where 424 faces the border of 444. A variable potential applied between terminals 170 and 490 will yield charge on conductive regions 440 and 420 according to the capacitance between these, which varies monotonically. This situation balances increasing capacitance and constant potential for 444 and 424 yielding increasing stored charge against decreasing capacitance and decreasing potential for 440 and 420 yielding decreasing stored charge; since 444 and 440 are free to move in the x direction according to attractive forces between 444 and 424 balanced against 440 and 420. The system has two variables in its operation, the independently variable potential V₄₇₀₋₄₉₀ and the dependent variable translation x, yielding electrically controlled positioning of the support at fixed distance from 444 and 440 (e.g. a support on which these are situated) relative to the support at fixed distance from 424 and 420 (e.g. a support on which these are situated.)

FIG. 10.l. depicts an alternate embodiment of the present invention of an electrically controlled analog positioner for translating structural member region 443 relative to structural member 455, comprising a variable capacitor (having plates 440 and 420) and a compliant member 453 (e.g. a spring.) Conductive region 420 and structural support member 455 are in a fixed relative configuration (e.g. as occurs when 420 is situated on a portion of 455) whereas the relative motion of conductive region 440 is constrained by structural member 457 but free to move in the x direction relative to 420 and 455, energetically restrained by the action of compliant member 453. Conductive region 440 is in a fixed configuration with structural member 443 (e.g. as occurs when 440 is situated on a portion of 443.) When there is no potential difference between terminals 470 and 490, compliant member 453 is free to relax to its equilibrium extension. As an electrical potential difference is applied between terminals 470 and 490, charge separation evolves between 420 and 440 causing an attractive force between these. Because it is free to move only in the x direction in response to said force, 440 translates in the x direction relative to 420, taking structural member 443 along. To a fair approximation, the x component of the forces (i.e. the first derivative of stored electrical energy with respect to x) between 440 and 420 is a linear function of the potential difference between these, and is approximately constant with respect to displacement x. Since motion of 440 relative to 420 is constrained to motion in the x direction, 440 responds by translation in the x direction until this force balances the force of compliant member 453. If compliant member 453 at least approximately obeys Hooke's law, every unique positive x extension exerts a unique restoring force on 440. To obtain displacement x of compliant member 453, the electrical potential difference between 440 and 420 is adjusted to yield an equal and opposite force to that exerted by 453 at that displacement x; forces balance at unique displacements for every unique electrical potential difference between 440 and 420, whereby a unique relation is achieved between the independent variable potential difference between 490 and 470, V₄₉₀₋₄₇₀, and dependent variable relative displacement x. Because of fringing field effects, Coulombic screening and other effects, this relation is best characterized empirically for each given design. The progression between FIG. 10.l . . . 1 and FIG. 10.l . . . 2 corresponds to reduction of the applied potential from an initial value intermediate in the functional range of the device depicted, to zero, so that FIG. 10.l . . . 2 depicts the system with compliant member 453 at equilibrium.

In FIGS. 10.m. through o. spacing members for preventing contact between conductive regions are not shown since these would generally not be situated in the plane of cross-section; optional spacing members such as 500 in FIG. 10.i. are preferably included in the devices depicted.

FIG. 10.m. schematically depicts an nanoactuator including structural a member surrounding an actuating structural member, which in operation translates structural member 445b relative to 405b. This embodiment additionally features positively charged groups 496 and negatively charged groups 498, which together provides for two stable states even in the absence of electrical potentials applied to any of conductive regions 400, 420 or 440, due to Coulombic forces between groups 496 and 498 when actuation brings either set of these into close proximity. Note that other relative arrangements of charged groups are possible.

FIG. 10.n. schematically depicts a nanoactuator similar to that in FIG. 10.m. adapted for application as a nanoelectromechanical switching device or nanorelay. This device features conductive regions 503a and 503b situated on structural member 405b and conductive region 506 situated on structural member 445b. FIG. 10.n.1. shows this nanorelay in the closed or “on” configuration with contact between 503a, 506 and 503b, such that electrical communication occurs between 503a and 503b, while FIG. 10.n.2. shows the open or “off” configuration. Various features of devices of this class permit these to be used in digital logic circuits. When optional charged groups 496 and 498 are included in the device, the resulting bistability permits this device to serve as a 1-bit memory device or an R—S flip-flop. Additionally, since there is no electrical communication between conductive regions 400, 420 and 440, and conductive regions 503a, 506 and 503b, the property of electrical isolation between actuation control and the signal switched permits signals switched by this device to be wired together to yield a “wire-OR” logic function, and also permits signal amplification if an electrical signal provided on 503a or 503b (or 506) is of greater voltage or current than that required for actuation. An inverter device or NOT gate is realized when an actuation signal applied to 400 opens the switch between 503a and 503b, while an intermediate bias potential applied to 420 causes actuation causing contact between 503a, 506 and 503b when said signal applied to 400 is removed or reduced (e.g. 440 is held at 0 V, 420 at 0.5 V and an input signal applied to 400 may be at logic levels of either true, represented by +1V, or false, represented by 0 V, and 503a is held at +1 V; +1 V at 420 causes translation of 445b away from 405b, open-circuiting 503b from 503a such that 503a no longer provides a “true” signal to 503b, whereas with 0 V on 400, attraction between 420 and 440 translates 445 toward 405b closing contact between 503a, 506 and 503b whereby a “true” signal is communicated to 503b.) Combinations of two NOT gates with outputs 503b wire-ORed together yields an output which is the logical AND of the inputs of the two NOT gates; one skilled in the art of digital logic circuit design will realize that all of the prerequisites for computational universality may be realized by various appropriate combinations of such devices. The particular arrangement shown provides for electrical contact to be made between 503a and 503b without either of these moving relative to eachother; a simplified variant could omit 503b and provide for electrical communication between 503a and 506 either if relative translation between terminals across which switching is desired may be tolerated or if a flexible wire is provided between 506 and a fixed terminal. A different mode of use of this device yields the function of an AND gate: 420 and one of 503a and 503b serve as the inputs and the other of 503a and 503b serves as an output (not buffered from the other of 503a and 503b;) in this case, a potential applied to 440 and 400 set the threshold for 420 to be considered true (and in this regard this same device may also serve as a crude analog comparator.) For example, AND functionality with 420 and 503a as inputs is realized with 440 held at 0.3 V, 400 held at −0.1 V and 420 either “true” at 1 V or “false” at 0 V; in this case, 503b reflects the state of 503a. This same device may also yield a buffer isolating an output signal from an input signal; with the foregoing exemplary AND gate, input 503a is held at a “true” logic level, such that 503b is true when 420 is true and 503b is false when 420 is false; this arrangement may also yield signal amplification where power required on 420 for operative switching is less than power provided on 503a and carried across 506.

Note that computational universality enabled by the foregoing and other devices disclosed herein permits devices of the present invention to be assembled together into useful information processing and storage means, including programmable digital computers and programmable digital control circuits, as is widely known; such. information processing and storage means may be operatively coupled to electrically control actuators and positioners of the present invention in communication with supports, platform moieties and/or molecular tools of the present invention, and thus may provide for the automated control of fabrication, manipulation and assembly of devices and systems according to the present invention, and in addition may also be incorporated as subsystems into devices or systems fabricated or assembled according to the present invention to programmably control the operation thereof. Furthermore, in combination with the foregoing, devices, subsystems or systems may additionally comprise one or more sensing means such as the analyte detectors disclosed herein or relays or nanorelays or actuators disclosed herein used as position detectors or sensors, meeting the requirements of the definition of robotic devices, subsystems or systems.

FIG. 10.o. schematically depicts a nanoactuator similar to that in FIG. 10.l. adapted for use as a nanorelay featuring sliding contact of conductive members 510, 520 and 530. Other features are numbered as in FIG. 10.l. FIG. 10.o.1. and o.2. depict two states of this device, while FIG. 10.o.3. shows a similar device which may also translate 443 to the position shown in FIG. 10.o.1. but having 520 and 530 situated in positions such that when compliant member is 453 relaxed to equilibrium position (shown in FIG. 10.o.3.,) 510 does not contact 520, but when actuated (shown in FIG. 10.o.4.,) 510 contacts both 520 and 530. Preferably, operational parameters are selected such that energies and forces due to electrical potentials between 510 and 520 and 530 are small enough to not affect actuation by energies and forces between 420 and 440 and also 453. This may be facilitated by requiring that the area of 510 is significantly smaller than the minimum area of 420 which faces 440, for example. This device may additionally serve as a NOT gate, a buffer, an XOR gate or an XNOR gate depending on the connections made to this device and the relative positions of 510, 520 and 530. XOR or XNOR functionality is realized when terminals 470 and 490 serve as inputs and one of 520 and 530 is wired to a true signal and the other of 520 and 530 serves as an output signal; the relative positions of 520 and 530 shown in FIG. 10.o.1. corresponds to XNOR functionality, while the relative positions of 520 and 530 shown in FIG. 10.o.3. corresponds to XOR functionality. Note that like the device illustrated in FIG. 10.n., the device illustrated in FIG. 10.o.3. may be wired to function as an AND gate (470 and 530 as input signals, 520 as an output signal, 490 held at 0 V bias; with 470 and 530 at +1V, actuation brings 510 into contact with 520 while 510 remains in contact with 530 causing electrical communication between 530 and 510 such that 530 then carries a +1 V potential and hence a true logic level, while if either 470 or 530 carries a false logic level of 0 V, 520 will not carry a +1 V signal.)

FIG. 10.p. schematically depicts a device similar to that depicted in FIG. 10.n. adapted for detection of an analyte, e.g. devices for performing biomolecular and chemical assays. Analyte 772, if present, may first bind either 774 or 776 at random. Presence of analyte 772 capable of being bound by ligands 774 and 776 causes colocalization of structural member 779 to structural member 445b when translatable member 445 is either free to translate or is caused by an electrical potential difference between 400 and 440 to translate towards 779 such that 774 and 776 are in sufficient proximity to simultaneously bind 772. Thus a suitable initial condition has the electrical potential of 400, 450 and 440 caused to be equal to eachother after 445b has initially been translated to 405b exposing 774 and 776. To test for simultaneous binding of 772 by 774 and 776, the electrical potential of 400 is adjusted to match the electrical potential of 440 if it differs, and the electrical potential difference between 440 and 420 is gradually increased. When 772 is present and simultaneously bound by 774 and 776, as in FIG. 10.p.1., translation of 445b is restrained until a sufficient electrical potential difference between 440 and 420 causes sufficient force to rupture binding between either 774 and 772 or 776 and 772, whereupon 445b translates to 405b and contact occurs between 506 and 503a and also 506 and 503b whereby electrical communication is effected between 503a and 503b. When 772 is absent, a lower potential difference between 440 and 420 suffices to cause 445b to translate towards 405b causing contact to occur between 506 and 503a and also 506 and 503b whereby electrical communication is effected between 503a and 503b, as in FIG. 10.p.2. Preferably, 405c and 445 and also 445c and 405b are sufficiently close to exclude any molecules from an analyte fluid (liquid solution or gas) from reaching actuator conductive regions and detection signal conductive regions 503a, 503b and 506 (although variations of this device could be designed for operation with contact between these conductive regions and analyte media.) In preferred embodiments, 772, 774 and 776 may all be polynucleotides, as illustrated in FIG. 10.p.4. (772b, 774b and 776b, respectively); for example, 772b may be genomic polynucleotide or fragment thereof, a copy of a genomic polynucleotide fragment, a specific mRNA in a cell, or a DNA fragment or RNA fragment from a pathogen, with 774b and 776b being oligonucleotide or polynucleotide probes for nearby sequences and the device is operated under conditions suitable for specific binding of 774b and 776b to respective target sequences; preferably oligo- or polynucleotides (or chemical modifications thereof, e.g. peptide nucleic acids or locked nucleic acids) serving as ligands 774b and 776b to a target analyte polynucleotide are immobilized to 779b and 445b via opposite termini which respective to eachother are most distal in the complementary target sequence, and target the same polynucleotide strand, such that actuation requires rupture rather than unzipping of hybridized oligo- or polynucleotides. Alternatively, 772 may be a polypeptide or protein or immunoglobulin or fragment of one of these or complex comprising these and 774 and 776 independently may be immunoglobulins, small-molecule ligands, epitopes or aptamers (e.g. oligo- or polynucleotide aptamers for binding protein or polypeptide targets.) Note that in an alternative embodiment, a plurality of ligands 774 and 776 may be adducted to members 779 and 445b respectively; this may increase minimum detectable analyte concentration and provide for more rapid quantitation of analyte concentrations. Again, ligands are preferably chosen and/or arranged such that unbinding is least processive and most catastrophic, thus requiring largest forces resisting actuation forces.

FIG. 10.p.3. schematically depicts an alternative analyte sensing device, similar to that depicted in FIGS. 10.p.1. and p.2., designed such that presence of 772 bound to 774 impedes translation of 445c past 774 situated on 779b, as seen in FIG. 10.p.4. This alternative embodiment is suitable for analytes for which only one ligand is available or which may be bound by only one ligand at a time, as is often the case for small molecule ligands. Note that alternatively, 774 could instead be bound to 445c such that on binding of 772 to 774 collision of 772 with 779b impedes translation of 445c. Note that the present invention facilitates the fabrication and assembly of devices with sufficiently tight dimensional tolerances to enable this mode of operation, which would likely otherwise be extremely difficult to achieve reproducibly.

FIG. 11 concerns accurate positioning means and devices which may be fabricated and assembled according to the present invention, useful in systems for fabrication and assembly according to the present invention. In particular, devices disclosed in this figure provide for positioning with greater accuracy than the positional accuracy of actuators used to translate positioning structural members. FIGS. 11.a-b. show a positioner featuring a track which imposes a mechanical disadvantage analogous to a ramp. FIG. 11.d shows a positioner featuring a hard-stop with various spatial features for defining positional resolution for a positioner comprising a less accurate or stable actuator. FIG. 11.d shows a positioner featuring a rack comprising teeth arranged for translation by actuators; an arrangement analogous to 3-position motor is shown and the operational positions thereof are illustrated; note that this arrangement provides for mechanical locking of a positioning member in a defined position by the actuators driving the rack.

FIG. 11.a. shows a positioning structural member 108 whereupon is formed a track comprising structural members 104 and 106, wherebetween positioning structural member 102a is constrained to slide. Rack 110 comprising teeth in communication with 108 provides for articulation with actuator teeth, but it is noted that 108 may alternatively be in communication with a variety of different types of actuators including by being a portion of an actuation structural member thereof. FIG. 11.a. shows the relative positions of the features shown in FIG. 11.a. after 108 has been translated by increment Δy, which caused translation Δx of 112a; note that 108 is not shown.

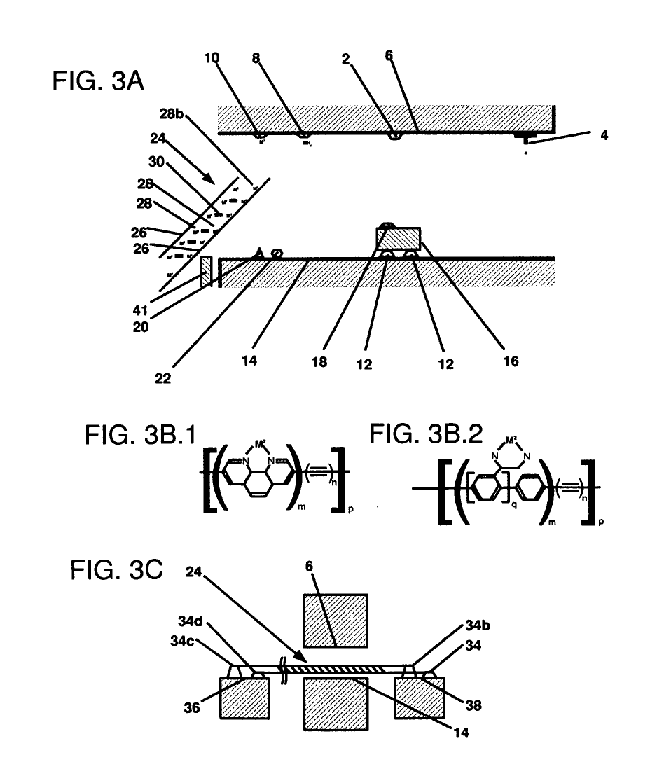

FIG. 11.c. shows the device partially shown in FIGS. 11.a-b. but additionally shows a positioner stage 102b in communication with 102a depicted thereunder, with 102b constrained to slide between structural members 112a and 112b of constraining member 112. Doubleheaded arrows indicate the ranges of motion of the positioning device shown, implying the geometrical mechanical disadvantage, x/y. Note that positioner stages such as 112b are ideal for use as support members for supporting molecular tools or workpieces of the present invention such as 6 and 14 (and alternatively or also 36 and 38) in FIG. 3.a.

FIGS. 11.d.1-2. show a positioner featuring a hard-stop 119b comprising steps 119a which define different positions, which is translated in the y direction by an actuator (not shown) to slide in the y direction against relatively fixed structural member 149, and which limits the motion of actuation structural member 124 of actuator 122 which optionally features a step 124a for articulation with steps 119a. Steps may be monoatomic layers (or multiples thereof) of a members fabricated according to the present invention, such that positioners according to the present embodiment can have accuracy equal to the crystal lattice of the corresponding material; most preferably, a positioner according to this aspect of the present invention comprises 119b and 124 of composition identical a the material to be fabricated and are comprised by a system or subsystem for fabricating said material.

FIGS. 11.e.1-2. show a positioning device comprising a rack 110 featuring teeth 110b and actuators 127 for actuating actuation members 129b comprising articulating features 129 for articulating with teeth 110b. Preferably, actuators 127 are of the type disclosed in FIG. 10.i. (or even nanorelays as disclosed in FIG. 10.o. whereby actuation may be monitored) comprising a compliant member opposing actuation. Actuators 127 may preferably comprise a housing 133 constraining actuation member region 129c.

FIG. 11.e.3. schematically depicts the operation of a 3-actuator version of this positioning device, somewhat analogous to a 3-position motor going through a 3-step cycle in i. through iii. whereby the rack is translated the full dimension of a rack tooth in iv., revealing that such a positioner may feature resolution equal to the dimension of a tooth divided by the number of actuators used, provided actuators may be arranged with that resolution. In this arrangement, actuation motion causes 129 to slide along 110b, causing 110, constrained to slide (e.g. as for the case of 119b in FIG. 11.d. by 149) perpendicular to the actuation motion of 129, to translate to the position where 129 is fully engaged in the depression between two teeth, constraining 110 in a minimum energy configuration which resists random motions e.g. due to thermal energy. 129d indicates the position of an actuated feature 129 of an actuation member 129b, while 129d indicates the equilibrium position of an unactuated feature 129; note that in this arrangement, a slight barrier to motion of rack 110 is imparted by the small compression of an internal compliant member of an equilibrium position actuator 127 as rack 110 is driven by an actuator 127 during the actuation stroke thereof, while other actuators 127 of the device are relaxed, preferably by slowly de-energizing actuation thereof such that motion of all actuators 127 is coordinated and gentle whereby vibrations are avoided. Also indicated are crystalographic indices which are preferred when a rack-based positioner devices according this embodiment of the present invention comprise adamantine materials such as diamond or silicon. This readily suggests that teeth may comprise as few as 3 Pandey chains fabricated on a 110 surface in the case of diamond and possibly also silicon, whereby subatomic resolution becomes readily feasible.

FIGS. 12.a-d. provides flow charts for preferred processes of the present invention.

FIGS. 13.a-c. illustrate electronic devices composed of branched polyacenes conveniently fabricated according to embodiments of the present invention. Note that narrow hexagons denote bending of polyacene segments into and out of the plane shown; note that a device of this type may comprise circuitry in a plurality of planes or may comprise segments situated askew from eachother. Polyacenes serve as conductive paths for charge such as electrons, comprise branched structures at which charge flow may be switched between alternative paths according to local electrical potential fields. As shown in FIG. 13.a. polyacenes further comprise electroactive moieties either bound as side-groups or spatially constrained to reside at particular locations on said polyacenes, or alternatively as seen in FIG. 13.b. integrated therein (p-quinone/p-quinoxide moeities are shown, although other compositions may serve this purpose; here negative charge as electrons is shown repelled by stored negative charge at sites of electroactive moieties, following paths indicated by arrows.) Electroactive moieties serve as sites for reversibly storing electrical charge, whereby a field is established for affecting the flow of charge along various paths. In either case, electroactive moieties may be oxidized or reduced by flow of charge along various polyacene wire members, which flow itself may be switched by other electroactive moieties. Note that electroactive moieties are preferably situated less than 10 nm from branch points, more preferably less than 2 nm from branch points, most preferably less than 1 nm from branch points, whereby subvolt fields established thereby may significantly affect the flow of charge along alternative branches, e.g. establishing fields in excess of 10⁶ V/m and switching energies greater than 50 meV. Note that other polarities than those shown may readily be utilized, e.g. flow of positive charge, positive charge attracted to negatively charged electroactive moieties, or alternatively flow of positive charge, positive charge repelled by positively charged electroactive moieties, or flow of negative charge attracted by positively charged electroactive moieties; more preferred embodiments may comprise more than one of the foregoing whereby a bipolar arrangement of electroactive moiety charging steers the flow of charge along circuits of this type. FIG. 13.c. depicts an equivalent circuit of a single switch.

FIG. 14.a. depicts a top view of a diamond 110 surface comprising phosphorus atom substitutions at the indicated positions for serving as a ligand for binding nickel atoms. Nickel atoms serve as binding means for unsaturated molecules, in this case zero-valent nickel atoms bind to ethyne groups of triacetylene; here a pair of ligand bound zerovalent nickel atoms are situated along the same (110) trough. Note that other heteroatom substitutions (e.g. especially nitrogen) may serve the ligand functionality, as may carbon radicals produced by hydrogen abstraction from unmodified C(110) or other diamond surfaces, or carbanions formed by reduction of same. Note also that other metal atoms or ions may serve this function. FIG. 14.b. depicts a top view of a diamond 110 surface similar to that in but with a different pattern of substitution for binding a polyacetylene. FIG. 14.c. depicts different electronic configurations of ligands and metals bound thereto and their control by a molecular wire associated therewith (in the case shown, by protonation of an atom at the terminus of said molecular wire) whereby strength of binding may be controlled. R1 and R2 represent substituents which are preferably atoms or bonds to structural members for positioning the depicted complexes. Complexes shown represent novel binding tools and deposition tools for depositing dimers and/or acetylene according to the present invention and represent a novel case of simple 5-membered rings serving as mechanosynthesis tools; these also represent novel cases of reactant fragment binding in three-membered rings or as pi-complexes for positional mechanosynthesis or nanopositioning or nanoassembly. Note that these same structures, without acetylene or dimers shown, may be used for reversible binding to radical sites formed by hydrogen abstraction for nanomanipulation of workpieces or components. [Mar98] discloses a family of molecular wires useful as substituents of several of the tools of the present invention for transferring electrons thereto and therefrom. Also, this dissertation extensively reviews a great deal of the related prior art for forming electrical connections with molecules produced by organic synthesis. For instance, more extended polyenes may replace those shown for the tools and complexes of FIG. 14.c. connecting these to a source of electrical energy or a potential bias for controlling the strength with which said tools and complexes bind reactants.

FIG. 15. depicts a novel method for avoiding the requirement for providing a preformed seed whereupon mechanosynthesis is initiated. Shown is a cross-section looking down (110) rows. Here a diamond or nanodiamond surface is provided comprising atomic substitutions at the sites indicated by circles or broken circles; exemplary substitutions include boron, nitrogen or phosphorus, such as may be fabricated according to various methods and means of the present invention. The case shown is a sequence for deposition of a first row onto rows comprising substituted atoms, deposition of a second layer of rows onto said first row, deposition of a third layer of rows onto said second layer of rows, and deposition of a fourth layer of rows onto said third layer of rows. These depositions are enabled by the expansion methods and means disclosed in the present invention. After a desired deposition sequence is completed, the deposited material is sheared from said diamond or nanodiamond surface by application of force or pressure by shearing means (as shown in FIG. 15.b.) by actuators (not shown) causing breakage as shown, facilitated by weaker bonding to deposited material by said atomic substitutions and also the narrowness of the break-point. In an alternative denoted by sequence v.b., said first row may instead comprise substitution atoms and be retained by said diamond or nanodiamond surface, for reuse in a similar sequence. Preferably, the structure thus fabricated is bound by binding tools (not shown) for nanomanipulation thereof subsequent to release by shearing.

FIG. 16.a depicts an AM1 optimized structure of a diacetylene molecule adducted to an Si(100)2×1 dimer of a Si nanostructure structural member as an ene-yne, similar to that described by [Hua04] and utilized in novel fashion herein by deprotonation of the alkynyl terminus as an abstraction tool or a base tool according to optional oxidation. FIG. 16.b depicts an AM1 optimized structure of a diacetylene molecule adducted to an Si(100)2×1 dimer of a Si nanostructure structural member as a cumulene following [Hua04] and [Lu04]; note that the cumulene structure may be favored on a Si(100)2×1 dimer over the eny-yne structure by depositing said diacetylene via another tool bypassing the kinetically favored path; which is novel to the present invention. Note also that a similar cumulene structure is kinetically favored on Ge(100)2×1. FIG. 16.c depicts an improvement over earlier expansion deposition, here a 1,4-pentadiene fragment with a central carbene, bound to an anthraquinone binding tool adducted to two Si dimers of Si(100)2×1, where earlier variation in reaction course is avoided by additionally providing a steric member (shown represented by a decalin molecule) for applying pressure to the reactant fragment towards the desired target site overcoming the barrier observed in some calculations. Said steric member may be positioned and forces applied therewith preferably by an independent individual actuator in communication therewith. FIG. 16.d. depicts a cumulene bound by Ge(100)2×1 similar to that disclosed by [Lu04] and the structure on Si(100) shown in FIG. 16.b positioned for addition to a dehydrogenated trough of C(110); note that the pattern of dehydrogenation situates isolated surface radicals and surface dehydrogenation yielding electronic conjugation such that isolated radicals may attack cumulene carbons to yield radicals on adjacent cumulene carbons which in turn are situated appropriately to attack said conjugation; this favors rapid reactions since intersystem crossing is unnecessary. FIGS. 16.e-h. depict various views and renditions of the structure of C(110) substituted by a nitrogen atom and a phosphorus atom for binding to a nickel atom for binding to ethyne groups or acetylene (this structure is hand edited due to lack of parameters in AM1.) Note that for zero-valent nickel, the core of this complex exclusive of diamond structure or structural member is closely analogous to that disclosed in [Mul02]. This structure may be used as shown in FIGS. 14.a-b, and FIGS. 18.a-b. FIGS. 16.i-j. show two views AM1 optimized geometries of tools for silene dimer addition at the predicted quintuplet ground state; here, tool silicon atoms are bridged by an ethyl linkage. FIGS. 16.k-l. show two views AM1 optimized geometries of tools for silene dimer addition at the predicted quintuplet ground state; here, tool silicon atoms are bridged by an ethene linkage, which is preferred because this facilitates radical delocalization on release of bound dimer reactant fragments from such tools. FIGS. 16.m-n. show the optimized discharged structure of the tools shown in FIGS. 16.k-l.

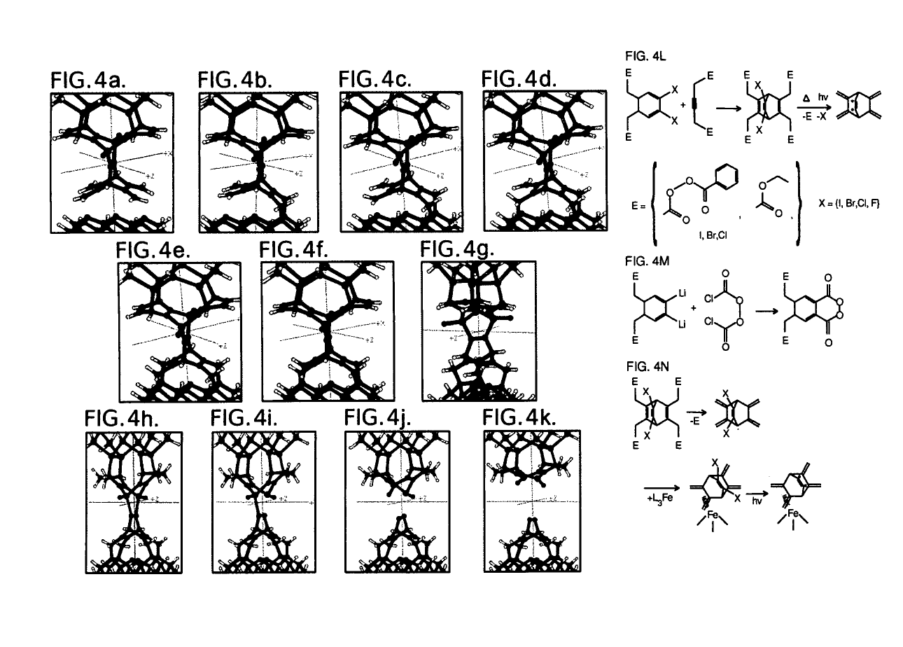

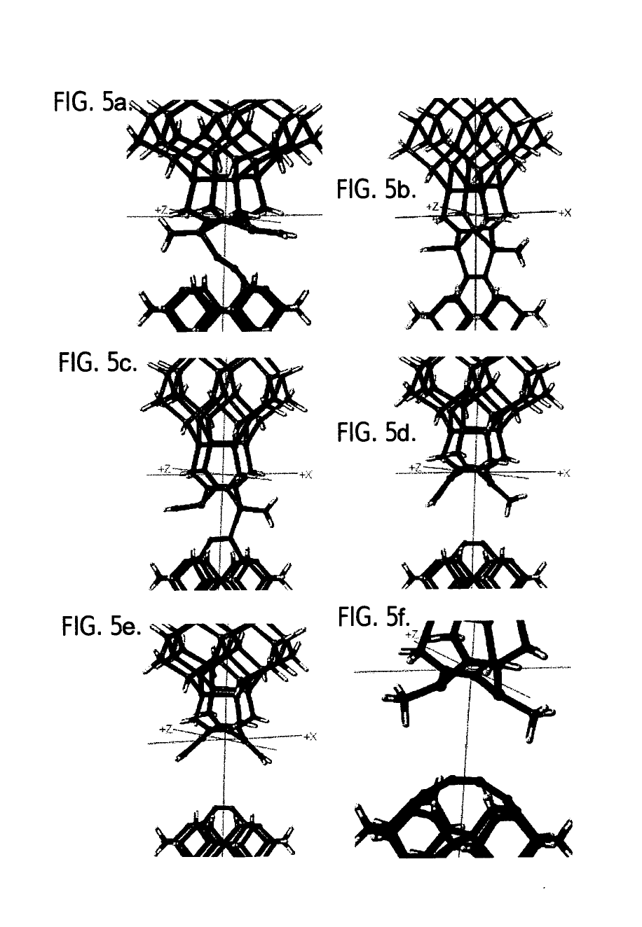

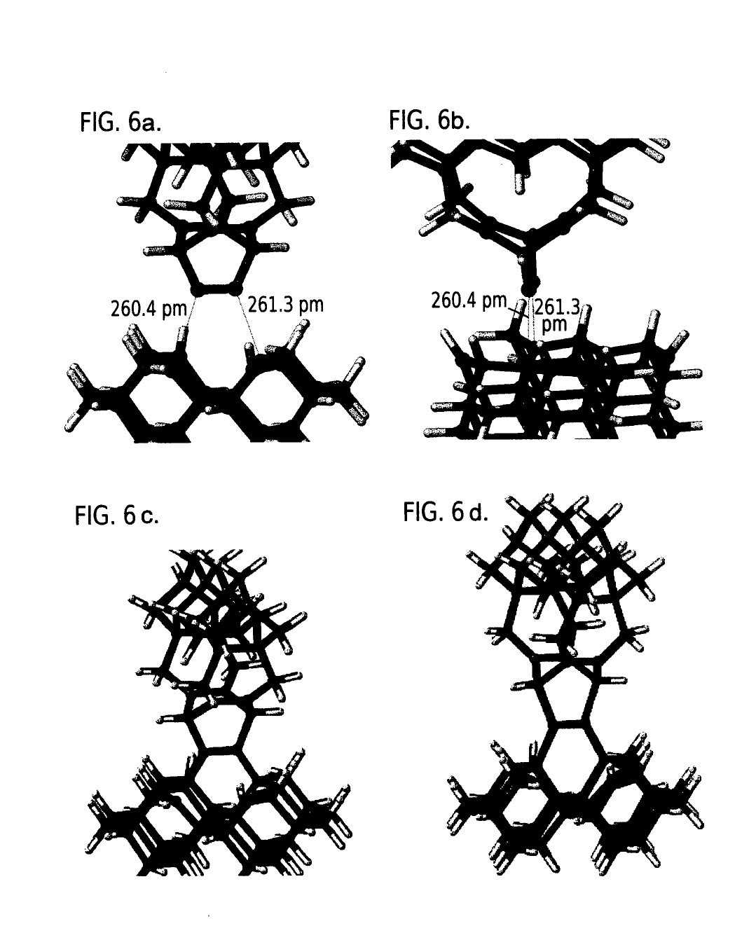

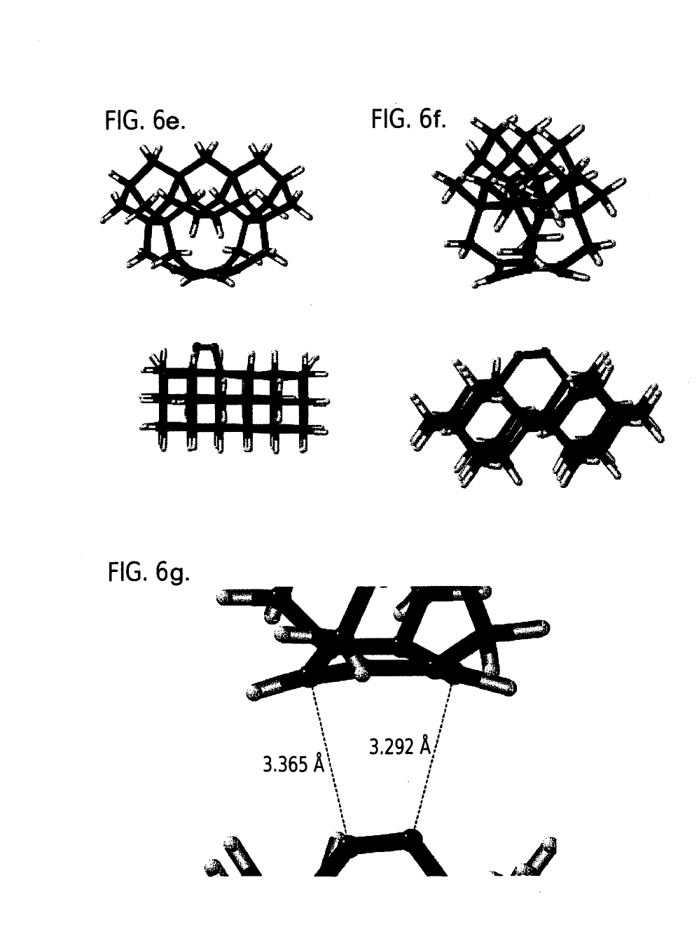

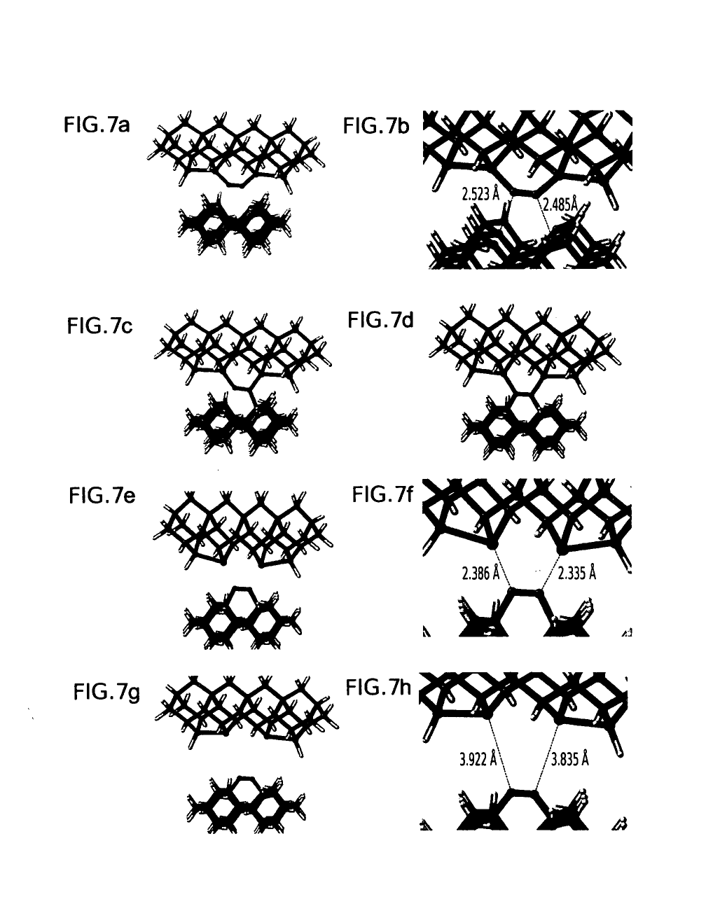

FIGS. 17.a-b. depict polycatenane feed chains with metal bound acetylides situated therebetween, and motions thereof for contacting acetylides with a dimer binding tool represented by a hexagon and withdrawing therefrom. This arrangement may be generalized to other reactant or reactant fragment or reactant precursor types. Note that other topologies such as [n]rotaxanes, polyrotaxanes or other mechanically linked molecules may be used, and that a vast range of compositions may be used to serve as feed chains in the present invention. These may be synthesized according to art methods, as reviewed in [Die03] and [Hub00]. See FIG. 4 of [Die03] for a variety of additional topologies useful as molecular architectures for feed chains for the present invention.

FIGS. 18.a-b. depict a simplified nanofabrication apparatus comprising a Ge nanostructure member comprising a Ge(100)2×1 surface oriented for binding and depositing diacetylene as a cumulene, a Si nanostructure member comprising an Si(100)2×1 surface for binding diacetylene as an ene-yne for serving as an abstraction tool, counterpressure members, a diamond workpiece, borne as shown by two structural members in communication with actuators (not shown) for controlling translation thereof in the directions indicated by doubleheaded arrows, serving as means whereby methods for positional mechanosynthesis according to the present invention may be performed. FIG. 18.b. shows the arrangement shown in FIG. 18.a. with polycatenane feed chains delivering reactant diacetylenes and also a second pair of polycatenane feed chains delivering reagents (Cu⁺² bound by carboxylates, some omitted for clarity but in fact in a Chinese lantern structure, Cu⁺ bound by amines and a deprotonated amine [an amide anion which reacts as a base] for deprotonating the abstraction tool ethyne for recharging said abstraction tool and conducting away the proton thereof, said abstraction tool then oxidized by Cu⁺².)

FIGS. 19 a-e. are Tables I-V, respectively.

### DETAILED DESCRIPTION OF THE INVENTION

The present invention addresses the practical challenges which have not yet been resolved towards the goal of precise positional mechanosynthesis of diamond nanostructures and other nanostructures using C2 precursors (i.e. acetylene, C2H2; ethylene, C2H4 or carbide, C2) and other simple precursors, and accomplishes this for formats which are readily scalable and may be implemented to perform hydrogen abstractions and C-dimer insertions in parallel. Novel methods for use of the tools of the present invention for manipulation of workpieces during the course of mechanosynthesis and nanofabrication are provided. Basic functional devices or components and methods and means for the mechanosynthesis thereof are provided. Numerous aspects and embodiments are disclosed in the figures and descriptions thereof and below.

No demonstration of any effective method for positional mechanosynthesis useful for the fabrication of materials has yet been disclosed in industrial use, and extensive searches yielded no example of any molecularly precise covalently bonded products comprising more than 22 atoms formed even experimentally by STM-based manipulation. To date, the only disclosed proposal even attempting to face most of the requirements for the manufacture and use of a tool for positional mechanosynthetic addition is [Fre04b] and subsequent efforts stemming therefrom. Compared with [Fre04b], requirements for deposition surfaces, functionalization of deposition surfaces, capping of tooltips, deposition of tools to deposition surfaces for handle growth, handle growth steps, handle gripping steps, need for MEMS based manipulators or SPM tips for gripping or binding to tools, random tool depassivation reactions and bond-forming reactions between tools on deposition surfaces and SPM tips, and the many difficulties associated with all of these are avoided according to the present invention, as are difficulties and challenges posed in the synthesis of novel tools proposed therein. It remains unclear whether the challenges faced by methods and means of [Fre04b] may ever be surmounted to fully enable industrial applicability thereof. Additionally, [Fre04b] does not provide for positional mechanosynthesis of self- or allo-replicating systems or specific components therefor, or for methods or means for nanomanipulation or manipulation, which would be useful for the assembly of positional-mechanosynthetically produced articles into useful devices, subsystems or systems, particularly if such could be accomplished largely by the same means required for positional mechanosynthesis if these were used or adapted accordingly. The foregoing may be accomplished by methods and means disclosed herein. To enable economically viable and physically efficient positional mechanosynthesis, the present invention provides and utilizes a broad variety of tool or platform moiety molecules or precursors thereof which do not require the formation of adamantane-like or iceane-like (lonsdaleite-like) cages, obviates MEMS or similar gripping means, avails itself of generally well defined chemistries for deposition of tool or platform precursor molecules directly to target supports for use in positional mechanosynthesis without handle growth, or (especially in application to self growth and self-growing subsystems or sytems, or self- or allo-replication and systems implementing same) to tool-binding tools for placing tool or platform precursors in well-defined configurations for positional mechanosynthetic formation to form adducts at desired locations and in desired configurations with support members. According to embodiments of the present invention it will never be necessary to bind any tool or tool precursor to any SPM tip; however, contrariwise, if desired, the present invention enables one to fabricate an SPM tip and precisely situate a tool or platform moiety precursor thereon, including for tools or platforms for mechanosynthetic operations other than carbon dimer addition, including tools or platforms comprising functional groups for chemical interactions or physical interactions useful in scanning probe microscopy.

To enable positional mechanosynthesis of diamond and related materials, it is necessary to provide one or more carbon addition tools, one or more hydrogen abstraction tools, optionally one or more hydrogen addition tools, optionally one or more proton removal (base) tools, defined chemistries, methods and means for attaching these to surfaces or supporting structural members, preferably also a defined seed or starting workpiece, and methodologies for positional mechanosynthesis therewith, all of which must be realizably attainable within existing arts. One aspect of the present invention is the use of molecular platform moieties for secure and well defined binding to well defined surfaces with functional group substituents appended thereto or atoms thereof serving to effect desired chemical transformations to accomplish desired mechanosynthetic operations, said functional groups or atoms thereby being precisely positioned and oriented. It is emphasized that with the sole and only partial exception of [Fre04b], despite a significant body of theoretical work, none of the work directed towards this goal which has heretofore been disclosed provides obvious methods or means for their reduction to practice or even sufficiently specific direction which an experimental researcher could take.

It should be clearly understood throughout that all of the translation steps involved in performing the methods of the present invention may be performed by actuators or positioners under electronic control including under digital electronic control and especially preprogrammed digital control, either by existing digital electronic computers comprising information storage means or by digital devices comprising information storage and processing means fabricated from devices fabricated and/or assembled according to the methods of the present invention. Likewise, it should be understood throughout that switches and relays disclosed herein may be situated at locations for detecting positions of structural members, whereby detection of completed or failed translation operations may be accomplished, and whereby success or failure of mechanosynthetic operations may be thereby determined by a programmed algorithm therefor, implemented in digital information processing means as above.

Tools capable of more versatile chemistries expand the range of products which may be fabricated; thus, where the same or similar tool may be used with precursors or reactants with atomic or functional group substitutions, broader mechanosynthetic capabilities are realized.

Further, in the course of analyzing various tools and methodologies, factors leading to undesired products were identified and measures to avoid them devised; also, new uses have been identified for certain so-called failure products of mechanosynthetic dimer addition.

One aspect of the present invention is the identification of known chemical compounds the practical synthesis of which has already been accomplished and the adaptation of these to the problem of interest. In particular, other methods established in existing arts are employed to securely bond these compounds to surfaces or other articles with well defined chemistries, mechanical properties, and in preferred embodiments electrical properties which together facilitate practical mechanosynthetic methodologies. The problem of designing molecular tools is disambiguated into the design of functional moieties, and support adaptor moeities such as platform moeities suitable for forming adducts with structural members, nanostructures, molecules or surfaces, said platform moeities substituted with functional groups bound thereto for positional mechanosynthetic modification operations, or reactant or precursor fragments bound thereto for positional mechanosynthetic addition operations.

Positional control for nanomanipulation is by now routine with apparatuses such as scanning probe microscopes (SPMs.) SPMs or alternative positioning means may similarly be used for performing the various translations of mechanosynthesis tools according to the present invention and it should be understood that many aspects of the present invention are directed at solving as yet unsolved challenges rather than implementing specific positioning means. In the following it should simply be understood that sufficiently precise positioning means are used to controllably or programmably translate the molecular tools of the present invention along predetermined trajectories to effect the methods of the present invention for precise mechanosynthesis of precise nanostructures, and that any comparably accurate positioning means may be substituted. It should be noted that no more than three degrees of freedom are required for use of the molecular tools of the present invention for performing the mechanosynthetic methods of the present invention. Positioning means alternative to complete scanning probe microscopes and useful for the present invention include capacitive actuators and especially comb-type capacitive actuators, motors and especially microelectromechanical motors commonly used in MEMS, electroactive materials, magnetostrictive materials, and piezoelectric materials. It should be understood throughout that the structural support members of the present invention and the mechanosynthetic tools situated thereon are in communication with positional control means for controlling the motions, trajectories and positions of mechanosynthetic tools relative to workpieces, and generally also applying required forces as needed for mechanosynthetic operations.

For the present invention, it should be noted, STM based hydrogen abstraction from Si may be used interchangeably with the molecular hydrogen abstraction tools of the present invention where this is convenient. The FCL method of [Her02] is a preferred methodology for this in SPM-based implementations of the present invention. Hydrogen abstraction by molecular tools comprising ethynyl radicals was proposed in [Dre91] and [Dre92] and most recently analysed further in [Tem06; see also especially references 17-19 therein]. Additionally it is noted here that unless otherwise indicated, methods of the present invention are carried out in ultrahigh vacuum conditions or in eutactic [Dre92] environments, although some embodiments may be performed in rigorously deoxygenated aqueous solution (preferably saturated with argon). This depends mainly on the sensitivity of C-dimer addition tools to water, especially in the discharged form, which in general is expected to be low, making this class of tools useful for operations in aqueous environments. The 9,10-carbon anthracene based C-dimer insertion tools should be stable to water after binding to Si dimers considering the properties of both alkyl and aryl carbons; anthracene-based tools bonded to [n]acenes should likewise enjoy this stability; the same should hold for tetramethylene-bicyclo[2.2.2]octene derived tools on nanodiamond structural members, for example. Water hydrogens should be sufficiently inert to abstraction by vinyl and phenyl radicals, so that vinyl and phenyl radicals should have sufficiently long lifetimes under these conditions to be useful for abstraction operations; ethynyl radicals may or may not be sufficiently inert to water under various conditions or for extended periods, so this must be tested on a case-by-case basis for different conditions, but it is noted that the Eglinton reaction (see [Cli63]) proceeds in the presence of water, sometimes as a solvent or cosolvent, such that ethyne-based abstraction tools may preferably be protected by binding the terminus thereof with copper or silver or other metals and producing the desired free radical therefrom near the desired abstraction site immediately prior to performing the abstraction operation, whereby opportunity to instead abstract hydrogen from water is minimized, increasing reliability of abstraction operations or reducing the need to test the outcome or repeat. Surface radicals on diamond correspond to carbon-hydrogen bonds which are considerably weaker than the oxygen-hydrogen bonds of water, so abstraction of hydrogen from water by workpiece surface radicals is highly unlikely. Accordingly, as an embodiment of the present invention, diamondoid materials may be fabricated using reactant fragment deposition tools according to the present invention adducted to structural members for the translation and positioning thereof in communication with one or more actuators, fabrication being conducted in the presence of water or more preferably submerged in an aqueous solution or pure water. More preferably, one or more abstraction tools according to the foregoing are provided and abstraction operations for forming target sites and influencing the reactivity thereof are also provided. Most preferably, one or more hydrogenation tools are additionally provided to adding hydrogens to predetermined sites on workpieces for influencing reactivity. I believe this case constitutes the first practical disclosure of diamond mechanosynthesis in aqueous solution or water. Additionally, liquid nitrogen and liquid helium should be significantly inert to all of the required chemical functionalities and mechanosynthesis in these represent distinct and novel aspects of the present invention. Further, inert atmospheres of nitrogen gas, argon, or other noble gases are feasible as media for mechanosynthesis provided that oxygen, contaminants, an optionally also moisture are rigorously excluded. Because the presence of mobile molecules or atoms might impede desired contact between reactant fragments and workpiece target atoms, a novel method for mechanosynthesis in gaseous, aqueous or adsorbate layer environments comprises vibrating an addition tool during advance towards a workpiece until the reactant fragment carried thereon is less than approximately two-thirds the smallest radius of any mobile molecule or atom which may be present. Such vibrational approach trajectories serve to sweep or nudge mobile molecules or atoms from between reactant fragment atoms and workpiece target atoms.

Here it is noted that the calculations presented herein to illustrate the methods and compositions of the present invention were done according to the AM1 semi-empirical method [Dew85+] with the corresponding atomic parameters [Dew85+] using PC-GAMESS [Gra04], a modified implementation of GAMESS [Sch93] which incorporates code from the MOPAC 6 implementation [JJPSte90] of AM1. For consistency, this widely used method is used throughout, although it is also noted that in the course of this work numerous other comparable results were obtained with other methods at both semi-empirical and ab initio levels of theory (not shown.) (Although more intensive computational methods yield higher predictive accuracy, AM1 calculations yield fair accuracy at relatively modest computational costs and permit larger systems to be investigated with greater breadth; calculations such as those presented here would pose prohibitive computational costs for higher levels of conventional ab initio theory.)

As part of the present work I have identified compounds which chemisorb in more defined configurations suitable for the present invention. None of these have been shown to quantitatively bond via [4+2]cycloaddition as a result of diffusion controlled chemisorption, but this desired addition geometry does dominate. These include cyclodienes, bis-dienes, exocyclic-bis-diene bicyclic compounds, aromatic and polyaromatic hydrocarbons and especially [n]acenes. These may serve as platform moieties for securely anchoring and orienting functional groups to be directly involved in mechanosynthetic reactions, or, in some special cases, themselves directly serve as mechanosynthetic tools.

In particular, [n]acenes form the desired bonding configurations with surfaces of interest and also present 1,4 atoms which are thus available for bonding carbon dimers, e.g. via Diels-Alder reactions with acetylene. It is well-known, for example, that anthracene readily undergoes [4+2]cycloaddition across the central ring with N-methyl-maleimide. Recently, M. Payne et al. [Pay04] found that ethynyl groups react rather spontaneously with acene rings, in fact being unable to prevent an attendant dimerization. This reaction is closely related to the reaction desired for loading of [9,10-C]-anthracene based C-dimer insertion tool molecules. Thus, for the present embodiment of the present invention, anthracene is bis-adducted via [4+2]cycloadditions to adjacent Si dimers within the same Si dimer row (preferably by specifically abstracting hydrogens from desired predetermined Si dimers, as discussed further for [n]acene chemisorption below) and then exposed to acetylene. The acetylene loaded onto this tool gains double-bonded character as a result of the Diels-Alder addition. The acetylene derived hydrogens are thus bound to sp2 hybridized carbons and hence more susceptible to abstraction by ethynyl radicals. Ethynyl radicals which constitute the active groups of hydrogen abstraction tools, further described below, are contacted with acetylene derived hydrogens whereby the adducted acetylene molecule is converted to a carbon dimer suitable for mechanosynthetic addition operations.

Similar reactions are predicted by AM1 calculations done in the present work to occur for bis-dienes with the dimers of the clean (dehydrogenated) 2×1 reconstructed diamond (100) surface, and the similar hydrogenated diamond (100)2×1 from which hydrogens were abstracted from the dimers to which adducts are desired to form. Again, dimers have reactivity which can approximate that of an alkene or that of a biradical. As a specific example, a six membered ring modified with four exocyclic methylidenes in a bis-diene configuration, e.g. 2,3,5,6-tetrakis(methylidene)bicyclo[2.2.2]oct-7-ene [Gab80] (see below,) reacts with a diamond (100)2×1 nanostructure where hydrogens have been abstracted from two carbon dimers of the same row separated by one carbon dimer from which hydrogens have not been abstracted (designated C(100)2×1:6 H-4H for the minimal 3 dimer single-row structure) to form a loaded C2 addition tool. Additionally, the clean diamond (110) surface can be adducted to two or more carbon dimers according to the C2 addition methods of the present invention, which are then reactive towards various molecular tool precursors of the present invention and platform moieties of the present invention including those comprising diene structures, bis-diene structures, polyaromatic structures (e.g. pentacene, heptacene) or substitutions, modifications or functionalizations thereof. Bonding of molecular tools or molecular platforms to diamond (100)2×1 or diamond (110) surfaces or nanostructures or structures similar to these as structural support members represent particularly preferred embodiments of the present invention because these enable self- or allo-replication of systems comprising these tools or platforms on these surfaces or nanostructures as structural support members: tool moieties situated on structural supports fabricate structural supports of similar or different material and bond similar tool precursors thereon. It should be noted that bonding of molecular tools or molecular platforms to diamond (100)2×1 or diamond (110)-related structural support members yields the convenient result that multiple tools may be situated on this type of surface with precise alignment or registry for multiple simultaneous C-dimer addition to C(110) workpieces, so diamond (110)-related structural support members bearing 2 or more C-dimer addition tools are a preferred embodiment, and a method for simultaneously adding two or more carbon dimers to a (110) surface of a workpiece comprising a step of contacting two or more C-dimer addition tools situated on a diamond (110)-related structural support therewith, represent preferred embodiments of the present invention.

Another 9,10-C C-dimer binding tool is the anthracene derivative anthraquinone, which has keto groups at the 9,10-positions. This particular tool would not be expected to load via Diels-Alder reactions but would add the various metalated acetylenes, e.g. Li₂C₂, Na₂C₂, K₂C₂, C₂(MgBr)₂, bis-dialkyl-alumina-acetylene, or C₂(CaCl)₂ to yield the desired C₂ bridgehead fragment and 9,10-oxide substituents each bearing a formal negative charge. Preferably the cations derived from the C-dimer precursor are removed, e.g. using a deprotonated ethyne tool.

Note that different charged C-dimer addition tools (from which acetylene derived hydrogens have been abstracted) have different ground-state multiplicities, but instances of both singlet and triplet ground-state tools are predicted (e.g. by AM1 calculations) to perform effectively. These [9,10-C]-anthracene based C-dimer insertion tool molecules bound to adjacent Si dimers in the preferred geometry show very high exothermicity for C-dimer discharge, also displaying bond-length changes consistent with aromatization in close analogy to the analogous but hypothetical DC10c tool proposed by D. Allis and K. E. Drexler [All05] discussed above.

Other modifications of this class of addition tools and tool comprising related platform moieties may affect the stability of surface adducts of these. For example, it was found that is some instances, extreme tensile forces could cause partial or complete debonding of various anthracene-based platform moieties from Si(100). On the speculation that the aromaticity resulting from retro-Diels-Alder mechanism contributes to this, hydrogens were added to atoms corresponding to anthracene positions 2, 3, 5 and 6 (forming 2,3,5,6-tetrahydroanthracene platform moieties,) i.e. bis(cyclohexadiene-5,6-di-yl) structures. Under similar tensile loads, these bis(cyclohexadiene) platform moieties remained bound by Si(100) dimers. Of note, [Kon00] studied the adsorption of 1,3-cyclohexadiene and other compounds on Si(100), finding some adducts of the geometry most preferred here. It is expected that bis(cyclopentadiene) based platform moieties would similarly perform better than those with aryl adducts, so a preferred embodiment of the present invention is a platform moiety for carrying a molecular tool (e.g. a functional group or molecular fragment) comprising a cyclohexadiene fragment or a cyclopentadiene fragment, or, more generally, a ring structure comprising a diene as a fragment. As with other embodiments of the present invention, atomic or functional substitutions are comprehended within this aspect of the present invention.

Heteroaromatic compounds also show promise as C-dimer binding tools. Some of these in some respects resemble various proposed DCB6 described above (although iceane structures are generally avoided) but additionally featuring varying degrees of aromaticity, and providing for derivation with functional groups for modulating reactivity. The first example of this I identified is 1,4-disilabenzene, the synthesis of which has been described in the chemical literature. A great variety of substitutions to anthracene, in particular substitutions of the 9,10 carbons and functional groups bound thereto have been described in the chemical literature [McC84], their synthesis and structure being disclosed. Notably, these include heteronuclear substitutions such as 9,10-SiGe, -SiSn and -SiPb. [Cor87] reviews some syntheses for disilaanthracene compounds and discloses stereoselective syntheses and separations thereof; methods disclosed therein are of particular use for producing some of the molecular tools of the present invention and hence are incorporated by reference. Heteronuclear C-dimer binding tools are of particular interest because one center may be chosen for avidity of reaction of the C-dimer carbon bound thereto with a workpiece while a second may be chosen for facility of C-dimer carbon release, for example. Note that the monosubstituted 9-sila-, 9-germanyl-, 9-stannyl- and 9-plumbylanthracenes represent heteronuclear species which may also be of interest. These must all be evaluated on a case-by-case basis for suitability for any given type of mechanosynthetic operation. It should be noted that some may perform poorly for C-dimer insertion operations while performing well in C-dimer addition tool deposition operations. Of particular note and interest is the work of M. Oba et al. [Oba01]. These workers showed that and intermediate resulting from the interaction of 9,10-dihydro-9,10-dimethyl-9,10-disilaanthracene with palladium on carbon could be induced to undergo addition of acetylene derivatives. They were able also to trap the 9,10-dehydrogenated intermediate. They presumed a [4+2] Diels-Alder cycloaddition mechanism but did not rule out “palladium catalyzed dehydrogenative double silylation of alkyne via a bis(silyl)palladium complex.” Thus, the same reaction instead performed with acetylene (C2H2) in place of the bis-alkyl-alkynes used by these workers would yield a molecule equivalent to the 9,10-dimethyl-9,-10-disilaanthracene based tools described herein with the C-dimer in dihydrogenated form. The more preferable 9,-10-diphenyl- and 9-10-dihydro- and other derivatives described or disclosed herein could presumably be subjected to similar reactions with acetylene, and molecules having other heteroatomic 9,10-substitutions may similarly be treated. Also, since some palladium catalyzed reactions have been found to work well in the presence of water, the possibility of oxygen binding to palladium should not discourage use of this reaction for alkoxy-derivatives such as the 9,10-dimethoxy-derivative or even hydroxy-derivatives such as the 9,10-dihydroxy derivative. Further, following [Oba01], since substituted alkynes undergo the desired 9,10 addition, the possibility of other bis-substituted acetylenes may be exploited for the present invention, in particular, and atoms or functional groups which are easily removed from the added alkyne would be of clear usefulness for the purposes of the present invention, as would substitutions which facilitate handling of non-surface bound tool molecules. Since halides tend to abstract more easily than hydrogens and also undergo photodissociation reactions, so these alkynes are of immediate interest, particularly for early implementations of the present invention.

On the topic of derivatives, it is noted that non-symmetric derivatives are fully within the scope of the present invention, and offer a further opportunity to differentially tailor the reactivities (in hydrogen abstraction, reaction to target atoms and discharge) of each carbon atom of a carbon dimer. Also within the scope of the present invention are derivatives at positions other than 9 and 10, and as are other polyaromatic skeletons with or without other atomic substitutions to the carbon skeleton or additional hydrogenation thereof. So, for example, 1,4,5,8-tetra-aza-9-10-disilaanthracene, 1,4,5,8-tetra-aza-9-phenyl-10-allyl-9-10-disilaanthracene, 1,4,5,7-tetra-aza-9-10-di-germylanthracene, 2,3,6,7-tetrahydro-9,10-diphenyl-9,10-disilaanthracene, and 9-10-disilaanthra-di-9,10-one (9,10-anthradisilanone) among many other combinations and possibilities are fully within the scope of the present invention, as will be apparent to those skilled in the art of organic chemistry. Likewise, different heteroatomic substitutions at the 9,10 positions or at other positions, e.g. 9-alumaanthracene, 9,10-dialumaanthracene, the 9,10-dihydro-9,10-dialumaanthracene dianion, 9-aluma-10-silaanthracene, 9-titanyl-10-zirconyl-anthrace, and 11,14-disilaanthracene are among the many variations of this kind which are possible. Further, departure from linear [n]acene skeletons is feasible via bent or branched skeletons as well as skeletons comprising 3-, 5-7-, or 8-membered rings or larger, e.g. a heptaphene skeleton, a rubicene skeleton, or small graphenes such as coronene.

Also, barrelene (bicyclo[2.2.2]octatriene) and more preferably 2,3,5,6-tetrakis(methylidene)bicyclo[2.2.2]oct-7-ene [Gab80; see especially compounds 4 and 10 therein] could be secured to a structural support member according to the present invention and subjected to hydrogen abstraction at each of the carbons of the bridgehead dicarbon according to the present invention, yielding charged C-dimer insertion tools partly similar to the DC10c tool proposed by Allis and Drexler. Preparation and studies of these and related compounds have been described in the chemical literature. Thus, preferred embodiments of the present invention are structures comprising two (100)2×1 dimers adducted to barrelene (preferably via two [2+2]cycloadditions) or adducted to 2,3,5,6-tetrakis(methylidene)bicyclo[2.2.2]oct-7-ene (preferably via two [4+2]cycloadditions,) where said dimers comprise atoms of group 14 of the periodic table. [Cos05] have studied adsorption of barrelene on Si(100), finding chemisorption between rows of dimers to be most stable; it should be noted that this configuration, along with that corresponding to chemisorption between two (100)2×1 dimers of the same dimer row both occur exothermically and both are useful for the present invention.

Returning to 9,10-disilaanthracenes, the identity of substituents bound to the atoms at the 9,10-positions were found to have significant effects on tool performance, particularly for C-dimer discharge. AM1 and other calculation methods consistently showed that 9,10-dimethyl-9,-10-disilaanthracene based tools were prone to causing the debonding of carbon atoms to which C-dimers were added from the carbon of the first subsurface atomic layer of C(110) upon tool retraction, rendering this tool less suitable for C-dimer addition to bare C(110). Note here that this tool shares with the DCB6Si tool of [Mer03] and some of the structures contemplated in [Mer97] the feature of having an alkyl substituent on a reactant-dimer binding Si atom. Further calculations performed using different calculation methodologies found similar debonding events, so this observation is probably not artifactual. Therefore with the exception of use with the healing process described below, this particular 9,10-dimethyl-derivative is predicted to be a less preferred embodiment of the present invention unless other measures are found for improving performance, although it cannot be ruled out that other calculation methods would yield different predictions or that experimental results may show this particular tool to perform well. Similarly, this tool may still be useful for comparison with other tools in studies of substituent effects. A simple modification of the 9,10-dimethyl tool may be performed on these substituents, in particular by tools already necessary for the present invention, namely, one hydrogen abstraction from each methyl group to yield a 9,10-dimethyl-C,C′-biradical derived species. The discharged state of this tool might be termed a 9,10-bis(methylidene)-9,10-disilaanthracene. The rationale for this is that conjugation of the radical electron of the methyl radical with one electron of the predetermined bond selected for cleavage will stabilize intermediate states on the reaction path to breakage, lowering energetic barrier to cleavage and stabilizing the discharged tool. Thus the methyl radical electron may couple to the adjacent Si—C bond bonding the tool to the C-dimer being discharged during tensile bond cleavage, so that a transition configuration described partly by a C—Si double bond being formed by donation of the radical electron from the methyl radical substituent and an electron from the cleaving Si—C bond between the Si atom of the tool and the C atom of the carbon dimer results; 9,10 substituent C—Si bonds in the resulting structure shortened by over 8 pm to about 163 pm and had near-planar geometries about these bonds consistent with double bonds, although angles with hydrogens and anthracene skeleton-carbons for the carbon and silicon atoms respectively were smaller than the idealized 120° (111° and 105°, respectively.) Thus the biradical modified dimethyl was found to cleanly alleviate this debonding phenomenon found with the fully hydrogenated parent tool caused by tensile tool retraction from a carbon dimer added to bare C(110). It should, however be noted that this modification also affects the barrier for C-dimer insertion, particularly compressive insertion from a switch-bladed bridging position. Whereas this tool in dimethyl substituted form forms a second C-dimer-target surface atom bond at a position corresponding to that which would measure 155 pm between the second carbon atom of the C-dimer to bond to the respective target surface carbon if this distance were inferred from distances of remote sites in the unstressed structures before close approach, from a switchbladed configuration, the dimethyl biradical substituted tool forms the desired bond with more difficulty. (While this construction describing distances may at first seem cumbersome it should be realized that in practice, in the performance of the reactant addition mechanosynthetic methods of the present invention one does not directly track the location of each atom but rather positions of supporting structural members and perhaps also forces, from which locations of particular atoms might be inferred, so this is a more practically relevant way of referencing distances.) In the case of the methyl radical substituted form of this tool, this value changes to 75 pm with noticeably increased deformation of both the tool-structural support member conjugate and the workpiece. In contrast, if the starting position permits the switchbladed configuration to be avoided, the dimer can form both desired bonds to workpiece target atoms avidly; factors affecting this are subjects for further investigation. It is expected that the rationale of situating a radical adjacent to a tool-reactant bond which is desired to be rendered more highly susceptible to cleavage (e.g. induced by mechanical stress) and hence conjugating a radical with a bond to be broken, which successfully informed discovery of this more reliable tool, would apply generally (to greater or lesser extent for different substitutions and substituents as is ordinarily the case for generalizations in chemistry) for mechanosynthesis tools. This would also be expected to hold for substituents conjugating conjugated electron systems (e.g. conjugated polyenes,) which distribute and hence stabilize cleavage-generated radicals, to bonds selected for cleavage and more so for substituents conjugating conjugated electron systems comprising a radical electron to bonds selected for cleavage, (e.g. an allyl radical.) Thus, conjugation of conjugated electron systems by mechanosynthetic reactant addition tool substituents chosen to exert this effect constitutes an aspect of the present invention.

Further, the above embodiment of the present invention also illustrates another aspect of the present invention, namely a method for the modification of mechanosynthetic tool properties through mechanosynthetic modification of functional groups or substituents on mechanosynthetic tools. So for example a tool may be used in a first reaction type in a first form, modified by the removal or addition of one or more or two or more atoms, or by the addition or removal of one or more or two or more protons (exemplified elsewhere herein,) or by the addition or removal of or one or more or two or more electrons (exemplified elsewhere herein) and used in a different mechanosynthetic reaction or reaction type. (Note that for the purpose of understanding the foregoing that a single mechanosynthetic operation may involve multiple mechanochemical or mechanosynthetic reactions, e.g. the C-dimer addition disclosed herein involves a first mechanochemical process for forming bonds between a reactant C-dimer and workpiece surface target atoms, and a second mechanochemical process for breaking bonds between atoms of C-dimer addition tool and atoms of a workpiece-bonded C-dimer fragment derived from a C-dimer reactant.) As a more preferred embodiment of this aspect of the present invention, said first and said second or further mechanosynthetic tools are securely bound to a structural support member, and yet more preferred embodiments said structural support member comprises at least one silicon atom, or said structural support member comprises at least two carbon atoms bonded together and each bonded to three or more heavy atoms (heavy atoms being atoms having three or more protons in their nuclear structure.)

Further, the process of developing the above embodiment of the present invention also illustrates an additional aspect of the present invention: a method for improving the design of mechanosynthesis tools by selecting the composition of functional groups for substitution onto tool molecules, comprising one or more atoms two or more bonds or bond-lengths away from a mechanosynthetic tool atom which forms a bond with an atom of a bound reactant, comprising the steps of performing a quantum chemical calculation of a putative reaction trajectory of a first mechanosynthetic tool as a trial, recording one or more result parameters related to desired reactivity or performance characteristics, designing a second or further mechanosynthetic tool differing in its structure from said first mechanosynthetic tool by at least one atom situated at least two or more or at least three or more bonds or bond-lengths away from an atom in the structure of said second mechanosynthetic tool which forms a bond to an atom of a bound reactant, performing a similar trial reaction trajectory calculation for said second or further mechanosynthetic tool, recording one or more result parameters related to desired reactivity or performance characteristics of said second or further mechanosynthetic tool, a comparison step comparing said parameters related to desired reactivity or performance characteristics of said first mechanosynthetic tool to said parameters related to desired reactivity or performance characteristics of said second or further mechanosynthetic tools, and selecting the composition of functional groups for substitution onto tool molecules in the design of said tool molecules according to which candidate mechanosynthetic tool yielded said parameters related to desired reactivity or performance characteristics most preferred in said comparison step. A further preferred embodiment of this aspect of the present invention involves two or more cycles (or rounds) of substitution, trials, comparisons and selection whereby mechanosynthetic tool designs and the reactivity or performance characteristics thereof may be increasingly refined or improved.

In the course of investigating the above debonding phenomenon, it was realized that adding a hydrogen to the surface carbons adjacent to target surface carbons might lock them in a tetrahedral configuration and favor sp3 electronic structure. This was found to reduce this debonding effect but not in all cases eliminate it completely. Similar effects of configurational locking and orbital hybridization restriction occur when an target-atom-adjacent surface atom is itself bonded to an added carbon (e.g. of another C-dimer or group of C-dimers, structures which I studied earlier for different systems.) Presumably, any other atom which can bond to sp3-hybridized carbon atoms would have this effect to some degree, so in general a fourth atom bonded to a target atom-adjacent atom would constitutes a preferred embodiment for compositions of matter suitable for addition of carbon dimers by mechanosynthesis. So, in the simplest case, for a each predetermined surface target atom of a bare surface to be prepared for reliable carbon addition, a hydrogen atom or another atom is added each target atom-adjacent atom prior to any step adding carbon to said target atom. This is expected to hold true for mechanosynthetic operations using the tools described heretofore and any other tools distinct from those taught in the present disclosure, so this method for manipulating debonding potential via controlling the number of atoms bonded to target-atom-adjacent atoms constitutes a general aspect of the present invention, with applicability to other methodologies. Thus, in cases of mechanosynthesis on bare (unpassivated) surfaces, addition of protons or hydrogen atoms constitutes a preferred embodiment of the present invention. Further, although there have been proposals (mainly in [Dre92] and related work) involving mechanosynthesis on hydrogenated surfaces via hydrogen abstraction steps, it has not been specified or suggested that target-atom-adjacent surface atoms be retained until after addition operations at target atoms, nor suggested that such measures might enhance results.

To further investigate this issue of debonding I turned to what is known about growth mechanisms in CVD of diamond. [Ste00] investigated mechanisms of diamond growth from hydrogen-poor plasmas, in particular dicarbon (C2) resulting from C60 fragmentation, using SCC-DFTB calculation methods. These workers found that multiple dicarbon additions to clean C(110) along the same trough can promote similar debonding, starting with the second dicarbon addition, there in the absence of applied tensile stresses. Presumably structures formed with this plasma phase reactant differ in initial electronic structure from those formed with the C-dimer addition tool-bound C-dimers of the present invention, and once added to C(110) might be expected to find different local minimum energy states even if identical calculation methods had been used. These workers note that the structure formed by dimer addition along a trough between dimer rows with this attendant subsurface debonding has curvature similar to that of single wall carbon nanotubes of (m,n) or armchair form. Because this raises the question of graphitization and delamination, as occurs with diamond (111) thermal graphitization processes, these workers proceeded to ask whether a structure with 50% coverage (i.e. Cn addition to every other trough) would delaminate but found that this graphene structure resembling armchair nanotubes was stable and did not migrate. Because work presented in [Ste00] was directed towards diamond growth from Cn plasmas rather than through positional mechanosynthesis, these workers were required to consider many different addition sequences which could occur at random, which may be avoided through use of the present invention. Here it is emphasized that through the present invention, even different types of addition events may be caused to occur in a predetermined desired sequence in a predetermined spatial pattern. Thus, although the 50% coverage surface described in [Ste00] was studied in order to ask the question of whether delamination is predicted to result from graphitization on C(110), the investigated random plasma dicarbon addition process offers no way to reliably obtain these structures, especially not in any desired predetermined pattern, and so does not enable technological exploitation of this phenomenon. Although my calculations did not proceed to similar extent of dimer addition and hence debonding, the similarity of bond lengths to those of olefins was apparent. The significance of these processes becomes manifold when one realizes that when combined with the spatial and temporal control over dimer addition which may be obtained through the present invention, this debonding phenomenon offers a process for forming conductive wires on the insulating surface of diamond, which may be useful in general, e.g. for nanoscale electronics or quantum computational devices, a process which only requires tools already used in other aspects of the present invention, that such wires may be selectively formed without requiring modified fabrication device designs for handling graphene sheets or carbon nanotubes, nor requiring feedstocks with other chemical elements such as metals, and that some aspects of the present invention require electron transfer processes most conveniently to or from electrodes connected with wires. Thus, this represents the inadvertent discovery of a method for forming integrated graphenoid wires via dimer addition to bare C(110) followed by tool retraction under conditions frustrating facile release and promoting debonding, the extent of which is readily limited by patterns of hydrogenation or hydrogen abstraction.

Further, and highly significantly, in combination with the oligo- and polyacene fabrication methods disclosed herein, hybrid devices comprising this nanotube-related structure (which I term hemitubes) bonded to or fused to by at least two common atoms with oligo- or polyacene structures represent heterojunctions (i.e. between different allotropes of carbon) colocalizing molecular orbitals of different energies and capable of electrical conduction. Various oligo- and polyacenes have absorptions in the visible and infrared spectrum, and so the colocalization of photon absorption with a heterojunction offers the possibility of forming photoelectronic devices including photodiodes, phototransistors and, for energy source applications, photovoltaic devices. In addition, the underlying diamond phase may be doped to impart semiconductivity, conductivity or (with heavy boron doping, e.g. 10²⁰-10²²/cm³) superconductivity. The combinations of acenes with semiconductive materials [Scho00, for pentacene on ZnO and Al doped ZnO] and of acenes with carbon nanotubes [Afz04],[Afz06] have in fact been studied and successfully applied in efficient and stable photovoltaic devices. Analogs of such devices may be fabricated according to and as embodiments of the present invention, although the challenges confronted in those cases are entirely circumvented in the present aspect of the present invention. The related device disclosed by [Afz04],[Afz06] utilize pentacene as a p-type material and carbon nanotubes as n-type material. In particular, since the foregoing photoelectronic devices are fabricated by macroscale methods, structural order obtained depends on thermodynamic properties of various phases of acenes and their derivative and the methods and precursors used to fabricate these. Pentacene has attracted particular attention both in the foregoing photoelectronic devices as well as other organic electronic devices because the crystalline form has a particularly high carrier mobility. [Wur06] relate this in large part to the crystalline structures of pentacene as compared with other compounds, namely a brickwork (as opposed to herringbone) structure featuring substantial pi-overlap of adjacent molecules, and adopt crystal engineering approaches to improving this property. [Den04] presents comparable theoretical analyses. A constraint on fabrication methods employed heretofore is that factors affecting the absorption spectrum such as length and functional derivatization also affect crystal packing and precursor processability. In the present invention, orbital overlap between [n]acene moieties and carbon-nanotube related structures to which these are adducted is predicted to provide excellent electronic coupling for single molecules or nanostructures, and direct manipulation during fabrication and subsequent assembly determines the location of these moieties relative to other structures. A photovoltaic cell may be realized according to the present invention by forming an adduct of an acene with a hemitube, preferably with said hemitube situated on a diamond support which has been fabricated with p-type doping (e.g. boron, according to methods and means disclosed herein, for example) especially patterned doping into specific desired regions whereby complete optical transmittance is preserved elsewhere to provide an optical path to said acene. Said acene may be a polyacene, serving both as absorber and molecular wire, or, more preferably, is contacted at a terminus or at least at a distance removed from the site at which it is adducted to said hemitube by an n-type semiconductor or a conductor terminal. Said acene may preferably comprise in addition atomic substitutions or functional groups for affecting the surface band structure of a said p-type semiconductor or a said conductor material for avoiding a Schottky diode effect, or for modifying photophysical properties of absorber moieties. For instance, the terminal ring of said acene may be formed from a 1-aza- or a 1,4-diaza-buta-1,3-diene precursor or a 1,4-dibora-buta-1,3-diene precursor (e.g. as a 1,4-diaza-buta-1,3-diene-2,3-di-yl fragment bound to a 9,10-disilaanthracene derived binding tool or a 1,4-dibora-buta-1,3-diene-2,3-di-yl fragment bound to a 9,10-disilaanthracene derived binding tool.) Alternatively, a 1,4-diamino-1,3-butadiene-2,3-di-yl fragment bound to a 9,10-disilaanthracene derived binding tool represents an example of a precursor fragment comprising functional groups for affecting electrical contact with an electrically conductive member such as a contact or terminal; similarly, a diol or dithiol could be used, or hydroxymethyl—or hydroxyalkyl—or aminoalkyl—or alkylthiol—substituents are likewise contemplated. Alternative embodiments may comprise dye molecules contacted with or covalently bonded to said oligo- and polyacenes for forming exciplexes or fluorescent resonant energy transfer complexes with said oligo- and polyacenes; these embodiments facilitate chemical tuning of absorption to specific wavelengths and for capturing more energy or for tuned photodetector devices, e.g. for optical receivers for optical communication devices, permitting processing of multiple signals of different frequency.

[Ste00] also find that adding a carbon dimer between the rows added over alternating troughs of the C(110) surface which underwent debonding causes rebonding of debonded surface atoms which is correct with respect to the diamond lattice and hence “heals” dimer induced graphitization. None of the mechanosynthesis schemes disclosed heretofore contemplate an analogous scheme availing positional control, so further aspects of the present invention are: mechanosynthetic carbon dimer addition to surface target atoms debonded from the C(110) surface due to carbon addition to an adjacent surface atom; and, causing the bonding of a graphenoid structure overlying a bare C(110) surface or surface region to form bonds to said C(110) surface by mechanosynthetic means causing the addition of one or more C-dimers to said graphenoid structure.

Note that the debonded failure products of a single C-dimer addition observed in my calculations commonly had more nearly linear dimer bonds suggesting that bond bending stresses significantly contribute to this. Apparently this results when strong C-dimer-surface atom bonds are formed and the switch-blading events observed in [Pen06] are prevented. Here I should note that my calculations involve the application of increasing compressive forces on the tool-dimer-workpiece complex until the desired dimer—workpiece-target-surface-atom internuclear separations approach single-covalent-bond lengths (<180 pm). These have seldom been observed to break once they have formed, so it is unclear how this may compare to the precise calculation steps in [Pen06]. Further it should be noted that complete dimer retention on C-dimer binding tool retraction was never observed for any of the tools investigated, although surmounting a switch-bladed intermediate configuration could sometimes involve high energetic barriers. In some cases applied forces appear to be only moderate, while in some instance these can approximate 10-20 nN (I don't consider these calculations valid for predicting precise force and pressure values because of the approximate nature of the semi-empirical methods used most extensively in this work, but these results indicate that a requirement for significantly large forces is not unexpected in various cases, but also that in spite of these high forces, compressive and tensile stresses, the desired bond forming and bond cleaving transformations are feasible and do not damage tools or supports in a wide variety of cases, indeed not in any but a small handful of instances were failure events observed beyond those discussed here.) Nonetheless, the supporting structural members (probably the weakest link) nearly always withstood the required forces and recovered correctly bonded structure in most of the few instances where bond rearrangements had occurred; for preferred tool molecules of the present invention in their preferred modes of use, structural support members never underwent bond rearrangement nor irreversible bond strain. In any case, the methods described here yield similar results independent of calculation method, which are also consistent with expectations based on chemical principles.

Separately, other 9,10-functional group substituents were evaluated on the hypothesis that electron rich substituents would push greater electron density to the silicon atoms and thus favor lower discharge forces (bond cleavage forces); to a fair approximation this was found to be the case: 9,10-bis-phenyl-substituents yielded clean dimer release without surface carbon debonding. Similarly, abstracting a hydrogen from each of 9-10-dimethyl groups, yielding a biradical structure which on C-dimer discharge is capable of forming C—Si double bonds had an even greater effect of reducing forces required for C-dimer release and hence avoiding surface atom debonding. This biradical tool displayed reactant fragment release at substantially reduced tensile force (retraction distance) permitting C-dimer addition to clean C(110) without target atom debonding, and so tools comprising at least one functional group substituent comprising at least one radicals represents a preferred embodiment of the present invention. (Methyl radical substituents do, however pose the risk that of forming tool surface adducts in the event of tool-surface collisions with Pandey chain carbons. Should this become an issue, a preferred embodiment of the present invention is the combination of 9,10-bis-phenyl-substituents with hydrogenation of target-adjacent atoms.)

Another set of substituents evaluated are oxide and hydroxide. The tool structure keeps these sufficiently far from the support structural member to which it is secured. Although these tools in the dianionic state (e.g. as would arise from hydroxyl deprotonation by base or deprotonation tool molecules) effectively added C-dimers to workpiece-target sites, they would desorb from support members on retraction, with nuclear motions resembling those expected for a retro-Diels-Alder mechanism. I speculate that despite the negative charge, oxygen is sufficiently electronegative to draw electrons from silicon in this structure, strengthening bonding to C-dimer atoms and frustrating discharge. A different approach was adopted in analogy to the case for methyl-radical substituents, namely removing two electrons. The energetic change suggests that resonable biases could accomplish this via electrooxidation. Since preferred materials for structural support members to which the mechanosynthetic tool molecules of the present invention are also semiconductors, it was realized that this afforded generally the opportunity to affect mechanosynthetic reactions both through application of electrical fields and through electron transfer. After C-dimer addition to a workpiece target site by this tool in the dianionic state, two electrons were removed from the tool-dimer-workpiece complex. The C-dimer insertion tool was then retracted, releasing the C-dimer at reasonable retraction distances and energies, without workpiece-surface atom debonding, without altering C-dimer bonding to structural support member atoms nor causing any stress induce rearrangements of bonding within the structural support member. Thus, a preferred embodiment of the present invention comprises the use of a C-dimer insertion tool comprising at least one siloxide (oxygen atom bearing one formal negative charge bonded to a silicon atom) for carbon dimer addition, more preferably in combination with a step causing a change in electrical charge of the C-dimer addition tool molecule (or the corresponding atoms of a larger structure comprising a a C-dimer addition tool moiety and a supporting structural member.)

Here it is noted that the oxide substituent may be obtained by reaction of the silane (H-substituent) the synthesis of which has been disclosed in the literature, with dimethyldioxyrane to obtain the corresponding silanol. This treatment is described as mild and thought to involve H-abstraction by the peroxide followed by radical attack on a peroxide followed by decomposition with hydrogen migration to oxygen. This occurs with retention of configuration [Sta02]. This silanol may then, as needed, be treated with base or more preferably subjected to the mechanosynthetic deprotonation described herein, yielding the negatively charged oxide derivatives.

In summary, two highly preferred embodiments for C-dimer addition are: preparing or providing a workpiece comprising at least one workpiece target-atom-adjacent-atom bonded to hydrogen or to exactly 4 atoms, and C-dimer insertion tools bearing electron rich functional-group substituents; and, preparing or providing a workpiece comprising at least one target-atom-adjacent-atom bonded to hydrogen or to exactly 4 atoms and electron rich functional-group substituents and with electron-transfer modulation (electrochemical modulation) of C-dimer binding strength. Note here that all of the foregoing proposed methods for positional mechanosynthesis disclosed heretofore have not specifically considered electrochemical processes for affecting these operations and the energetic barriers thereof, particularly the forces required.

It is widely known in the chemical arts that most reactions are far from perfect and yield less than quantitative conversion of reactants to desired products; here it is noted that in positional mechanosynthetic operations such as those of the present invention, trajectories, orientations and forces may be optimized in a ways not possible in conventional chemistry, and many operations may take place on femtosecond to picosecond timescales, which is to say faster than many undesired reactions. A detailed analysis of such issues was presented in [Dre92] and similarly in [All05] showing extremely low frequencies of reaction failures when factors such as the foregoing obtain.

An additional method for facilitating cleavage of desired bonds involved ultrasonic frequency mechanical vibration of tool-workpiece separation tuned to frequencies which pump energy into those modes which excite tool-dimer bonding orbitals, thus supplying a portion of the energy required for the desired cleavage without also promoting undesired cleavage, debonding or rearrangement events. Because this involves complex interactions of modes and will be highly dependent on specific geometries and system configurations, this is best tested experimentally, but may provide for lower operation energies and hence energy efficiency.

Chemisorbed oligoacenes and polyacenes ([n]acenes), especially anthracenes and their substituted analogues represent both useful tools which may be charged with C2 for use as carbon dimer addition tools and a favorable platform whereby other chemical functionalities can be securely bound to a surface in a well defined and stable way. Alternatively, in some cases (e.g. for the Si mechanosynthesis disclosed herein) the various oligo- or poly-acenes or related hydrocarbons with suitable modifications may serve both as tools comprising atoms for binding reactants or functional groups serving as tools and also support members, providing a very convenient bridge between conventional chemistry and the present invention.

Oligoacenes and polyacenes chemisorb to clean Si(100)-2×1. K. Okamura et al. [Oka04] studied the adsorption of anthracene on a Si(100)-2×1 surface using infrared reflection absorption spectroscopy in the multiple internal reflection geometry (MIR-IRAS) technique and find bonding via anthracene atoms 1, 4, 5 and 8, resembling a [4+2] Diels-Alder cycloaddition of the non-central benzenoid rings to adjacent Si surface dimers within the same dimer row. Pentacene yielded similar findings for adsorption parallel to dimer rows but also yields adsorption perpendicular to dimer rows which appears to involve the same atoms in a given ring (1,4) but not the same rings. Similarly, G. Hughes et al. [Hug02] used STM to find that pentacene adsorption occurs in three modes: on top of dimer rows, between dimer rows and perpendicular to dimer rows. Not all of these orientations are most desirable for the present invention, but low coverages (which is in any case preferable for early embodiments of the present invention where a single carbon dimer is added per addition cycle) permit sufficient separation between adsorbate molecules that those with the most desired configuration (on top of dimer rows) can be identified as per Hughes et al. [Hug02], i.e. those with positive contrast (bright) in filled state images and negative contrast (dark) in empty state STM images. Presumably, similar contrast relationships would occur for anthracene bound on top of dimer rows, which is a preferred case for use with the present invention. Thus the teachings disclosed in [Hug02] for adsorbing polycyclic compounds to (100) surfaces and also for determining precise adsorption configuration are incorporated herein by reference. It is noted in addition that molecules adsorbed at undesired sites or in undesired configurations may be eliminated by shearing these away with an SPM tip advanced towards a sample at an appropriate position in the course of tracing a scan line across such undesired molecules. Since this process may grind away at a tip, this should preferably be done after other operations are completed.

The frequency of desired orientations and bonding of oligoacenes and polyacenes as well as other tool molecules useful with the present invention can be enhanced in two independent ways, which more preferably are used together. First, hydrogen passivated surfaces may instead be used and hydrogens abstracted from dimers at sites selected for tool-molecule chemisorption. Second, molecules to be chemisorbed may be mechanically transferred from a molecule chemisorbed on a second surface, structural support member or SPM tip to which the molecule to be chemisorbed is specifically bound. A particularly facile case is that of a charged C2 binding tool secured to a support, the carbon dimer of which reacts with the 1,4 positions of a ring of the oligoacene or polyacene to be deposited to a predetermined target site. This arrangement may be termed dimer-cross-bridging. The reaction involved is apparently a Diels-Alder [4+2]cycloaddition, although two isolated radical attacks cannot be ruled out. Factors affecting C2 dimer discharge in the use of such tools for C2 dimer additions can similarly be adjusted to determine whether the cross-bridging dimer is retained by the oligo- or polyacene which is deposited or the tool used to deposit this species. The beauty of this approach is that the same tool used to perform a desired mechanosynthetic reaction is used in a distinct mode but utilizing similar chemical principles to position, secure or assemble similar tools, although it should be noted that one such system can deposit distinct tools with different functionalities or substituents if these are provided, and deposited moieties may be deposited in an entirely different configuration or pattern than that of the tool or tools used to deposit them. In particular, it should be noted that this methodology is useful both for self-replicating systems but also allo-replicating systems, that is, systems with similar positional-mechanosynthetic capability utilizing similar chemical and physical principles but entirely different in design, structure, symmetry or scale or even material composition (e.g. a fabrication system with dimer addition tools supported by Si fabricating a daughter fabrication system with dimer addition tools supported by Si-beta-SiC structural members.

Alternatively, specialized tool-molecule deposition tools (which themselves may be and generally are molecules) may be used to positionally deposit tool molecules. Compound 6 of [Oba01] wherein the two silicons of each of two 9,10-disilaanthracene derivatives are bridged via an oxygen linkage would represent such a case if used with the present invention. A case in the chemical literature directly applicable to this for 1,4-disilabenzene was disclosed in [Dys01]. Cyclopentadienyl-Ruthenium-bis(trimethylphosphine) derivatives bound to the silicon atoms. Presumably this would extend similarly to 9,10-disilaanthracene. Another instance of metal-1,4-sila-acene bridging is found in the reaction of 9,10-disilaanthracene with alkyne disclosed in [Oba01], specifically palladium compound 3 of that disclosure (for the present purpose palladium could be held by one or more coordinating ligands, e.g. phenylenes.)

Note that where adsorbed molecules are precisely positioned and oriented, it becomes possible to do multiple carbon dimer additions in parallel in a single addition cycle provided that registry between sites of dimer insertion tool adsorption and C2 insertion target sites on a workpiece is maintained, which will depend most significantly on the crystal lattice of the tool substrate or structural support member and the lattice of the workpiece. One simple case which illustrates this is anthracenic insertion tools on Si(100)2×1 on top of dimer rows used to fabricate a diamond nanostructure via addition to a (110) surface. Since the C2 of a charged insertion tool would lie directly over Si subsurface atoms bound to each of the Si dimers to which the anthracenic tool is bound, the Si lattice determines allowable periodicities for tools along dimer rows. For any given specific tool, there will be an optimal angle (projected onto the C(110) surface) between the axis of the carbon dimer to be added and the two workpiece carbon atoms of adjacent Pandey chains on the C(110) to which the dimer is to bridge upon addition. Preliminary calculations have shown that a parallel orientation permits successful addition and discharge, although it has not yet been determined whether this is optimal. Alternatively, the carbon dimer axis can be parallel to the bond between the two subsurface carbon atoms to which the two surface atoms to which the dimer is to be added are bound. For any given tool and set of conditions, it is expected that the optimal angle as well as other operational parameters will need to be determined empirically, as well as the efficiency at other angles. This angle is then expressed as an angle relative to Pandey chains, and a line at this angle to the Pandey chains crosses Pandey chains at a characteristic period of Pandey chains. To a fair approximation, the least common multiple of the period of Pandey chains along this line and the lattice spacing of the tool substrate sets the lower bound on spacing of dimer insertion tool molecules along Si dimer rows. Tools may be staggered along different rows with a similar periodicity to maximize their surface density for the case of support on a flat Si(100)2×1 surface.

A further type of surface or material composition for structural support members which may be used according to the present invention for supporting molecular tools for performing mechanosynthetic operations is diamond itself. This of course yields excellent mechanical strength and also excellent thermal conductivity, but most importantly, means that nanostructures fabricated according to the present invention may themselves serve as components in systems for implementing the present invention. While this is a trivial example of one requirement for K. E. Drexler's proposed self-replicating nanoassembler, it is also quantitatively the most demanding and qualitatively the final one to be addressed (in that all other requirements must be met before this one may practically be contemplated.) Here, platform moieties are bound to radical sites formed on diamond surfaces, especially and most preferably surfaces fabricated by means of the present invention. Here, rather than Diels-Alder type reactivity, direct radical additions to unsaturated carbon-carbon bonds are most preferred.

In the course of performing calculations on tool molecules on Si(100)2×1, I realized that there may exist a case in nature where Si atoms are situated appropriately for carbon dimer binding and with likely properties similar to that of the present tool molecules under study, but which would not generally be the province of organic chemistry. This is the binary material beta-SiC which is separately also useful for the present invention as a substrate or material for structural support members as described above. In nature this occurs as the mineral Moissonite, thought to be extraterrestrial in origin. On the perhaps naïve speculation that Si atoms on Si-beta-SiC(100) would form dimers as with Si(100)2×1, calculations were performed on a structure having a carbon dimer bridging two Si dimers of adjacent dimer rows (such that the all of the atoms of the carbon dimer and the two silicon dimers lie in the same plane). These Si dimers are more closely spaced than those of Si(100)2×1, permitting adjacent collinear dimers from each of which at least one hydrogen has been abstracted to bond to C2 forming a bridge structure. Preliminary AM1 calculations showed this to perform very satisfactorily on initial attempts, with more favorable energetic barriers than other systems considered, resulting in transfer at greater C-dimer-C-target internuclear separations, and also in tool-dimer discharge at shorter retraction lengths (presumed to correspond to lower release tensions or forces, which is important to prevent stress-induced product rearrangements,) in spite of the fact that the exothermicity of tool discharge is much smaller than the endothermicity of forming the desired C2 dimer-C(110)-surface adduct, indicating that the reaction is driven to the intermediate by input mechanical energy, and that the mechanical energy of tool retraction preferentially destabilizes the tool-C-dimer bonds rather than the newly formed C-dimer-workpiece bonds. As with other tools disclosed herein, there is further the potential for use with other reactant moieties. Thus, a preferred embodiment of the present invention, most generally, is a method for forming a reactant binding site on Si-beta-SiC(100)2×1:H (or related reactant binding site structural members as described below) by abstracting at least one hydrogen from a surface Si atom, more preferably, by abstracting one hydrogen from each of two adjacent Si atoms where each Si atom is part of a different collinear surface Si-dimer, and more preferably still abstracting one hydrogen from each of three Si atoms of two adjacent collinear surface Si-dimers including the two adjacent Si atoms of two different surface Si-dimers. Another useful configuration is obtained by abstracting four hydrogens from two adjacent collinear surface Si-dimers. Note that various cage SiC molecules may comprise accessible atoms in the same configuration and such molecules or nanostructures are similarly useful for the present embodiment of the present invention even if they do not comprise atoms with bulk-type coordination. These are prepared by the same sets of hydrogen abstractions listed above. Most generally, the surfaces of the bulk material and related molecules or molecular nanostructures are all reactant binding site structural members. For instance, the cage molecule structures on which dimer loading reactions and dimer addition reactions were calculated are better described as molecules or molecular nanostructures than bulk materials with flat surfaces, so these would not ordinarily be considered topics of surface science. Nonetheless, these feature similar configurations of atoms (comprising a fused [3.1.3] bicyclic ring structure) for binding reactants and thus may be used interchangeably. One relatively minimal structure (used for calculations described herein) comprising this substructure is a tetramantane framework of Silicon Carbide composition, where each adamantane unit shares 3 atoms (2Si and 1C) with each neighboring adamantane unit, with one hydrogen removed from each of 4 adjacent silylene silicons to permit bonding analogous to (100)2×1 reconstructions (whether or not additional hydrogens are removed as described above for the preparation of reactant binding sites.) A further aspect of the present embodiment of the present invention is the loading of this class of reactant binding sites. This is favorably accomplished by exposing this class of reactant binding sites to reactant molecules reactive to dienes ore reactive towards radicals. For example, acetylene is predicted (AM1) to react with two adjacent collinear fully dehydrogenated Si dimers (triplet ground state) to form the desired bridge structure (with two vinylic hydrogens which are then removed by abstraction to yield the desired ethyne bridge.) A similar reaction is predicted for the didehydrogenated reactant binding site, although in this case silyl radicals of the two monodehydrogenated silicon dimers do not have any silene character and the acetylene molecule twists so that each silyl radical can attack a different acetylene pi orbital, and a twisted bridging vinyl is formed; this may undergo intersystem crossing to the more stable singlet state, which has the vinyl carbons and hydrogens in the same plane as the silicon dimers, although the relaxed triplet geometry is destabilized by more than 16 kcal/mol at the singlet electronic structure so this triplet might be stable for extended periods. Nonetheless, abstraction of vinylic hydrogens yields initially a quintuplet state structure which relaxes to the desired coplanar conformation.

Where only one hydrogen is removed from a hydrogenated Si dimer, it is expected that the single naked Si atom will have greater radical character than the naked Si atoms of a doubly dehydrogenated dimer, facilitating the desired C2 charging reaction. Here it is noted that analyses [Cat01] of the C terminated beta-SiC(100)2×1 (C-beta-SiC(100)2×1) find substantial sp-character to the C—C bond and bond lengths consistent with triple bonds, as for the case with carbon dimers to be inserted according to the present invention. This supports the view that an isolated carbon dimer bridging two monodehydrogenated Si dimers on Si-beta-SiC(100)2×1:H might have similar bonding, as found by my own calculations. It should also be noted that even when a small region or island of Si dimers is dehydrogenated, e.g. a few dimers in a single row, as may often be useful in various embodiments of the present invention, neighboring hydrogenated Si dimers impose boundary conditions impeding undesired reconstruction to other surface configurations. It is interesting to note that, fortuitously, [Cat01] find that the B (bridged) reconstruction of C-beta-SiC(100), having the same structure as that of the present embodiment of the present invention i.e. a loaded C-dimer binding site on Si-beta-SiC(100)2×1:H, is predicted to be the most stable reconstruction by GGA-PBE calculations, and that this structure yields density maps in agreement with experimental STM measurements.

V. Derycke et al. [Der01] note that beta-SiC has higher ionicity than other group 14 covalent materials. Presumably, a carbon dimer bound to Si atoms on surfaces of this material may be expected to be more like carbide than other cases. Since charge transfer is incomplete, as a carbon dimer is transferred to a workpiece target, a carbon dimer might be expected to back-transfer charge and at some point along a transfer pathway resemble the C2 used as a feedstock in various diamond CVD methodologies. Compared to previous proposed carbon dimer addition tools, to my knowledge this is the first comprising a fused [3.1.3] bicyclic ring structure, i.e. analogous to bicyclo[3.1.3]nonane (with the circumferential ring being an 8-membered ring.) Considering SiC as a material with significant ionicity suggests that other phases of SiC may similarly be suitable for the present invention, and, generalizing this further, that other ionic materials or materials having high ionicity (and preferably also hardness and perhaps conductivity or semiconductivity) such as titanium carbide, tantalum carbide, aluminum carbide, tungsten carbide, magnesium oxide, aluminum nitride (especially the cubic or rock-salt phase), titanium nitride, vanadium nitride, chromium nitride, manganese nitride, platinum nitride (PtN2,) iridium nitride (IrN2), titanium oxide (anatase [especially the (101) surface], rutile or brookite,) alpha-aluminum oxide (especially the relaxed (1000) surface wherein Al atoms are about 270 pm apart,) tin oxide, tungsten sulfide, and materials having a cubic, B1 or rock-salt crystal structure may similarly be useful for use as carbon dimer binding surfaces for these variations of the present invention. Carbon dimers would be expected to bond to metal atoms, and especially along surface exposed metal-metal bonds (e.g. the intermetallic diagonal of the (100) surface of the halite (also referred to as B1 or rock-salt) unit cell, or the Ti—Ti bond on the 101 surface of anatase). Given the extensive use of transition metals in catalysts for organic transformations including carbon-carbon bond forming reactions, transition-metal carbides, nitrides, oxides, sulfides and tellurides immediately present categories of interesting candidate materials and surfaces, as do compounds of titanium, zirconium, tantalum, vanadium, chromium, cobalt, rhodium, rhenium, iridium, platinum, palladium, silver, nickel, copper and zinc. Note that materials with rock-salt or halite or B1 structure are preferred cases also because the (100) surface is unlikely to reconstruct in most cases. Given their uses in organometallic chemistry, materials comprising main group metals such as tin, aluminum and lead may also be useful. To my knowledge, this is the first proposal that simple surfaces of binary materials or of ionic materials may be used to bind precursor species for positional mechanosynthesis. Since metal atoms are directly involved in carbon binding in many of the foregoing cases, the possibility of using metals follows logically. Depending on the energetics of surface diffusion of carbon dimers along the surface of a given material, passivation may be necessary in particular cases to confine reactant molecules to predetermined locations, and in addition, low temperature may be required for some materials, while in other instances low temperature is sufficient to impede surface diffusion; therefore rectant adsorption at liquid nitrogen or even liquid helium temperatures represent preferred embodiments. These aspects of the present invention are summarized as follows: providing a surface of a binary or metallic material or a metal; adsorbing molecules comprising two carbon atoms to said surface; as necessary, removing hydrogen atoms from said molecules comprising two carbon atoms; providing a workpiece comprising two target atoms; contacting at least one of said molecules comprising two carbon atoms with said target atoms of said workpiece, where said contacting optionally occurs with applied force; optionally adjusting the electrical potential bias of said binary or metallic material or the said surface thereof; and withdrawing said binary or metallic material from said workpiece with force sufficient to break bonds to said at least one of said molecules comprising two carbon atoms.

Additionally, despite experimental complexity and difficulties in performing sensitive enough measurements to resolve different possibilities, it has recently [Min06] been determined that acetylene binds preferentially in a [2+2]cycloaddition atop the unhydrogenated silicon dimer of Si(100)2×1, at least at low coverages (whereas end-bridged and pedestal configurations involving multiple dimers become important at higher coverages.) As an embodiment of the present invention, this structure represents a binding tool for binding acetylene. This type of tool may be used according to the methods disclosed herein for carbon dimer deposition, via at least two distinct modes. In a first mode, hydrogens are abstracted from adsorbed acetylene to form a bridging carbon dimer, used as other disilicon bound carbon dimer loaded tool disclosed herein. In an additional mode, this structure may be used to contact dienes or radicals for positional synthetic or positional mechanosynthetic operations involving one or more acetylene reactants. Similarly, the butadiyne (diacetylene or buta-1,3-diyne,) found to yield cumulene adsorbate structures via [4+2]cycloaddition to a single 2×1 surface dimer of dehydrogenated Ge(100)2×1 and also predicted to be a minor product on 2×1 dimers of dehydrogenated Si(100)2×1. [Lu04] [Hua04] Accordingly, Si and Ge dimers of this type represent binding tools for binding this compound, and may be used for mechanosynthetic operations with cumulene reactants. Because of the high reactivity of cumulene species and the simplicity by which the readily synthesized diacetylene may be used as a reactant for positional mechanosynthesis. See FIGS. 16.a,b,d. and FIGS. 18.a-b. In a very simple case, hydrogens are removed from target atoms and target-adjacent atoms on a C(110) surface of a workpiece such that surface radicals attack a cumulene carbon atom of a double bond, yielding a radical on the other carbon of the attacked double bond, which then reacts with a target atom located adjacent to a dehydrogenated target-adjacent atom, as for a radical attacking a surface double bond. (Note that various calculation methods predict dehydrogenated target atom-target-adjacent atom pairs to be singlets while others predict triplet ground states; removing a hydrogen atom from a further adjacent atom yields a structure like an allyl radical which is rather consistently predicted to have a doublet ground state and also to cleanly react like the double bond in an allyl radical, that is, to accept attack by a radical and form a bond therewith.) Further, longer polyynes (e.g. hexatriyne, octatetrayne, etc.,) may similarly bind to collinear dehydrogenated silicon or germanium dimers and serve as reactants consistent with the foregoing, with applied pressure by the silicon or germanium member forcing the desired reaction to completion. Note that to the extent carbon dimers deposited on C(100) bind to more than two surface atoms as predicted by some calculation methods, cumulene reactants offer an attractive reaction chemistry, for adding carbon thereto while avoiding any difficulties caused by those structures. Note that the foregoing cumulene addition methods and means may alternatively be applied to deposition of cumulenes to workpieces or workpiece target sites with complete surface dehydrogenation (that is, bare workpieces without passivation) or other patterns of radicals or of unsaturated surface bonds or other patterns of depassivation.

Thus, as conceived here, perhaps one of the simplest possible tools for positional mechanosynthesis may be formed by the cleavage of a binary material or an ionic material, or the above noted crystalline materials, to which a carbon dimer (C2) or acetylene or ethylene adsorbs or is otherwise transferred, forming a carbon-dimer-loaded carrier surface. The surface chemistry of this material may be modulated by passivation, especially by hydrogen, and in particular predetermined loading sites may be defined by passivation. Hydrogen is abstracted from hydrogen-containing reactants (e.g. acetylene, ethylene.) This carbon-dimer-loaded carrier surface is then juxtaposed to the surface of a workpiece or material under synthesis with carbon dimers situated directly across from target sites and contacted thereto, generally with an applied force. Optionally, in some preferred embodiments, target sites on a passivated workpiece may be predefined by hydrogen abstraction from a hydrogen passivated workpiece surface region wherein at least two atoms undergo hydrogen abstraction. Optionally, in some preferred embodiments, the electrical potential of the carbon-dimer-loaded carrier is varied, whereby either carbon dimer addition to a target site or carbon dimer release from the carrier surface may be facilitated at different potential bias for different materials.

Since quantum calculations cannot be expected to always faithfully predict surface reconstructions at the present refinement of that art, a review of the literature on the topic of beta-SiC surfaces was undertaken. Experimental evidence exists that, fortuitously and surprisingly given the pitfalls of surface reconstructions, despite the particular complexity of SiC surface reconstructions the above speculation holds for Si dimer formation in the special case of H passivation whereby p(2×1) reconstruction to Si dimer rows is obtained.

Further variations involve the substitution of cyanide (radicals or anions) or carbon boride (CB, radicals or cations) for carbon dimers whereby nitrogen or boron doped diamond nanostructures may be obtained. These may be accomplished by loading these molecules themselves onto C-dimer addition tools or by reacting precursors of these, e.g. H2CNH or HC2BH via, for example, Diels-Alder [4+2]cycloadditon to appropriate dimer addition tools and performing hydrogen abstractions to obtain the desired reactive fragment. Alternatively, binding tools may be lithiated at dimer binding atoms and contacted with organoborohalides such as Cl₂BCCl₃, Cl₂BCCl₂H or Cl₂BCClH₂ which are expected to yield the desired adduct via two S_{N}2 reactions, after which remaining halogens and hydrogens, if any, are abstracted therefrom to yield the desired tool-bound precursor fragment. Note that unprecedented control of dopant location may thereby be realized, which may be particularly useful for applications in quantum electronics or requiring other advanced material properties. The heteroatoms these species contain have been of interest for doping diamond materials thereby imparting semiconductivity, conductivity or superconductivity. Interestingly, boron-doped diamond (which occurs in nature as blue diamonds) has p-type semiconductivity which reportedly under various conditions of hydrogen termination can switch to n-type semiconductivity, so that three mechanisms (B doping, N doping and H termination) are available according to the present invention for modifying the semiconductive properties of diamond and nanostructures of similar composition. Mechanosynthetic addition of CB enables the fabrication of boron-doped diamond nanostructures or regions thereof; beyond useful semiconductive properties, heavily boron-doped diamond (10²⁰-10²² B atoms/cm³) is reported in the scientific literature to have metallic conductivity and to be superconductive at low temperatures [Eki04] with a report of transition onset as high as 12K, and is also reported at least in some instances to have metallic conductivity. B-doped diamond has also attracted substantial interest in electrochemistry for use as electrodes with advantageous electrochemical properties including chemical resistance, oxide formation resistance, and stability, [Mon03 and references therein; also note use as supports for catalytic particles on such electrodes therein]. [Iba04] notes “the boron-doped diamond electrode [.] is quite durable, resists oxidation, and has a large overpotential for oxygen production; this last property makes possible the oxidation of other substances with standard potentials higher than that for the oxidation of water. Substances that have been treated by this technique include: Organic compounds. Phenols, aromatic amines, halogenated compounds, nitrated derivatives, fecal wastes, dyes, aldehydes, carboxylic acid anions, etc. Inorganic compounds. Perhaps the inorganic substance that has been most commonly treated by the electrochemical route is cyanide. The main product is the much less toxic cyanate ion.” Boron-doped diamond also has optical transparency under different conditions or compositional ranges; whereby application requiring the combination some degrees of transparency and conductivity, particularly photovoltaic and display applications. Photovoltaic devices have been fabricated comprising heterojunctions of p-type B-doped diamond and n-type P-doped silicon (and also junctions between n-type P-doped C and B-doped n-type Si,) [Rus05], materials and structures which may be fabricated according to the present invention.

A further facile method for fabricating ligands in communication with structural members for various uses in the present invention including for binding metals for binding reactants for positional deposition of said reactants, for binding metals for positional deposition or positional electrodeposition, or for binding metal atoms or ions for binding to ionic or radical sites on workpieces for nanomanipulation of workpieces, is provided. For diamond, diamondoid or diamond nanostructure structural members, one or more hydrogens are abstracted from one or more target sites at which it is desired to form a ligand; most preferably, said one or more target sites is/are tertiary alkyl carbon atom(s). The resulting radical(s) is/are then halogenated, e.g. by exposure to a halogen gas such as Cl₂ or Br₂ or alternatively by contacting a halogenation reagent to said radical, whereby a halogen is situated at said target site. Halogenation reagents or halogen gases are removed or excluded, and halogens are permitted to be eliminated to yield cations at said one or more target sites. The resulting carbocations are then contacted with or exposed to molecules comprising atoms for serving as ligand atoms; for example, phoshine or ammonia molecules in gas phase, or alternatively dissolved in inert solvent, or alternatively bound as ligands to metal complexes comprising one or more second ligand linked to a second structural member for positioning thereof (i.e. a metal complex comprising a ligand bound to said second support for positioning said metal complex and comprising as a ligand a molecule to be deposited at said carbocation target site; so for example an amine on a second structural support may bind to a copper atom itself bound by five other ammonia molecules as in an ordinary cuprous amine complex, and said second structural member is translated to contact said carbocation whereby said carbocation is permitted to react with one of said ammonia molecules, whereafter said second structural member is withdrawn leaving an ammonium group at said target site.) As necessary, the product is treated with base or a proton removed via a base tool. After all atoms necessary for fabricating the desired ligand at said target site are added, said ligand may be contacted with a metal atom for binding thereto, e.g. by contact with a metal complex bound to said second structural member or to a third structural member, or alternatively by contact with a solution or vapor comprising the desired metal atoms or ions. In a convenient alternative, an organometallic complex comprising ligands having atoms which may react in nucleophilic reactions may comprise a ligand in communication with positioning means for positioning said organometallic complex and one or more preferably two or more ligands for deposition to said target sites; said ligands for deposition of organometallic complex are contacted with said target site whereby bonds are formed thereto; said positioning means are withdrawn, whereby at least said ligands for deposition and more preferably also a metal atom or ion bound thereto provided in said organometallic complex are deposited at said target site and said positioning means are withdrawn with scission of one or more metal-ligand bonds. Note that more complex ligands in communication with or integrated into structural members may be similarly fabricated from larger molecules, such as azacyclopentane (C₄H₉N) or phosphocyclopentane (C₄H₉P), for example reacting with target sites from a gas phase exposed thereto, or a liquid or solution contacted therewith. A preferred target site consists of two adjacent carbon atoms of a hydrogenated C(110) surface. According to the foregoing, ligands analogous to those of [Mu102] (e.g. PN ligand) for binding metals such as zero-valent nickel for binding to unsaturated bonds may be formed on diamond surfaces or nanostructures or related molecules.

Note that [Mu102] disclosed insertion of ethynyl groups into the strained bond of biphenylene. Calculations using different methods including higher levels of theory (not shown) sometimes find that graphenoid structures with adjacent radicals may form similar four-membered rings, which would impede some of the foregoing mechanosyntheses, although this issue is not yet fully resolved and is the subject of further investigations and efforts; nor have I yet obtained consistent results concerning the rapidity with which this would be expected to occur if it does occur. Tools comprising zero-valent nickel or other metals with unsaturated reactants bound thereto similarly to the complexes of [Mul02] may accordingly be used to insert reactant fragments into strained bonds such as the foregoing four membered rings to yield the desired results. Note that turnover rates observed by these workers, although improved over those of diphosphine ligands, and the fact that these reactions are conducted at moderate temperature suggest that there remains a significant energetic barrier for this reaction; in the present invention, applying mechanical force to force the metal against and into a target bond to be inserted into followed by the application of force to an unsaturated ligand to be inserted thereinto, said force directing said ligand into the desired target site and displacing the metal atom temporarily inserted therein may yield more rapid and facile reactions, and these may more preferably be performed at lower temperatures such as ambient temperature or below. In the foregoing, force is applied by steric members of structural members preferably in communication with independent actuators for applying force, similar to the case with expansion additions disclosed herein. Similar insertions are likewise contemplated using similar tools for inserting carbon dimers and other reactant fragments into the strained bonds which are predicted by some methods to be formed subsequent to dimer deposition on C(110) diamond; other metals known to be active for insertion into strained carbon-carbon bonds include rhodium (Rh) and iridium (Ir) although any metal found to usefully display this property may likewise be used.

Turning to abstraction tools, several alternatives exist for securely situating and alkynyl group on a surface or structural member in orientations useful for hydrogen abstraction. A particularly facile case utilizes 9-anthrone bound, as above for anthracene, to Si dimers forming a platform. This surface adducted platform is then treated with an acetylide such as acetyling Grignard (HCCMgBr), monolithium acetylide (LiCCH)[Mid93], or monosodium acetylide (NaCCH). These are expected to react via attack of the negatively charged acetylide carbon on the carbonyl carbon on 9-anthrone, yielding a surface adducted structure with a negatively charged oxygen paired with a cation from the acetylide reactant and presenting the ethyne group away from the surface. Note that because hydrogenated Si surfaces may be anticipated to have acidic character, it may be desirable to passivate this surface via hydrosysilylation of terminal vinyl compounds such as propene after platform adduct formation. Alternatively, 9-chloro-10-hydro-anthracene may be used and the reaction with an acetylide such as those listed above is a simple S_{N}2 reaction. Other olefinic compounds bearing carbonyls or halides or halide equivalents may be substituted in direct analogy to the foregoing, so, for example, 5-chloro-cyclohexadiene, 5,5-dichloro-cyclohexadiene, -cyclopentadiene or 5,5-dichloro-cyclopentadiene may serve as a platform and subjected to a similar S_{N}2 reaction with acetylide. Alternatively to reaction of acetylides to surface adducted platform moieties, the same reaction may be done before chemisorption to structural support members or substrate surfaces, avoiding the direct treatment of the latter with acetylides. A disadvantage of this for the case of conventional chemisorption is that there is competition between the ethyne group and other unsaturated bonds of the platform moiety for bonding to surface atoms, potentially yielding mixed binding modes; although this is not desirable it may be tolerated by mapping properly and improperly bound abstraction tools (e.g. using STM or SPM methods) and using only properly oriented abstraction tools selected for use, which is controlled by determining tool-support trajectories contacting only these correctly oriented tools with workpieces. There is in addition a minimal case whereby useful abstraction tools may most simply be obtained: direct [2+2]cycloaddition of buta-1,3-diyne to a single Si dimer; this case omits use of a distinct platform moiety distinct from the functional group to be secured to a surface or structural support member, rather employing the same chemical functionality for the two distinct purposes. A review of the literature found both theoretical [Hua04] and theoretical and experimental [Min06] investigations for other purposes of precisely this adduct to a 2×1 Si(100) surface, and also 2×1 Ge(100) and 7×7 Si(111), finding in the first case that this adduct forms as the major product with an ene-yne structure. A potential shortcoming of this, however, is that the resulting structure is less stabilized against dynamic motions of the terminal carbon atom to be used for hydrogen abstraction, but such a tool may still be sufficiently stable to be useful. Note that for the case of hydrogen abstraction from silicon surfaces (and to a lesser extent beta-SiC surfaces)—operations useful in implementing the present invention, the larger lattice spacings of these materials relative to diamond somewhat increase absolute tolerances for positional errors, so that even if positional error inherent with this type of tool is problematic for hydrogen abstraction from diamond, it may still be a valuable alternative hydrogen abstraction tool for the present invention. Some stabilization of the desired configuration against lateral rocking of the projected ethyne group may be imparted by forming adducts of small unsaturated organic molecules with adjacent surface dimers, e.g. acetylene, ethylene, propene and possibly also rings such as benzene. This ene-yne adduct may be charged for use as an abstraction tool by contact with monovalent copper, base and divalent copper or alternatively electrooxidation in place of divalent copper, as detailed below (especially if the underlying silicon or germanium structure is doped to impart conductivity.) Note that the alternative adduct structure found by those workers, the [4+2]cycloaddition adduct having cumulene structure exclusively formed with 2×1 Ge(100) dimers and to minor extent with 2×1 Si(100) dimers find use as intermediates for addition of cumulenes to workpieces. See FIGS. 16.a,b,d. and FIGS. 18.a-b. for examples of use according to the present invention.

An additional instance of particular interest is that of an ethyne group situated on an acene such as naphthalene bound to a binding tool of the present invention; e.g. 1-ethyne-naphthalene-6,7-di-yl bound to a 9,10-di-silaanthracene platform which, for example, may be bis-adducted to an Si(100)2×1 surface; this instance features an ethyne group directed parallel to the platform moiety. This arrangement is particularly useful for hydrogen abstraction steps in the oligo- and polyacene fabrication methods disclosed herein; this may be termed a lateral abstraction tool to distinguish from the more common axial or surface-normal abstraction topology.

A particular preferred embodiment for forming ethyne-based hydrogen abstraction tools may be realized via an S_{N}1 reaction with a structural support member adducted platform moiety. For example, 9-methyl-9-halo-10-hydro-anthracene may be chemisorbed to a Si(100)2×1 surface (preferably hydrogenated with hydrogens abstracted from dimers to which an adduct is desired to be formed; more preferably a bare surface may be used which is hydrosilylated to 1-propene following platform moiety chemisorption, whereby deprotonation of this surface by acetylide may be avoided.) This molecule is a tertiary halide, and thus is prone to liberating a halide anion to leave a tertiary carbocation. To ensure that electron transfer does not occur from a semiconducting or conducting support to the resulting carbocationic center, such supports are preferably held at a positive electrical potential. An acetylide (e.g. NaC₂H) is then contacted with the support-bound carbocationic platform to form a support-bound 9-methyl-9-ethynyl-10-hydro-anthracene, which, due to the foregoing process by which this structure is formed, presents the ethynyl group in the desired projection away from said structural support member.

Having variously formed appropriately secured and oriented ethyne groups, these must be converted to appropriate radicals to be useful as abstraction tools. Although [Dre92] and [Mer97] propose various schemes for obtaining ethynyl radicals, more facile methods may be adapted from reactions established in the chemical literature. Note that for the following, molecular oxygen and radical scavengers must be rigorously excluded from reaction volumes. A first method for ethynyl radical tool preparation or recycling comprises deprotonation of ethynyl groups by base or by contact with alkaline metal, followed by oxidation. Oxidation may be done by contacting deprotonated ethynyl groups with oxidizing agents such as cupric acetate (Cu(II)(H₃CCOOH)₂) or preferably with Cu(II) bound to support-bound carboxyl groups (e.g. a carboxylate group on an oligophenylene or polyphenylene structural support, or on a diamondoid structural support.) Since Cu(II)(H₃CCOOH)₂ is known to form a “Chinese lantern” complex of stoichiometry Cu(II)₂(H₃CCOOH)₄ with each copper atom bonded to one oxygen from each acetate molecule, supports presenting colocalized carboxyl groups capable of adopting appropriate conformations and orientations for forming this complex are a preferred embodiment of the present invention. With Cu(I) and Cu(II) bound to immobilized carboxyl groups and amine bases such as ethylene-diamine, ethynyl radicals may be prepared in the same manner as they are in Eglinton coupling reactions (see [Cli63] for a mechanistic analysis of this reaction and experimental factors affecting its course) with the distinctions that since ethynyl groups are fixed on a support they are prevented from coupling, and that because copper ions are bound to carboxylates tethered to a second support, copper ions may be mechanically pulled away from ethynyl groups to yield naked ethynyl radicals. A second and more convenient alternative for ethynyl anion oxidation is simple electrooxidation of a base deprotonated ethyne (i.e. a naked ethide group, RCC—). Where the platform moiety bearing an ethynyl group to be converted to an ethynyl radical is bound to a conductor or semiconductor support, a positive electrical potential or bias is applied to said support. In cases where said ethynyl group is situated on an insulating support, said ethynyl group may be brought into close proximity to a positively biased electrode; in this case direct contact (i.e. separations less than about 250 to 350 pm between the nearest electrode atom and the apical ethide group atom) is preferably avoided to preclude bonding of ethide groups to metal atoms or other atoms of said electrode, or other reactions of the ethide or formed ethynyl radical with atoms associated with said electrode. Instead, electron tunneling processes or field emission may accomplish the desired electron transfer yielding the desired ethynyl radical. A closed circuit is unnecessary since the starting electronic configuration comprises a charge to be transferred and not replaced. Here it should be noted that the same molecule serving thus as an abstraction tool can serve as a deprotonation tool (base) by omitting this oxidation step.

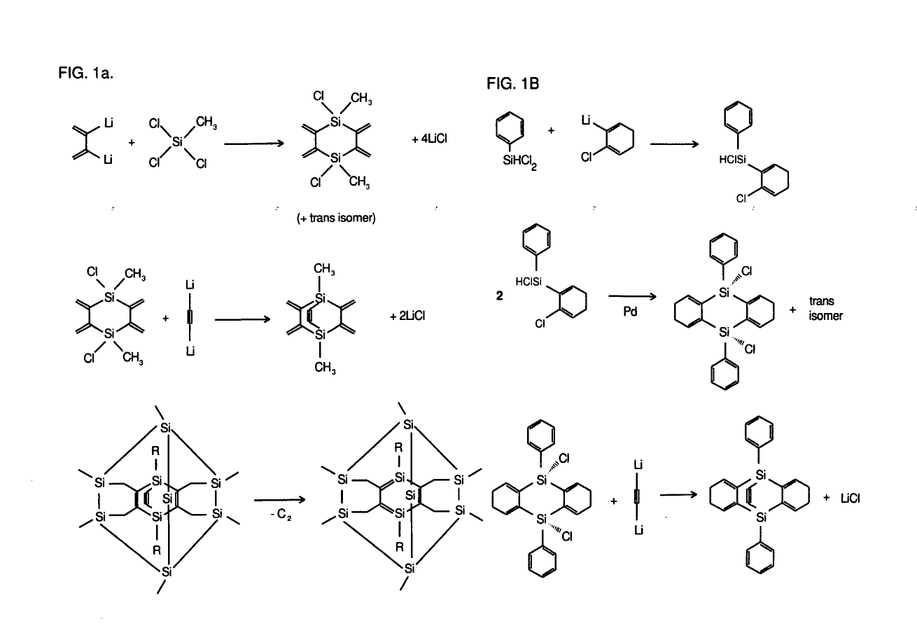

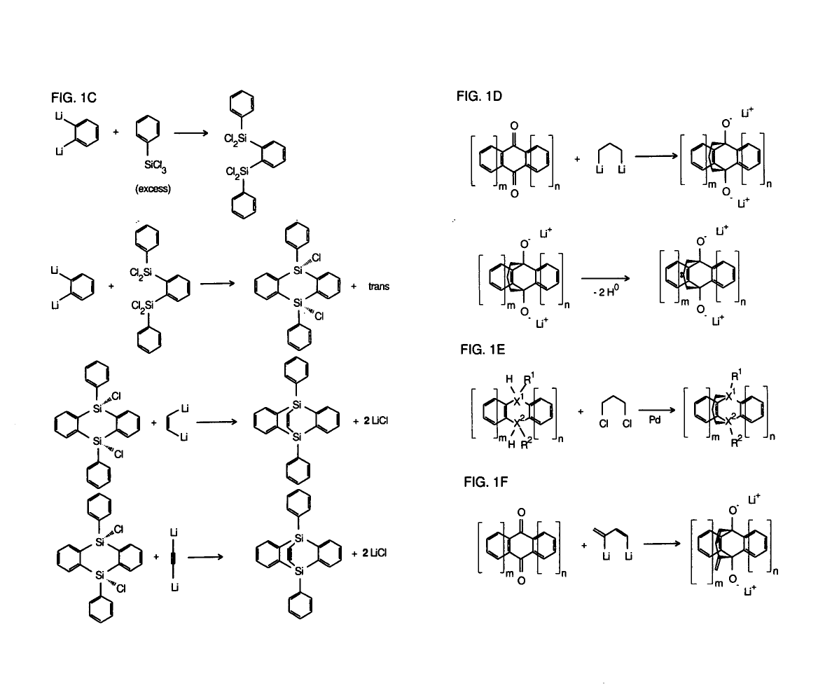

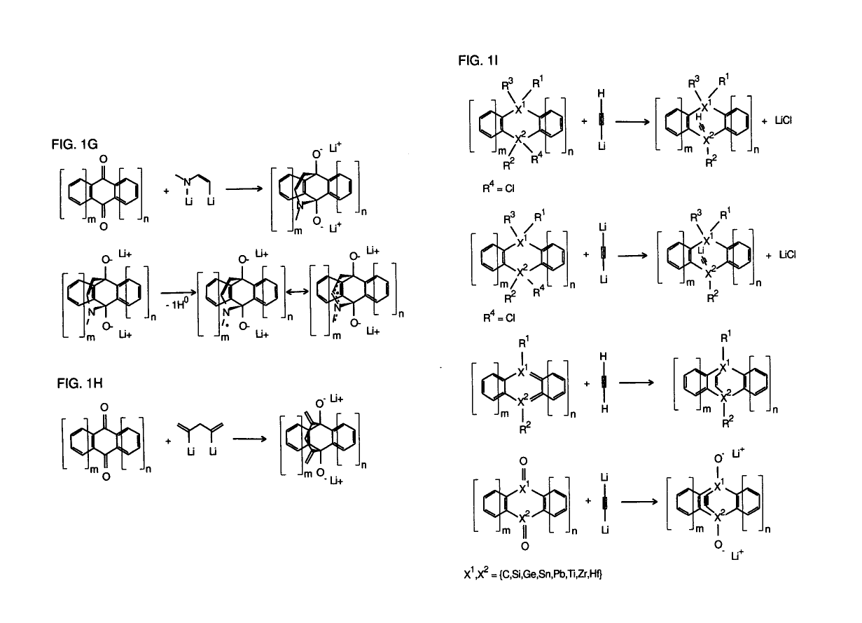

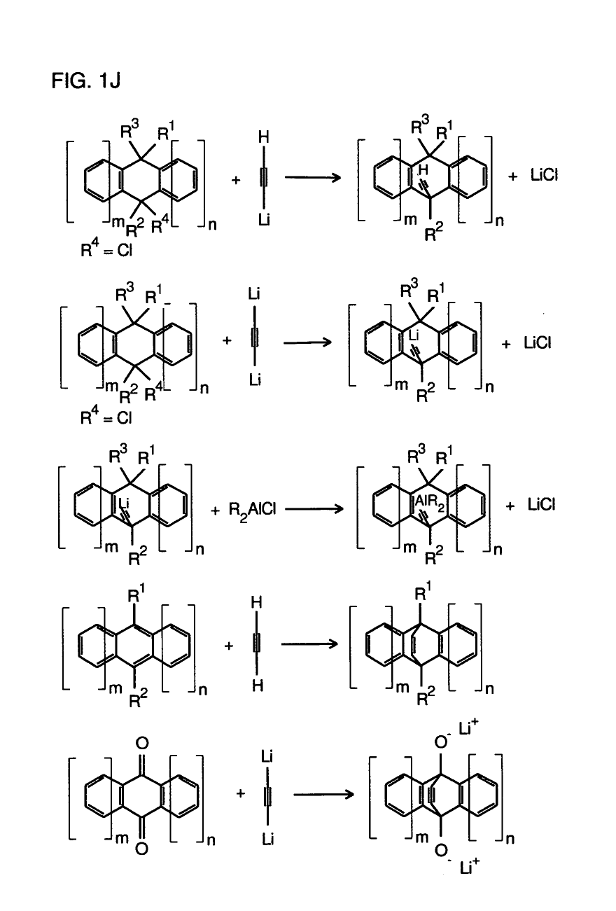

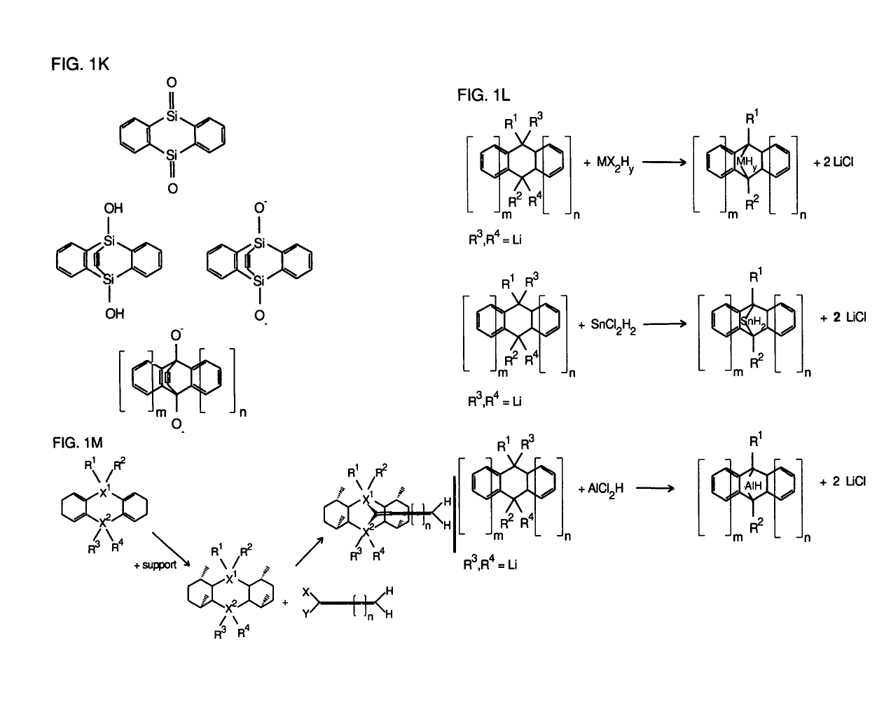

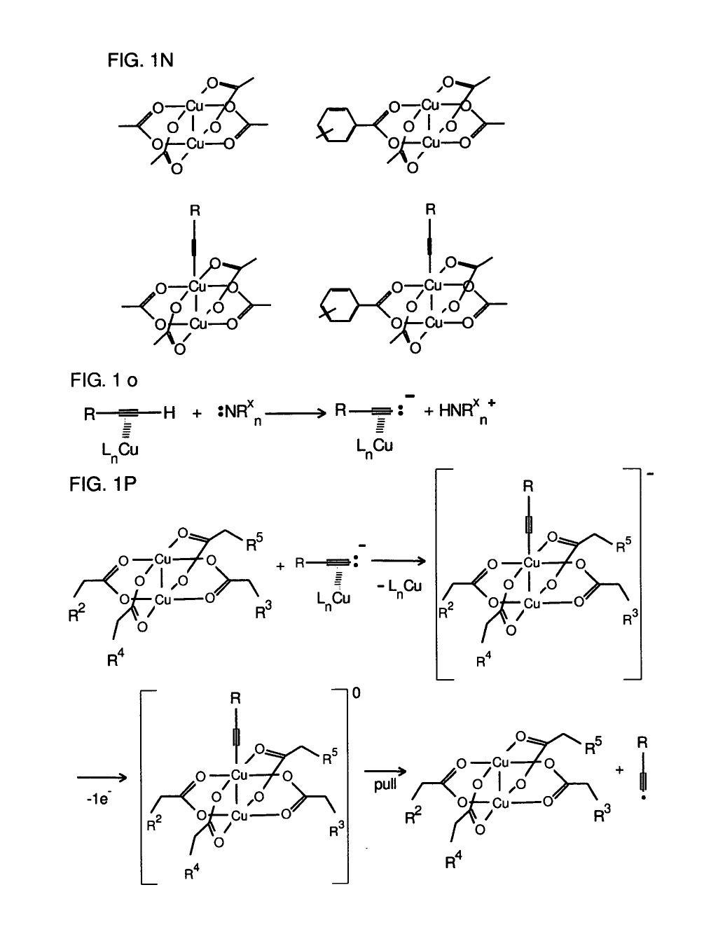

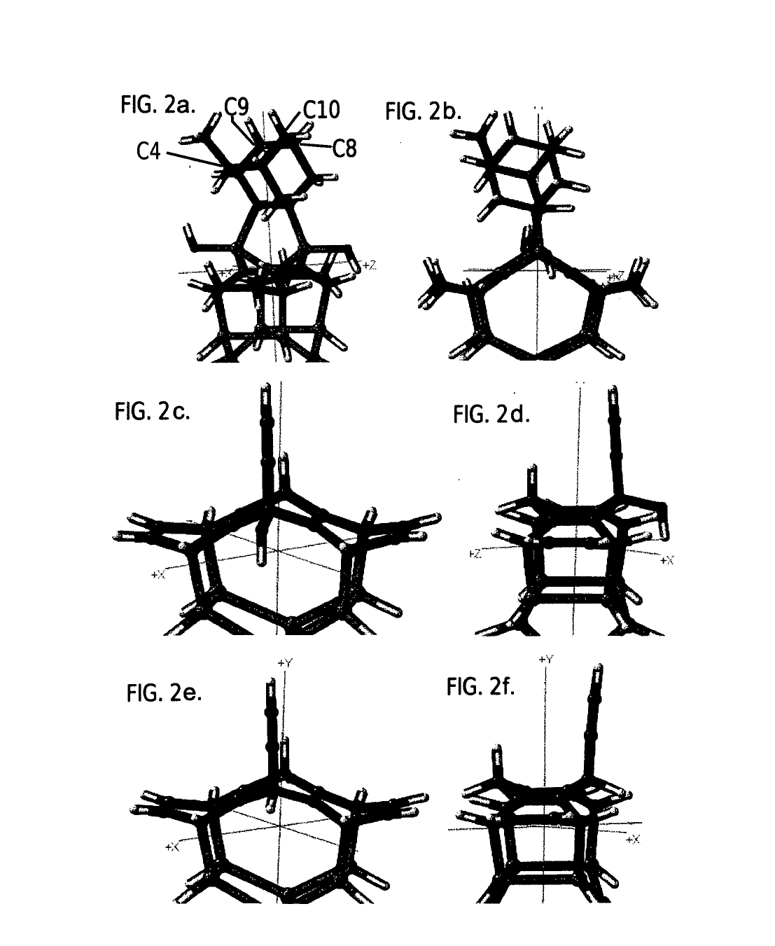

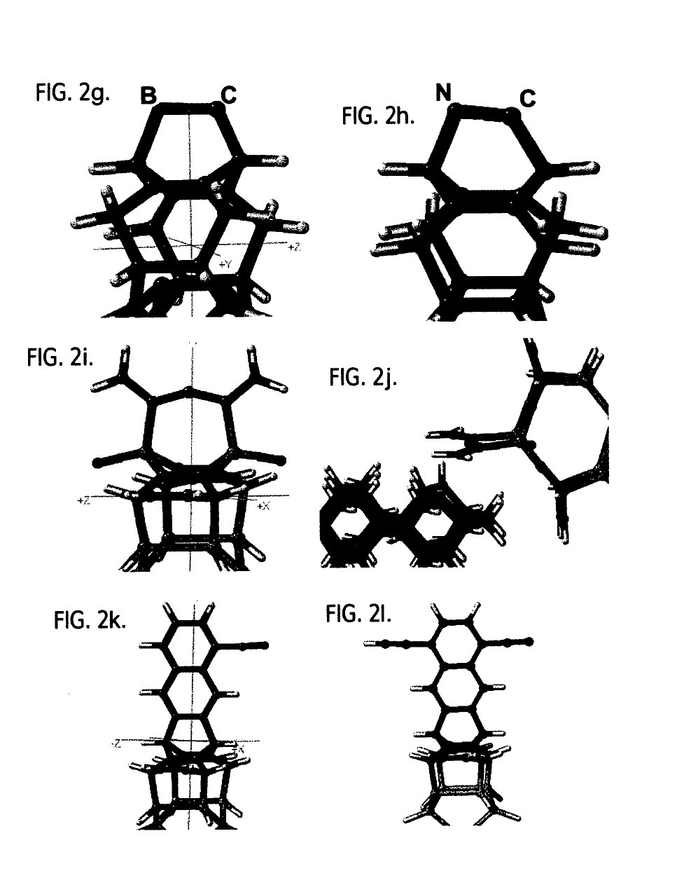

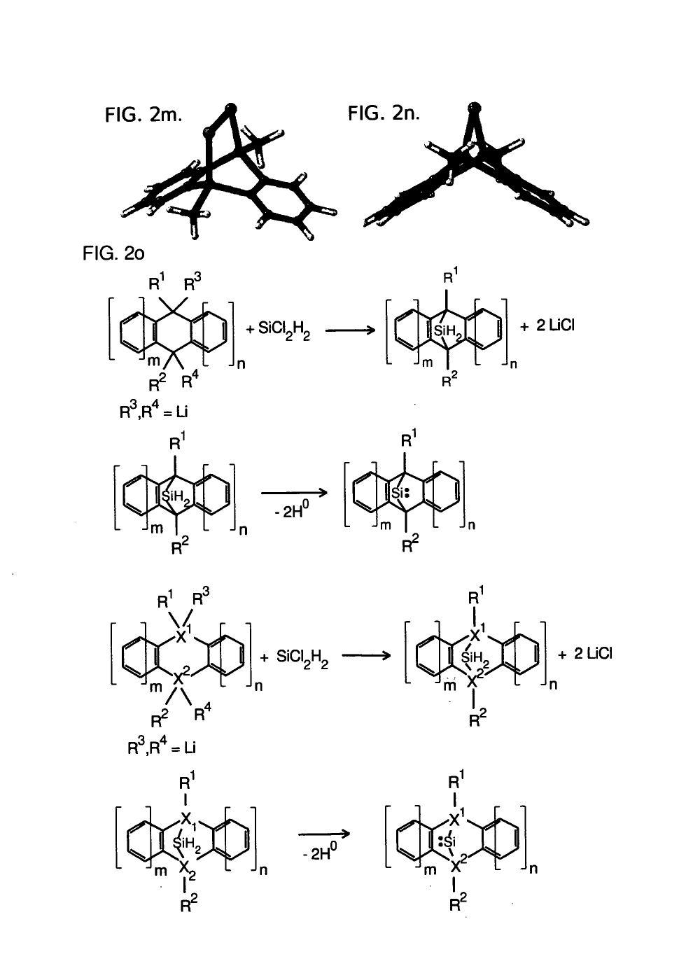

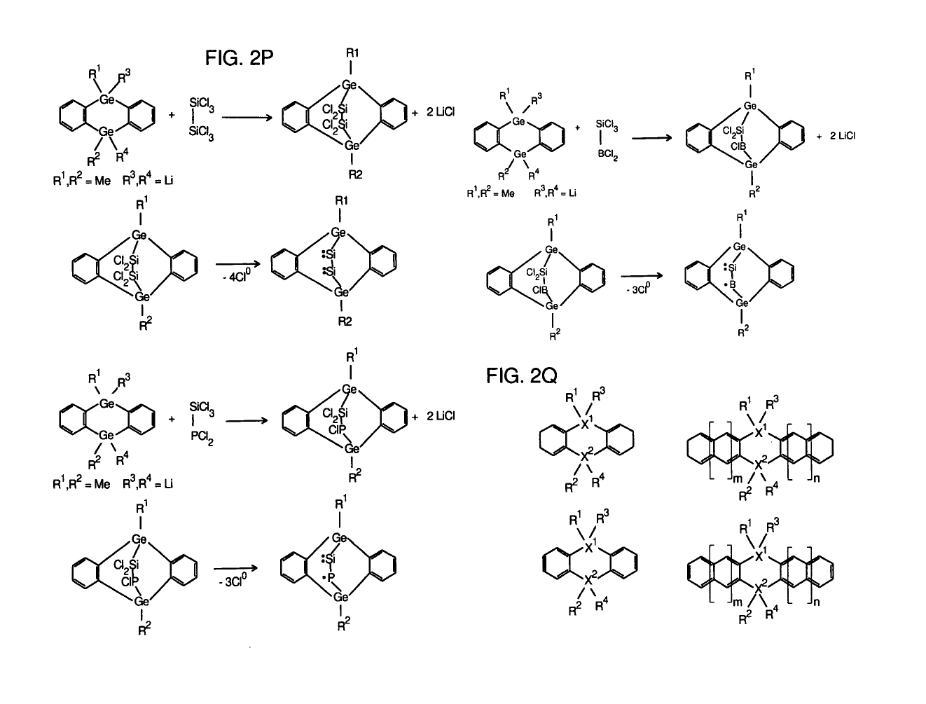

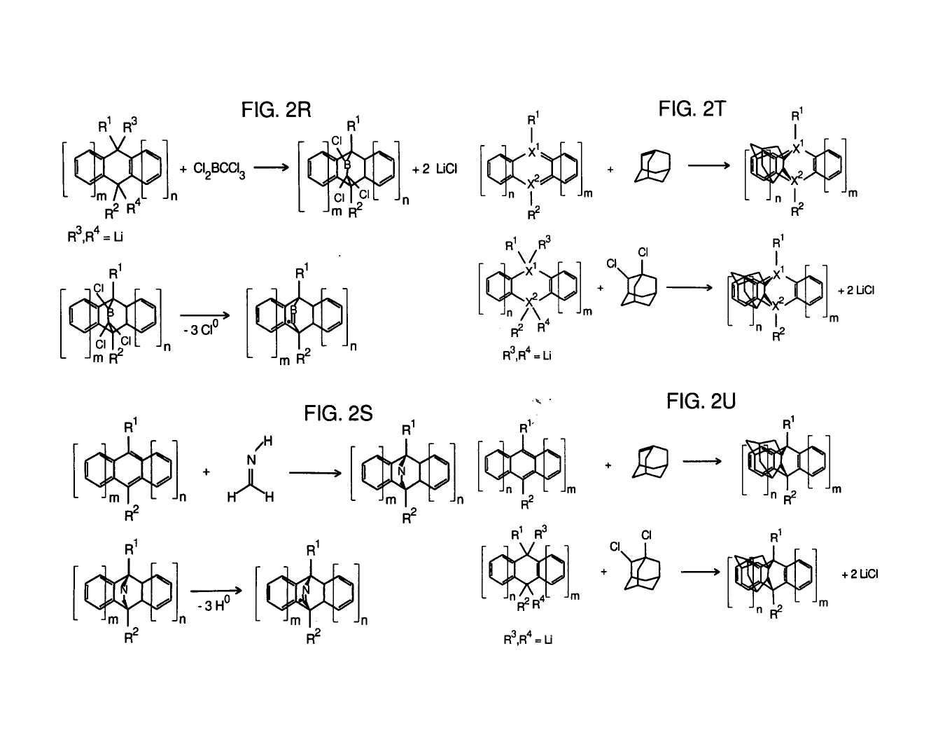

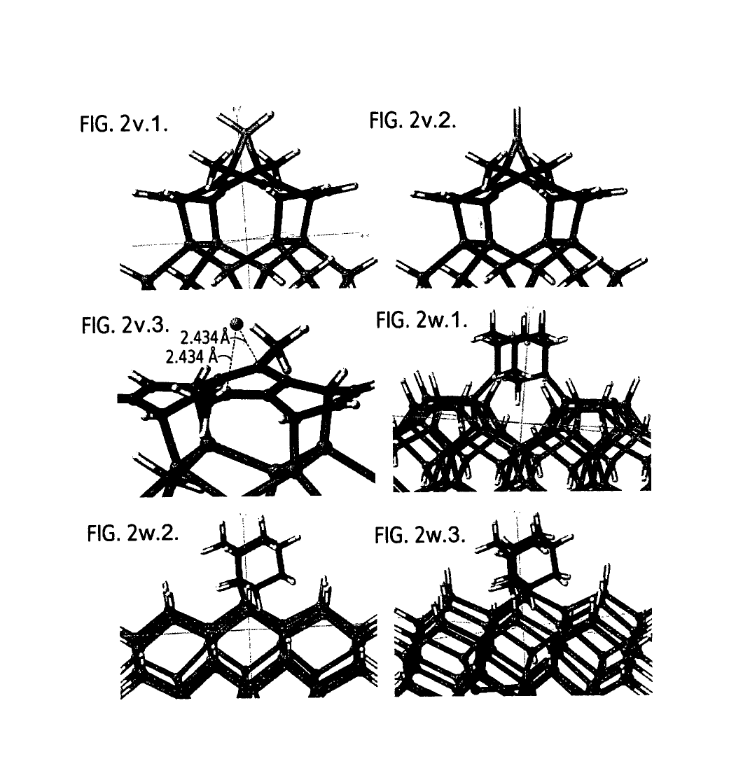

Turning to the case of hydrogen insertion tools (which may also be regarded as atomic hydrogen donation tools), tin (stannyl-) substitution of the bridgehead carbon of 2,3,5,6-tetrakis(methylidene)bicyclo[2.2.1]heptane yields a bis-diene tool precursor which may be bound to two adjacent Si dimers via [4+2]cycloadditions whereby the stannyl-substitution and the hydrogens bonded thereto are presented apically. Alkylstannylanes are frequently used as abstractable hydrogen sources in radical chemical processes, e.g. for quenching radical reactions, and various stannylanes undergo hydrogen abstraction at high characteristic rates. Also, —SnH3 groups (or most generally —XHn, where X is any atom which (1) forms stable bonds to carbon and (2) weaker bonds to hydrogen than does carbon) may be appended to the terminal ethynyl carbon of same tool molecules used for hydrogen abstraction and also for proton removal. Although this may introduce some additional positional error, it is logically equivalent in any mechanosynthetic scheme to depend mainly on hydrogen abstraction for positional accuracy and tolerate less positional accuracy from hydrogen donation tools used to “mop up” radicals left over from other mechanosynthetic steps. Other elements expected to be useful in hydrogen donor groups include aluminum, boron, titanium, zirconium, rhodium, platinum, palladium, and, to a lesser extent, oxygen, sulfur, tellurium, lead, germanium and silicon. All of these may be added as chlorides to anionic ethide groups prepared by deprotonation of ethynyl groups, or to metal acetylides derived from said ethynyl groups, as listed above for reaction with platform moieties. Similarly, the foregoing tool structure may be modified by replacing Sn with Al to yield 2,3,5,6-tetrakis(methylidene)-7-aluma-bicyclo[2.2.1]heptane, or alternatively the related anthracene, oligo- or poly-acene derived platforms similarly modified, e.g. according to the reaction disclosed herein in FIG. 1.1. or the structures shown in FIGS. 2.v.1-3. This tool is expected to have similar reactivity to diisobutylaluminum hydride, a strong agent for reductive hydrogenation. The discharged form of this tool of the structure shown in FIG. 2.v.3. may be used in a different mode to position aluminum as a reactant for positional electrodeposition whereby an aluminum atom is transferred to a workpiece, e.g. a conductive workpiece or more preferably workpiece comprising an aluminum nanostructure, held at a cathodic potential, preferably while the tool-support (which is preferably of conducting or semiconducting or superconducting material or a molecule with one of these properties) is adjusted to an oxidizing electrical potential, whereby the 6-membered dianionic platform moiety is oxidized to neutral charge to facilitate release of the aluminum atom and metallic binding thereof to a workpiece including a workpiece comprising a metal region, and the tool-support is withdrawn or retracted to break any residual weak bond to the atom deposited. Thus, the same means used in the present invention for positional mechanosynthesis using carbon (of silicon or dopants) may likewise be used for positional electromechanosynthetic deposition of a metal. Similarly, the foregoing positional electromechanosynthetic deposition method may be performed for other metals bound to the platform moieties or addition tools of the present invention, so it is expected that this method will be widely applicable to any metal which may be bound to a platform moiety or addition tool which itself is susceptible to oxidation from a form suitable as a metal ligand to a form which binds a metal less avidly or releases any metal bound to the reduced state thereof. Accordingly, many metal-ligand complexes known in the art of organometallic chemistry are candidates for use according to this method.

It should be noted that although, following work by others in the field, mechanosynthetic addition reactions of carbon dimers to C(110) diamond surfaces has been emphasized herein, other classes of target materials may be fabricated using identical or closely related methods and means, using similar or identical tools. The minimal case for graphene fabrication by C-dimer addition is the addition of a C-dimer to bridge the 4,5 positions of phenanthrene to yield a pyrene skelleton. Hydrogens are abstracted from carbons 4 and 5 using an ethynyl radical. This case also illustrates an issue which has not been addressed heretofore, the shrinkage of a “growing edge” for C2 addition to linear or flat growth zones, which is also an issue for diamond (110) surfaces: there is, at the limit of an edge or a surface, some point at which two target atoms are no longer available for addition of a carbon dimer, so that with each succeeding layer of C2 addition, the surface or edge shrinks, eventually coming to a point. Adding C2 to a single target atom yields an ethyne functionality which can pose difficulty for further addition with this chemistry, and so is less favorable as a solution to this issue. It was found that the addition tools of the present invention can bind butadiene as a reactant in both cis-oid (s-cis-1,3,-butadiene-2,3-diyl) and trans-oid (s-trans-1,3,-butadiene-1,3-diyl) configurations, which are both conformationally restricted. Where exocyclic atoms may be tolerated at the edges of graphenoid structures, the problem of growing-edge shrinkage from carbon dimer addition may be solved by addition of s-trans-1,3,-butadiene-1,3-diyl via butadiene carbons 2 and 4 to form a six-membered ring with the graphenoid workpiece. Generally this will occur by forming a bond between the carbon atom of a previously added carbon dimer proximal to the graphenoid edge and one butadienyl carbon, and a bond between a carbon atom two bonds away from the carbon dimer carbon and a second butadienyl carbon. Thus, a preferred embodiment of the present invention is a method for fabricating graphenoid nanostructures comprising the steps of adding a carbon dimer bound to a first addition tool to an aromatic hydrocarbon, removing said first addition tool from the product formed thereby, adding a reactant comprising an s-trans-1,3,-butadiene fragment bound to a second addition tool to a said product formed thereby to form a new 6-membered ring, and withdrawing said second addition tool from said new 6-membered ring. Said first and said second addition tools may be the same tool after a recharging reaction, or may be different tool molecules or nanostructures. Pursuing this progression, it was found that 1,4-pentadiene reactant fragments may similarly bind to and be added to workpieces by the tools of the present invention. 1,4-pentadiene-2,4-di-yl loaded tools are a particularly preferred embodiment of the present invention because these permit the expansion of both diamondoid and graphenoid structures (in contrast to the growing edge shrinkage described above) and so are also particularly useful for fabricating graphenoid structures comprising linear [n]acene bridges between polyfused graphene ring structures, which may include branches. (Before mechanosynthetic addition reactions of this reactant fragment with these tools, one or two hydrogens are preferably abstracted from the carbon at position 3 of this fragment, whereby a delocalized radical fragment or a carbene, respectively, are obtained.) This product configuration is of interest for applications in molecular electronic devices, permitting both branching or fan-out or fan-in of wires and seamless connection to graphenoid components, e.g. photodiodes and phototransistors, and photovoltaic devices, quantum devices including quantum interference devices, and quantum circuits or wires conducting quasiparticles.

Another preferred embodiment of the present invention similar to the immediately preceding embodiment is a method for fabricating graphenoid nanostructures useful as binding tools and addition tools according to other embodiments of the present invention, comprising the steps: providing a carbon dimer loaded binding tool; providing two of a first addition tool loaded with s-cis-1,3-butadiene-2,3-di-yl; providing an second addition tool loaded with a cis-1,2-disilyl-vinyl reactant (e.g. 9,10-(cis-1,2-disilyl-vinyl-1,2-di-yl)-9,10-disilaanthracene;) abstracting one hydrogen from each of the two reactant fragment silyl groups to yield a s-cis-1,4-disila-1,3-butadien-2,3-di-yl loaded addition tool; contacting the carbon atoms at the 1 and 4 positions of said s-cis-1,3-butadiene-2,3-di-yl reactant fragment bound by one of said first addition tool with said carbon dimer to form a first 6 membered ring; withdrawing said first addition tool; withdrawing said one of said first addition tool from said first 6 membered ring; contacting the silicon atoms of said s-cis-1,4-disila-1,3-butadien-2,3-di-yl reactant fragment bound to said second addition tool with two carbon atoms of said first 6 membered ring deriving from carbon atoms 2 and 3 of said s-cis-1,3-butadiene-2,3-di-yl reactant fragment to yield a second 6 membered ring comprising silicon atoms at positions 1 and 4 thereof and fused to said first 6 membered ring; withdrawing said second addition tool; contacting the carbon atoms at the 1 and 4 positions of said s-cis-1,3-butadiene-2,3-di-yl reactant fragment bound by another one of said first addition tool with carbon atoms at positions 2 and 3 of said second 6 membered ring to form a third 6 membered ring; withdrawing said another one of said first addition tool from said third 6 membered ring. Preferably one or more withdrawing steps of the foregoing method are preceded by a step causing oxidation-reduction reactions of addition tool for modifying the strength with which said reactant fragments are bound to addition tools. For example, after said first addition tool loaded with s-cis-1,3-butadiene-2,3-di-yl is contacted with a workpiece via the reactant fragment situated thereon (forming two bonds and thus a 6-membered ring,) a positive electrical potential is applied to said first addition tool to cause removal of one or more electrons therefrom, and then said first addition tool is withdrawn from said workpiece.

The same tools used for C-dimer addition to C(110) may also be used to fabricate graphene materials such as graphite, graphene ribbons, carbon nanotubes, nanohorns, etc. A further simple case is growth by C-dimer deposition of an open nearly-axial arm-chair single-walled carbon nanotube (formally this is a chiral nanotube.) As needed, the same ethynyl radical group based hydrogen abstraction tools used for diamondoid mechanosynthesis are used to abstract hydrogens from the edge of a provided graphene sheet or the rim of an opened zig-zag carbon nanotube. In both nanotube cases, a starting nanotube segment having an open end is provided and situated between two parallel surfaces (in a sandwich configuration) which are used to roll the nanotube as it is extended through C-dimer addition. If both surfaces are translated in opposite directions perpendicular to the tube axis, the nanotube will roll in place whereby successive target sites may be rotated to a fixed location to undergo C-dimer addition. A first case is a nearly-armchair chiral nanotube where the trans-oid carbon chains form a helix rather than approximating stacked circles in parallel planes (i.e. these are nanotubes with a helical pitch of one graphene ring per circumferential rotation.) This particular special case permits each added C-dimer to be bonded to one carbon (designated a “down carbon”) of the preceding C-dimer which was added and to one carbon (designated an “up carbon”) of a dimer added to the nanotube one rotation earlier.) Because aryl and vinylic radicals are much more reactive than the surface radicals on diamond, these reactions should be more favorable than those treated above for C(110). Similarly, zigzag-type carbon nanotubes may be synthesized by an identical reaction but via growth of an zigzag starting structure and with both each carbon of an added C-dimer each being bonded to a carbon of a different dimer added in an earlier rotation cycle at about the same rotational orientation, resembling the reaction of phenanthrene described above yielding a pyrene skelleton. Cylindrical structures such as these are facile cases because growth by addition of carbon dimers in a single orientation may proceed indefinitely without reducing the extent of the growing edge; larger cylindrical graphene structures which might not be immediately identified as “tubes” may similarly be synthesized. Again, as discussed elsewhere herein for the case of diamondoid materials, atomic substitution of graphenoid materials may be accomplished through the used of atom-substituted dimer precursors (e.g. H2CNH, H2CBH.)

Graphene type structures and materials may also be synthesized from (or extended by) s-cis-1,3-butadiene reactants (or reactants comprising this structure as a fragment thereof.) In particular, linear oligo- and poly-[n]acenes are conveniently prepared by the present embodiment of the present invention. The chemistry of the present invention may commence from a binding tool-bound acene, a binding tool-bound arene or aryl ring, a binding tool-bound benzene or phenyl ring, or even a binding tool-bound acetylene in the simplest case (as seeds.) Hydrogens, if present, are preferably abstracted from the atoms in the 2 and 3 positions of the terminal arene ring using one of the hydrogen abstraction tools disclosed herein or other such tools to increase the reactivity of these atoms; atoms at positions 1 and 4 of a tool-bound s-cis-1,3-butadiene reactant are contacted thereto to form a six-membered ring. Presumably, both tandem radical addition and Diels-Alder type pathways may compete, but yield the same products although at a different spin state unless intersystem crossing also occurs. The addition tool to which the reactant of this mechanosynthetic cycle is then withdrawn (preferably after being subjected to an electrochemical reaction to modify the strength of bonds to the reactant fragment bound thereto) to release the product of such a mechanosynthetic cycle. Note that atoms at positions 2 and 3 do not bear any hydrogen atoms bound thereto upon release from an addition tool, facilitating further addition cycles. Hydrogens are then preferably abstracted from carbons at the 1 and 4 positions of the newly formed ring to yield an added terminal benzenoid ring. Note that, as with other embodiments of the present invention, atomic substitutions and functional substitutions of either reactants (including different such substitutions at different successive mechanosynthetic addition cycles) are fully within the scope of the present embodiment of the present invention. Attention is drawn in particular to nitrogen, boron, phosphorus, silicon and germanium atomic substitutions for carbon atoms in reactants or starting precursor molecule (seed) fragments. So, for example a pyridine molecule bound to a binding tool may serve as a seed, a silicon substituted butadiene (e.g. 1-sila-1,3-butadiene, prepared in situ by hydrogen abstraction from the silane group and carbon 3 of 3-silyl-1-propene bound to an addition tool via propene carbons 2 and 3 [-2,3-di-yl]) may serve as a reactant in accordance with the present embodiment of the present invention.

A simple and useful application of graphene structures and nanostructures which may be fabricated according to the foregoing is as filtration membranes or membranes for sieving applications. A wide range of arbitrary pore shapes and sizes may be obtained, and also these membranes or sieves are electrically conductive, so may serve as both electrodes and sieves or filters in the same application where this is useful.

Discharged C-dimer addition tools may be recharged in a variety of ways. They may be contacted with gas phase acetylene or derivatives thereof, or they may be contacted with yet other C-dimer binding tools loaded with the corresponding carbon dimer compound or precursors thereof (C-dimer transfer tools.) Reaction chemistries for C-dimer binding may generally be the same as those used for initial synthesis of any given C-dimer loaded tool where C2 precursors are added therein, but other reactions or reaction mechanisms may also be used. For instance, the 9,10-di-oxo-9,10-disilaanthracene tool (which on discharge yields a disilanone) may be recharged following discharge by contacting this tool with di-lithium-acetylide [Mid93], the synthesis of which has been reported in the literature. In this case attack of the carbanions of LiCCLi on the silaketone groups yields the desired C-dimer-charged tool in dianionic form. In this particular case the lithium cations would preferably be removed, e.g. by contact with tool molecules comprising one or more carboxylates or other anionic groups depleted of counterions. Similar reactions could be performed for anthraquinone based tools. Note that the converse is usually true, most recharging reactions will be suitable as synthetic steps for initially producing charged C-timer binding tools.

A special and useful case for recharging discharged tools may use carbon dimers from calcium carbide crystals. The aluminum modified ethyne tool depicted in FIG. 1.j. may be electroreduced to a complex comprising Al(I) to cause ligands to dissociate and then contacted with a carbon atom of an ethide dianion in a calcium carbide crystal, withdrawn very slightly and electrooxidized to Al(III), whereby transfer of a carbide or ethide dianion to the tool may be accomplished. Alternatively, aluminum ligands which do not dissociate on electroreduction of the tool-borne aluminum complex may be chosen so that the carbide transfer process involves exchange of ligands with calcium ions, in which case the process if formally a tandem concerted transmetallation. The carbide loaded aluminum modified ethyne tool is then translated into proximity with a carbon dimer addition tool and the carbide dianion is contacted to the addition tool, whereby loading is facilitated. Addition tools suited to this type of loading include those comprising carbonyls or silanones, those comprising displacable halides or other leaving groups, or those which may be oxidized to cationic states with at least partial positive charge on the atoms which bind carbon dimer reactants. Alternatively, loading via a Diels-Alder mechanism (to appropriate tools comprising suitable bis-dienes or bis-double bonds) may be possible with reduction of the carbide loaded aluminum bearing ethyne tool, in which case the loading process is closely analogous to a Diels-Alder reaction of a substituted 3-alumo-cyclopropene with an additional ligand on aluminum (a ligand bound aluminum substituted for one carbon of cyclopropene wherein the double bonded carbons are both bonded to the same aluminum atom) as a dienophile.

Silicon and Germanium Fabrication:

Methods, means, devices and systems of the present invention may straightforwardly be extended to mechanosynthetic fabrication of Si structures and nanostructures via silicon dimer deposition on the Si(100)2×1 surface as shown in FIG. 8. The deposition tools shown in FIG. 8. are preferably integrated into poly[n]acene structural members, themselves most preferably fabricated according to embodiments of the present invention, although it is noted that other structural members such as diamond nanostructures or silicon nanostructures, especially those fabricated and/or assembled according to the present invention may likewise be used to position deposition tools for these embodiments of the present invention. Note that substituted dimers may be used to effect atomically precise doping or fabricate quantum structures, and also that the same methods and means are likewise applicable to the fabrication and doping of Ge structures. In addition to the structures shown in FIG. 8.

Aspects of novel methods for the fabrication of Si nanostructures are depicted in the sequence of geometries shown in FIG. ______. There, the deposition tool shown is a 9,10-digermyl substituted anthracene, which may be part of an acene or graphene structural member or may be adducted to an Si structural member, for example. The Si dimer reactant fragment thereupon has had all further substituents (e.g. hydrogens, halogens) abstracted therefrom to yield the naked dimer, which is predicted to be intermediate between the silene and silyne hybridization. Alternative deposition tools may be like that, but instead 9,10-disilyl substituted anthracene, or unsubstituted anthracene having carbon atoms at positions 9 and 10, in analogy to the biphenyl species of [Sak90+94] and [San00]. In further alternatives, silyne fragments may be held by R3Si or R3Ge or R3Sn or R3Pb groups, or by functional groups or other composition provided that these do not have such extent or bulk as to hinder approach of the silyne borne thereby to target atoms. Vinyl or unsaturated R groups offer the possibility of delocalization of radicals arising from release of the bound silyne subsequent to deposition, and so are preferred functional groups for silyne binding tools or deposition tools. Similar fabrication methods and means for fabrication of Ge and Sn nanostructures straightforwardly follow from the foregoing.

The recently discovered [Kin07] stable triple-bonded silicon dimer compounds may be modified for use as reactants with the present invention. In contrast to that work, which significantly involved a great deal of efforts for hindering silyne fragments using bulky side groups, immobilization of such reactants to feed chains or structural members prevents these species from encountering like species and reacting. Accordingly, compounds and chemistries disclosed therein may directly be used with the present invention with greater facility and fewer restrictions. Silynes may be used in the present invention for positional deposition of silicon dimers, especially to silicon workpieces and most especially to 2×1 reconstructed Si(100) surfaces thereof as for silicon dimers bound to anthracene, modified anthracene and related binding tools as disclosed elsewhere herein. Shown in FIG. 16.i-n. are the optimal geometries of the AM1 predicted ground states if silicon dimer binding tools. The first comprises two silicon nuclei linked by an ethyl bridge, while the second, a more preferable tool, comprises two silicon nuclei linked by an ethene bridge, which facilitates delocalization of radicals arising from dimer release; in both cases, any of the hydrogens shown may be replaced by bonds to structural members for positioning these tools. The essential feature of these tools is that a reactant dimer is bound to silicon atoms as in the silyne compounds disclosed by [Kin07], although the bound dimer is probably better described as a disilene diradical or a disilene tetraradical, although further investigation would be necessary to reach definitive conclusions as to the actual electronic state thereof, but it is noted that during operation, configuration interaction and intersystem crossing would likely render all of the possible states useful; for comparison, note that epitaxy of disilanes yields crystalline silicon.

[Sak90+94] and [San00] disclose masked disilenes similar to some of the disilicon binding tools disclosed herein but use these for ordinary chemical synthesis; for the present invention, the disilene moiety, as disclosed elsewhere herein, is unmasked. In those works, anionic polymerization of masked disilenes based on 1-phenyl-7,8-disilabicyclo[2.2.2]octa-2,5-diene derivatives, in which a disilene is effectively bound to a biphenyl related structure, formed linear polymers via silicon-silicon bond formation.

Methods and Means for Nanomanipulation:

In addition to the flexibility of the disclosed addition tools disclosed herein regarding useful reactants and types of products, a further novel aspect of the present invention is the use of the tools disclosed herein or of the tools disclosed in the prior art for manipulation of workpieces. This is possible in particular where a stable intermediate comprising a tool and a workpiece bridged by a carbon dimer or other fragment. As discussed elsewhere herein, such intermediates form in many cases and are controllably caused to yield addition products and discharged tools by the controlled application of energy (e.g. mechanical force, electrochemical energy [e.g. via oxidation reactions or reduction reactions,] via application of electrical potential bias, actinic radiation or thermal energy.) In addition, addition tool candidates which are not successful at addition reactions but instead retain reactants or precursors are particularly suitable for this aspect of the present invention provided they to not modify workpieces in undesired ways in the course of this use. For example, tools like the DCB6Si tool of [Man04] which show greater likelihood of retaining reactant moieties than adding reactant moieties to workpieces are useful in this aspect of the present invention. Preferably, addition tools which retain reactants upon mechanical pulling from an intermediate but add reactants during pulling in conjunction with the controllable application of an additional form of energy are used in this aspect of the present invention; this permits the same tool, tool molecule or tool nanostructure to be controllably used for at least two distinct types of operation useful in mechanosynthesis or nanofabrication. Alternatively, manipulation performed in accord with the present aspects of the present invention are conducted with addition tools such as the addition tools disclosed herein or in the prior art with concurrent carbon dimer or reactant addition. Presently, tools used in this aspect of the present invention will be termed binding tools and denoted loaded or unloaded with respect to the presence or absence of reactant fragments if these tools are also at least potentially useful as addition tools where the loading state is relevant. Because addition tools are of a nature permitting the binding of organic functionalities, it is further possible to form a radical target atom (e.g. by hydrogen abstraction) and directly form a bond between said radical target atom and an unloaded binding tool. This aspect of the present invention for manipulation of workpieces comprises the steps: one or more bonds are formed between a binding tool and a target site on a workpiece, said binding tool is then translated along a predetermined trajectory, and either said one or more bonds formed or one or more bonds between said binding tool and the reactant molecule situated thereon (if any) are caused to break. Whether or not a carbon dimer or any other reactant is added to a workpiece during the course of this manipulation process depends on the nature or the binding tool used, the presence and nature of the reactant or bridging fragment, and the conditions under which the bond-breaking step is conducted. For this aspect of the present invention, a workpiece to be manipulated is preferably secured to a support member with a binding energy or energy barrier to rotation less than the energy required to cause a translation of the bridged intermediate, or is caused to undergo a reduction in binding energy or energy barrier to rotation or translation relative to said support member.

A further aspect of the present invention concerns binding of workpieces to structural support members. The foregoing binding tools may additionally be used for this purpose. At least one, preferably two and more preferably three or more binding tools are situated on a structural support member in sufficient proximity to each other and situated in a suitable spatial configuration for binding one or more workpieces. Alternatively, a set of binding tools for securing a workpiece is distributed among two or more structural support members, whereby one or more binding tools may selectively unbind from a workpiece while one or more binding tools retains said workpiece, or whereby a workpiece may be caused to rotate along a predetermined arc trajectory by translating a first structural support member whereupon at least a first binding tool is situated relative to a second structural support member whereupon at least a second binding tool is situated, where a workpiece is bound by said first binding tool and said second binding tool. Preferably, one or more of said binding tools is chosen from among binding tools or addition tools which undergo a reduction in the energetic barrier for release upon change in redox state, i.e. a redox-responsive binding tool. In this case, the strength of the bond or bonds between said redox-responsive binding tool and a workpiece bound thereto is selectively modified in strength by changing the redox state of said redox-responsive binding tool. Such redox-responsive binding tools are preferably situated in proximity to a wire, and the strength with which said redox-responsive binding tool binds to a workpiece is conveniently adjusted by adjusting the electrical potential of said wire. Thus, it is possible to bind a workpiece to two or more sets of binding tools, cause a change in the redox-state of one or more of binding tools in a first set of binding tools, translate one set of binding tools relative to another set of binding tools with sufficient force over a sufficient distance to cause bond breakage, thus causing the selective release of a workpiece from a predetermined set of binding tools, where bonds to said first set of binding tools are in aggregate stronger than bonds to a second set of binding tools when said first set of binding tools are in a first redox state and are weaker than bonds to a second set of binding tools when said first set of binding tools are in a second redox state. In the simplest case, a workpiece is bound to a first redox-responsive binding tool and a second binding tool, a redox state of said first redox-responsive binding tool is adjusted to cause the binding of said first redox-responsive binding tool to be stronger or weaker than said second binding tool, and said first redox-responsive binding tool and said second binding tool are translated relative to eachother, whereby a workpiece is released by a predetermined binding tool and retained by a predetermined binding tool. For example, the 9,10-diphenyl-9,10-disila-anthracene based addition tools disclosed herein show a reduction in the tensile force required for dimer release upon addition of two electrons (i.e. reduction from the neutral triplet state to the dianionic quintuplet state of the addition intermediate [although spin states will vary according to workpiece dehydrogenation state],) so a workpiece bound by two loaded binding tools of this kind with tension applied will be selectively released from a binding tool which is subjected to electrochemical reduction, e.g. by applying a negative electrical potential bias to an adjacent wire, but retained by an unreduced binding tool.

The foregoing aspects of the present invention are illustrated in the fabrication and assembly of a nanodevice actuator. Aspects of the present embodiment of the invention include microscale and nanoscale actuators, a method for fabricating and assembling nanoscale actuators, a system for fabricating and assembling nanoscale actuators, and a system for fabricating and assembling nanoscale actuators for use in a system for fabricating and assembling nanoscale actuators. The nanoscale actuator of this embodiment comprises at least two structural members (e.g. slabs,) with at least one structural member facing another structural member, with conductive or semiconductive regions formed on facing surfaces, with at least three regions of conductive or semiconductive surface. In the following example, slabs will be used but it should be understood that structural members of different geometry may serve equivalently for this aspect of the present invention. Said regions of conductive or semiconductive surface conveniently comprise the hemitube structures described above, preferably fabricated according to the present invention. Two C(100) slabs are provided, bound to a structural support member via binding tools. Preferably, said structural members are smaller than 100 microns in their largest dimension, more preferably smaller than 10 microns in their largest dimension, more preferably smaller than 1 micron in their largest dimension, more preferably smaller than 1 micron in their largest dimension, more preferably still smaller than 100 nm in their largest dimension, even more preferably smaller than 25 nm in their largest dimension, and most preferably smaller than 10 nm in their largest dimension. These may be initially provided bound to a single structural support member or to two different structural support members, although the former may be more convenient. Provided C(100) slabs may be further grown by mechanosynthetic addition reactions (e.g. dimer addition and preferably also addition of larger fragments at borders to prevent growing surface shrinkage if desired, as well as attendant hydrogen abstraction and donation reactions, increasing the thickness of said slabs) and hemitubes are fabricated in desired patterns on a first slab by dimer addition with subsurface bond breakage after the desired slab thickness has been fabricated; due to the positional control available according to the present invention various desired lengths and patterns of hemitubes useful in various device structures may thereby be realized. A second slab is transferred to a second structural support member, preferably with an exposed C(100) surface parallel to the exposed C(100) surface of said first slab, and preferably with Pandey chains aligned parallel to those of or said hemitubes of said first slab; hemitubes are caused to form in desired patterns on said second slab. Said first structural support member is translated relative to said second structural support member such that said first slab faces said second slab, preferably with hemitubes on the surface of said first and said second slab aligned and offset so as to interdigitate or interleave when contacted; and further translated to contact hemitubes of said first and said second slabs. For comparatively large contact areas, contact binding forces arising from van der Waals attraction may be greater than forces required to release said first or said second slab from binding tools; for smaller contact areas, the an electrical potential bias may be applied to hemitubes on one slab relative to the electrical potential of the hemitubes of the other slab such that electromotive force attracts said first and said second slabs together with a force greater than that required to release either said first or said second slab from binding tools. Preferably, binding tools on said first structural support member or said second structural support member are caused to undergo a reduction in binding energy (e.g. by site selective oxidation caused by applying a positive electrical potential bias to a wire extending to nearby positions.) Said first structural support member is then withdrawn from said second structural support member, yielding a structure comprising said first and said second slab with contacting hemitubes interdigitating, bound by one said structural support member and an unbound said structural support member. The identity of said structural support member is predetermined according to which of said first and said second slab is less tightly bound to the respective said structural support member, which in turn is determined by the number of said binding tools which bind the respective said slab, and the aggregate strength of binding, which in turn may be controllably varied as described above. Said translating and withdrawing steps may be accomplished by communication between one or more of said structural support members and a nanoscale actuator, preferably a nanoscale actuator fabricated and assembled according to the present embodiments of the present invention. Thus, the foregoing example uses a plurality of tools distributed on at least two structural support members for mechanosynthetic addition reactions to form or expand molecular nanostructures and uses at least a subset of said plurality of tools also to manipulate one or more of said molecular nanostructures for assembly into a device. In particular, nanoscale actuators produced in this example are useful for translating structural support members, and so may be used to form systems for positional mechanosynthesis and nanomanipulation, including systems or subsystems capable of fabricating and assembling nanoscale actuators; this is a prerequisite for producing formally self-replicating systems, and is also useful for producing allo-replicating systems.

A possible shortcoming of the foregoing nanoscale actuators is that, at least during some modes of use, a current may pass between hemitubes situated on different slabs during operation. A further modification of the foregoing involves placement of a spacer between said first and said second slab. A simple example is a third slab of any non-conductive material. This reduces the current which may flow between conductive regions (e.g. hemitubes) situated on different slabs during operation. Said third slab may be bonded to either said first or said second slab, or to a different structural support which holds said third slab between said first and said second slab. Alternatively, other structural support members may confine a third slab which is not bonded to any other structure to remain between said first and said second slab.

Alternatively, raised structures for enforcing a gap between conductive or semiconductive regions (e.g. hemitubes) situated on different slabs may be fabricated by mechanosynthetic additions to regions of said first or said second slab; numerous configurations for preventing contact of actuator conductive or semiconductive regions are possible, and therefore most generally the present aspect of the invention is an actuator comprising three or more conductive or semiconductive regions and structural means for preventing contact of at least two conductive or semiconductive regions. More preferably, said actuator features structural members smaller than 100 microns in their largest dimension, more preferably smaller than 10 microns in their largest dimension, more preferably smaller than 1 micron in their largest dimension, more preferably smaller than 1 micron in their largest dimension, more preferably still smaller than 100 nm in their largest dimension, even more preferably smaller than 25 nm in their largest dimension, and most preferably smaller than 10 nm in their largest dimension.

A related structure comprising two or more conductive or semiconductive regions and structural means for preventing contact of at least two conductive or semiconductive regions and a force applying means such as a spring, a cantilever or a flexible beam may also form a useful nanoscale actuator. In this case, positional control and resolution can be realized if said force applying means applied a different force at different positions of a structural member of said actuator along the range of travel thereof; different electrical potential biases between said at least two conductive or semiconductive regions causes a counteracting force such that said structural member of said actuator settles in a position balancing the force applied by said force applying means and the force between any of said two or more conductive or semiconductive regions. Thus, actuators of the present embodiment are useful as positioner devices.

The foregoing nanoscale actuators are additionally useful as components of digital logic devices of electromechanical type. Such logic devices of electromechanical type comprise an actuator and at least two terminals which are conductors or semiconductors different from those of the actuator device itself (or a conductor and a semiconductor in combination, both different from those of the actuator device itself), one member of said actuator in communication with at least one of said terminals, situated such that actuation of said actuator may reversibly cause electrical contact of said terminals permitting current to flow therebetween or electrical potential to be conducted thereacross. (Here terminals of actuator devices themselves will be termed control terminals.) In the simplest case this can be a single-pole electromechanical relay. If in addition such a device comprises a third terminal, a dual-pole electromechanical relay may be realized with a first terminal selectively translated from contact with a second terminal and a third terminal; additionally such a device may comprise a third stable state wherein terminals are open-circuit. Logical gates such as NOT and AND may thereby by realized, and according to DeMorgan's Theorem, combinations of these are logically universal and so permit the construction of any desired logical information processing circuit, including devices or subsystems for information storage. Such logic circuits may be realized by providing at least two such electromechanical logic devices, with a terminal of a first electromechanical logic device placed in electrical communication with a (conductive or semiconductive) wire which is in electrical communication with at least one control terminal of the actuator device of a second electromechanical logic device, whereby the output of a first electromechanical logic device causes a change in state of a second electromechanical logic device (and thus permits a change in the output of a second electromechanical logic device.) A particularly significant case representing a preferred embodiment of the present invention comprises a logical circuit comprising at least two electromechanical logic devices each of which comprises an actuator, and an actuator in communication with a structural support member in communication with at least one molecular tool, said logical circuit comprising at least one output terminal in electrical communication with at least one control terminal of said actuator in communication with a structural support member. Preferably, said logical circuit comprises information storage means. Preferably, said logical circuit comprises at least one input terminal for inputting a signal to said logical circuit for controlling said logic circuit controlling said actuator in communication with a structural support member.

A further modification of the above actuators or logic devices permits the detection of analytes. At least one analyte-binding specific ligand is adducted to a structural member of an actuator such that translation of an actuation member is affected by the presence of a specifically bound analyte. A first variation implements a sandwich-type assay wherein an analyte is simultaneously bound by two ligands with a first ligand bound to an actuation member and a second ligand bound to a structural member relative to which said actuation member translates, such that translation is restrained by said simultaneous binding of said analyte by said first and said second ligand; preferably, such a device additionally comprises conductive regions which may come into contact providing for electrical communication therebetween as in the nanomechanical logic devices and nanorelays disclosed above, such that translation of said actuation member may be detected when an electrical signal is able to be conducted between said conductive regions which have come into contact. A second variation requires only one analyte-specific ligand bound to a structural member such that binding of said analyte thereto blocks translation of said actuation member by steric interaction, but in the absence of said analyte no such steric blockage occurs. This variation is particularly useful for the detection of small molecule analytes. Note that in a first alternative of this variation, said analyte-specific ligand is bound to said actuation member such that binding of said analyte thereto situates said analyte in a position which would cause collision of said analyte-specific ligand bound analyte with a structural member of this device relative to which said actuation member translates, while in a second alternative of this variation, said analyte-specific ligand is bound to a structural member of this device relative to which said actuation member translates such that binding of said analyte thereto situates said analyte in a position which would cause collision of said analyte-specific ligand bound analyte with said actuation member. Such devices are widely applicable in clinical biomedical and veterinary uses including diagnostic devices.

An additional important use for actuators is to drive pistons, which may readily be fabricated and assembled according to the present invention. A piston fitted additionally with two portals with closing members actuated respectively by a second and a third actuator (each actuator of this device being independently controlled) to serve as electrically controlled valves may, filled with an appropriate gas (preferably a noble gas) or alternatively a fluid to be pumped, serve as a two-port pump. Thus, a pump comprising a piston and two actuators wherein at least on of said piston or one of said actuators are fabricated and assembled according to the present invention represent a device according to the present invention. Accordingly, fluid handling means (e.g. fluidic devices) may be fabricated and assembled according to the present invention.

A pumping device according to the foregoing may be filled with a refrigerant to yield a refrigeration device for cooling as an embodiment of the present invention.

### Embodiments for Producing Systems Capable of Other Processing Methods:

According to the present invention, it is possible to fabricate and assemble a vast array of devices and systems; among these are systems for performing conventional chemical reactions and transformations and devices for performing other physical transformations of matter such as are known in the respective arts, for example, in chemical engineering, in petrochemical refining, in gas reforming, in feedstock processing, in metallurgy, in ceramics, in electroforming, in raw materials processing, etc. Thus, applicability of the present invention is not limited to specific materials and structure for which there positional mechanosyntheses are disclosed or come to be known, whatever the advantages of precision and efficiency may be availed through positional mechanosynthesis. The principal advantages here of producing these devices or systems according to the present invention are extreme miniaturizability, high tolerance accuracy, rapid fabrication and assembly, extremely low capital costs due to the fact that systems for fabricating and assembling systems capable of materials processing may themselves be or be produced by self- or allo-replicating systems, preferably under automated or programmable control. Thus, as a simple example, a device comprising a heating element for melting input or stored material, a feed vessel, a channel, a pump, a mold in communication with actuators, and a thermal pipe for eliminating heat, may perform the thermoplastic molding of desired articles from a provided thermoplastic material.

Similarly, and more usefully, metals with melting points lower than that of diamond may be melted and flowed into desired shapes and structures defined by walls fabricated and or assembled into border structures, said walls optionally being removed after cooling as below for the case of electroforming. Metals of appropriate composition may optionally be subjected to applied magnetic field (with either a permanent magnet or electromagnet) while still molten and through cooling to yield articles comprising permanent magnets, useful for assembly into rotary motors.

A more important example concerns electroforming, whereby borders are established by fabricating walls (e.g. diamond structures, microstructures or nanostructures, providing an cathode situated on at least one of said walls. Here, providing an electrolyte comprising a dissolved metal species. Exposed metal surfaces may be realized if at least one wall is not covalently bonded to other walls, and either in communication with an actuator for moving said at least one wall or alternatively is removed by nanomanipulation subsequent to electroforming. Note that because hydrogen or fluorine terminated diamond surfaces are inert, and because the present invention enables the fabrication of atomically flat diamond surfaces, sliding of a wall across a metal electroformed thereon is energetically and physically tennable. A subsystem or system for performing electroforming comprises at least a vessel for serving as an electrochemical cell (which may comprise walls which may be disassembled,) an electrical energy source (e.g. energy storage means) preferably providing a controllable electrical potential, a cathode (where this is not provided by a workpiece comprising another terminal connected to a cathode thereon, in which case an electroforming device must comprise a clip or terminal forming an electrical circuit with this) and an anode, a switch for applying electrical potential from said electrical energy source, preferably also a channel for transporting electrolyte, preferably also a pump for causing mass transport of electrolyte, preferably also nanomanipulation means according to the present invention for adjusting the position of a workpiece in the cell, preferably also a vessel for storing an electrolyte, and preferably also a resistor or variable resistor or rheostat for adjusting the cell potential. Note that subsystems, systems or devices according to the present invention may compete their own production by electroforming metal structures or wires according to the present aspect of the present invention by incorporating a subsystem according to the present aspect of the present invention, to which an electrolyte comprising a dissolved metal is provided.

### Embodiments for the Processing of Matter:

Both embodiments directed towards separation, treatment, sequestration or conversion of pollutants as well as embodiments directed at chemical or materials processing may be realized by devices and systems fabricated and assembled according to the present invention designed to perform such desired physical transformations of a starting material, preferably including concentrating said starting material from an input stream, or at least excluding components of an input stream from one or more processing chambers or vessels, where said physical transformation are adapted from or even identical to physical processes established in the respective arts. Embodiments for the processing of matter according to the present invention may be implemented in systems across a wide range of size scales, from microscopic to arbitrarily large systems. Also, larger systems may superficially resemble existing chemical plants in layout or overall design, or alternatively may comprise cellular subsystems including even microscopic subsystem cells comprising nanoscale components for processing of matter. Note, however, that unlike a chemical plant of conventional design and construction, systems according to the present invention may comprise or may be operatively coupled to systems for fabricating and assembling such macroscale systems, preferably under the programmable and automated control of information processing subsystems comprised therein, whereas it remains the case that chemical plants require substantial human involvement in their construction, as well as significant capital expenditures. Since such systems may approach or even exceed kilometer scales, it is not unreasonable to term this class of technological applications “terananotechnology”.

According to the present aspects of the present invention, input streams may comprise one or more raw materials and/or one or more pollutants and said input streams may be processed in a variety of ways. Raw materials and pollutants which may be processed according to the present aspect of the invention include: carbon dioxide, ozone, ultrafine particulates, nanoparticulates (including pollutant nanoparticulates), one or more chemical wastes, one or more metals, one or more ores, one or more minerals, and may also be materials comprising carbon atoms, or materials comprising silicon atoms, including silicates. Preferably, subsystems or systems according for the present invention comprise separation means for separating desired products or intermediates from unprocessed inputs and any slag or byproduct, and outflows or holding vessels or chambers to which any slag or byproduct may be transferred. Physical transformations useful for processing according to the present aspect of the invention include: separation, filtration, heating, cooling, evaporation, degassing, vaporizing, melting a solid or glass or metal, solidifying a liquid, subliming a gas, crystallization, chemical reaction, an arc reaction, one or more catalyzed chemical reactions, one or more chemical reactions catalyzed by a metal or metal particle, a metal oxide or metal oxide particle, or complex comprising a metal, one or more photoassisted chemical or electrochemical or electrocatalyzed reaction, one or more electrochemical reaction, one or more caused by actinic radiation.

Note also that systems according to the present aspect of the present invention, in highly miniaturized form, should be highly desirable for space applications, whereby a subkilogram payload is likely to suffice to enable the self- or allo-replicative construction of lunar, Martian, asteroidal, Jovian or other extraterrestrially based production facilities for converting raw materials to useful forms, converting energy and producing needed equipment, and even, ultimately, terraforming applications, should considered analysis deem this wise.

The present invention may also both address and take advantage of what is regarded as a problem in the field of gas reforming and related areas. Frequently, catalysts or electrodes are degraded in their activity by the formation of carbon deposits, obstructing access of reactants to catalytic sites or conductive surfaces. Sometimes operations like pulse waveforms for cleaning or stripping electrodes may mitigate this condition, but deposition remains an issue which limits many applications of electroreduction, electrooxidation, electrocatalysis or catalysis. Two cases present themselves: a first case where the deposited material degrades an expensive or rare material and a second where it is the apparatus or system capacity to accommodate electrode or catalyst are limits the simple increase of the respective quantity. Because the present invention permits the fabrication of atomically precise structures and also because devices and structural members operative at the relevant scale are likewise enabled, this class of problems is readily addressed for locally flat catalysts or electrodes according by fabricating supports and preferably also the active material according to the present invention to preferably yield an atomically flat surface, integrating actuators and structural members into or onto electrode or catalyst supports, designed such that a beam with an atomically flat surface slides across the catalyst or electrode such that deposits are scraped away by said beam. Since the beam and the active material support may be a hard material, preferably diamondoid or modified diamond material according to the present invention, and since actuators may be scaled as necessary to apply significant forces, and also because sub-nanometer tolerances are feasible, self-scraping electrode or catalyst supports represent an embodiment of the present invention for eliminating deposits on an active material. The principal limitations of the applicability of this approach are limitation posed by mechanical properties of the active material and the adhesion thereof to said active material support compared to strength of adhesion of deposits to active materials. At least the strength of adhesion to said active material support may be improved through fabrication according to the present invention compared to conventional methods, for instance, by fabricating optimal patterns of hydrogenation on a support surface (or more specifically, abstracting a precise pattern of hydrogens from a hydrogenated surface) for registry with an active material; since a deposit is unlikely to deposit in an optimized lattice, generally this advantage should be available in interfacial design. Turning now to the objective of carbon capture or CO₂ conversion, formation of carbon deposits on active materials, especially inexpensive materials such as aluminum, represents a useful method for carbon capture, especially if deposits can be recovered and preferably also active materials restored to activity.

Systems or subsystems implementing the present aspects of the present invention may comprise pumps, heating means, cooling means, electrical arcs, electrochemical cells, fuel cells, energy conversion means, lasers for producing actinic radiation, catalytic materials, vacuum pumps, reactor tubes, reactor volumes, and/or reactor beds.

### Embodiments for Reducing Pollutants and Associated or Related Embodiments for Processing Raw Materials:

Systems capable of self- or allo-replication or self growth comprising energy production means, particularly photovoltaic devices for solar energy conversion, electrochemical means for converting chemical compounds, and programmable information processing and storage means in communication with actuators, positioners and sensors comprised by these systems and means for effecting mass transport (e.g. pumps driven by actuators or electrophoresis means comprising electrodes, as well as porous membranes for filtration or separation of different species according to size and interaction with different surfaces or surface compositions) may be fabricated and assembled according to the foregoing methods of the present invention, and may, if designed and programmed to do so, fabricate and assemble similar systems; when these systems are designed and operated to perform electroreduction of carbon dioxide or carbonate (and possibly also water) to other chemical compounds including useful feedstocks or chemical precursors (e.g. syngas,) driven by energy converted by photovoltaic devices comprised by these systems. This class of embodiments of the present invention may be realized by several combinations of alternatives disclosed herein (but may also comprise devices, methods, means and compositions of existing technology,) and represents a significant answer to the challenges posed by the accumulation of carbon dioxide and other greenhouse gases in the Earth's atmosphere. Preferably, such systems are provided with a store of precursors not obtainable from the external environment in which the operate, and comprise vessel structures or compartments for storing precursor compounds, as well as channels in operative communication with pumping means whereby mass transport to molecular tools is enabled. Among pollutants which may be transformed are carbon dioxide, ozone, metals, and a wide variety of chemical wastes.

In a preferred embodiment of the foregoing aspect of the present invention, systems comprise a filtration membrane for excluding environmental debris and unwanted matter (e.g. a diamondoid membrane comprising pores) or multiple stages of membranes with different pore sizes, an adsorption means for adsorbing CO₂ or carbonate (e.g. CaO or MgO surfaces including nanophases thereof, actuation means for translating adsorbing material from and adsorption chamber to an electrochemical cell, means for desorbing CO₂ therefrom (e.g. heating means such as a resistive wire [e.g. N-doped polyacenes fabricated according to the present invention or acenes packed non-optimally for electrical mobility] in thermal communication with said adsorbing material once this has been translated to said electrochemical cell,) an electrochemical cell comprising an electrode to which is controllably applied a potential for electroreducing CO₂ or carbonate, are combined to enable the conversion of CO₂ to useful feedstocks or materials. Alternatively or additionally, photoassisted electroreduction means may be employed for direct conversion of CO2, e.g. to CO+H₂. Various means for accomplishing this are known in the arts including the use of monovalent cobalt complexes or the use of various electrode materials such as InP as electrodes under irradiation. [Hal80] also discloses methods and means which may be implemented for the present purpose according to the present invention in combination with the other elements of the present embodiments of the present invention to yield systems implementing an instance of the present invention. For instance, B-doped p-type Si fabricated according to the present invention may be used as a cathode in a subsystem comprising a system disclosed by [Hal80]. As a further example, graphenoid materials and structures fabricated according to the present invention may serve as n-type anode material. Preferably, in addition to the energy input via illumination of the electroreduction at the cathodic interface according to [Hal80], electrical energy supplied to the reduction reaction is derived from a photovoltaic subsystem of a system of the present embodiment of the present invention, preferably from solar radiation.

Input streams may be atmospheric air, flue gases from combustion chambers (which is preferable due to reduced molecular oxygen content), or may be river, lake or ocean water.

For instance, seawater contains dissolved carbonate at a higher concentration than the concentration of carbon dioxide in the atmosphere. Seawater also contains significant quantities of dissolved metals such as sodium, magnesium and calcium which are useful for CO₂ processing. Application in marine environments is also particularly desirable since this eliminates the need to obtain land for facilities. Systems adapted for use in marine environment preferably comprise structural members enveloping evacuated spaces for forming flotation members. Preferably, such systems additionally comprise fins for stabilization or steering, and more preferably also comprise propellers driven by motors e.g. for maintaining a geographical position. In a further alternative, carbon dioxide or carbonate may be reduced to carbon at graphenoid electrodes. This type of reaction is facilitated by metals including alkali metals such as potassium (m.p. 64° C.) or lithium or sodium. In this category of implementations, electrodes may be continually supplied and translated through said electrochemical cell with the product carbon deposit situated on used regions of electrodes translated to storage compartments wherein said deposit is scraped from said electrode whereby said deposit is placed in said storage compartment and whereby said electrode is cleaned or regenerated for subsequent reuse. Thus a preferred case comprises looped electrodes. A conjugate cathode comprising a graphenoid terminal and a molten metal represents a further embodiment of the present aspect of the present invention; where said metal is potassium, copper, nickel or iron, CO₂ is expected to be reduced to C, which may preferentially bind to the graphenoid member in analogy to mechanisms for carbon nanotube growth, although in this phase, dendritic structures or amorphous products would be expected. Conversion of carbon dioxide to carbon (graphene or amorphous carbon) also represents a form of energy storage, and carbon thus obtained may be useful as a fuel for combustion, or for reforming into feedstocks, or as an oxidant at higher temperatures.

In particular, as is known in the fields of gas reforming or of electrochemistry, CO₂ may be reduced to methane. Methane may then be converted to acetylene, for example, by reaction promoted by energy supplied by arc torch, as taught by J. E. Anderson in U.S. Pat. No. 3,051,639 (herein termed arc reaction). An arc torch according to [Ard62] and references therein may be fabricated and assembled according to the methods of the present invention, and provided with a methane input stream (which herein may be the output of an electrochemical cell wherein methane was obtained by reduction of CO₂,) and an H₂ input stream. Preferably, for the present purpose, the required H₂ input stream is obtained by electroreduction from a hydrogen electrode (e.g. via electrolysis of water) the energy was obtained from a phototovoltaic cell, or by photoassisted catalytic reduction of water. Preferably, a switch activating said arc is controlled by a relay or switch device of the present invention. Preferably, activation of said arc is controlled by a programmable digital circuit or information processing device or computer, which even more preferably comprises components of the present invention, even more preferably fabricated or assembled according to methods of the present invention. Photovoltaic cells, preferably fabricated according to an embodiment of the present invention and assembled into a system according to the present embodiment of the present invention are preferably provided for energy conversion. Thus a system for transforming carbon dioxide to methane, reducing solid carbon to acetylene and performing positional mechanosynthetic fabrication therewith represents an important preferred embodiment of the present invention. Thus a system according to the present embodiment comprises an electrochemical cell for reducing CO₂ to methane and an arc torch reactor according to [And62] and preferably also a photovoltaic cell. Alternatively, photoassisted electroreduction may be used to obtain H₂ under solar irradiation, e.g. using solluble cobalt complexes as taught by [Leh82]. Acetylene is a useful feedstock for mechanosynthesis according to the present invention. So a further preferred embodiment comprises conversion of CO₂ to acetylene according to the foregoing, loading a molecule of acetylene onto an addition tool of the present invention, and adding carbon atoms deriving from said molecule of acetylene to a workpiece. Most preferably, said workpiece is a component for a system according to the present embodiment of the present invention for converting CO₂ to acetylene. Note that other methods for reforming known in the arts may similarly be applied according to corresponding embodiments of the present invention (as illustrated by the range of applicability of the [And62] to forming products other than acetylene, which therefor enables a similar range of applicability for corresponding embodiments of the present invention.) Note that although the energetic efficiency of these methods may not be optimal, since (1) energy costs may be minimized in this embodiment of the present invention, and (2) since energy is preferably derived from solar irradiation, no net heat is added to the Earth which would not have been added at the time solar energy was converted to electrical energy, and also given the proximity of photovoltaic component to arc reactors, at least geographically speaking, use of the present invention, at whatever energy efficiency, causes neither time-shifting nor space-shifting of heat and thus poses no significant risk of thermal pollution.

[Hag93] discloses methods and means electrolysis of CO₂ for O₂ production, as well as energy storage, and [Sri95] report related work directed towards similar objectives including for space applications (e.g. Mars expeditions). The electrochemical cells of [Hag93] are operated in the range of 800-900° C., at which temperature diamond and silicon remain stable, electrochemical cells according to [Hag93] may comprise structural materials of such compositions fabricated and assembled according to aspects of the present invention and incorporated into systems according to the present invention, e.g. in place of or in addition to arc torch based reactors according to [And62] in the systems disclosed above.

Another useful conversion of CO₂ is to carbon nanotubes. Although the present invention discloses far more refined methods for their production, it may be advantageous to use CO₂ as a raw material, either indirectly as is the net result when CO is used as a feed gas (and is obtained via a reverse water gas shift reaction from CO₂) or, interestingly, directly as disclosed by [Nas05]. [Nas05] studied the effect of CO₂ and H₂O on carbon nanotube growth catalyzed by Fe particles generated hot-wire generator method or alternatively formed in situ by thermal decomposition of ferrocene. These workers found that nanotubes would grow in the absence of CO due to disproportionation of CO₂ in the presence of Fe and H₂O under the reaction conditions used, in particular at temperatures between 894° and 908° C. Since materials which may be fabricated according to the present invention are stable in this temperature range, such reactors may be fabricated and/or assembled according to the present invention, especially from silicon, which preferably is then permitted to form an oxide layer on surfaces to serve as reactor walls. Thus, as with the electrolysis cells of [Hag93], reactors such as those used by [Nas05] may form subsystems of systems for converting CO₂ to useful materials as part of systems fabricated by the self- or allo-replicating systems of the present invention, and such systems comprising subsystems for converting CO₂ to carbon nanotubes thus represent an embodiment of this aspect of the present invention.

Note that carbon nanotubes, prepared by bulk methods from CO₂, CO, methane, formaldehyde, methanol, acetylene, ethylene, ethane, ethanol, acetic acid, oxalic acid or other feedstocks by methods presently known in the respective arts or subsequently developed corresponding methods and means, or nanotubes or related materials of different composition, may be used as materials by systems of the present invention to form photovoltaic and other devices such as those disclosed by [Afz04], [Afz06], as well as other known devices comprising nanotubes. Preferably, such nanotubes are manipulated by a binding tool or manipulation tool of the present invention for assembly into structures implementing such devices, most preferably by subsystems of systems comprising other subsystems for the transformation of matter. In examples of the foregoing, CO₂ is either reformed to CO and used as a feedstock for carbon nanotube growth, or more preferably CO₂ is directly used as a feed gas according to [Nas05] in a suitable reactor for carbon nanotube growth. More preferably, carbon nanotubes obtained according to the foregoing are bonded by manipulation tools of the present invention and assembled with other required materials into electronic devices or photoelectronic devices. More preferably still, nanotubes are assembled according to the foregoing into photovoltaic devices (e.g according to [Afz04] and [Afz06] whereby pollutant CO₂ is transformed into an instrument of its own conversion into useful devices.

In some of the foregoing embodiments, it is useful to provide CO₂ to a reactor in a relatively concentrated form. Similarly, physical methods for extraction of CO₂ from an input stream are useful in embodiments of the present invention. [Fan06] teaches a method for adsorption and release of CO2 from calcium oxide, and reviews longstanding art for this class of processes. Similar adsorption may use on MgO and other materials. Since both calcium and especially magnesium are abundant in seawater, CaO or MgO sorption present alternative methods and means for separating CO₂ for conversion according to the present invention, including from input streams of atmospheric air, adsorbed as CaCO₃ or MgCO₃. Most simply, water may be evaporated from seawater to obtain salts used as sorbent, although sodium chloride is less efficient and may interfere. Thus, in a preferred embodiment of this aspect of the invention, a subsystem for obtaining calcium and/or magnesium from natural water comprising filtration means, heating means, refrigeration means and a vessel for concentrating and crystallizing CaCO₃ or MgCO₃ which may then be calcined to the desired materials. Alternatively, magnesium is first precipitated from seawater with hydroxide (e.g. sodium hydroxide, above pH 8.0 and more preferably above pH 10.0, followed by filtration or at least centrifugation, yielding a mixture of MgO and Mg(OH)₂.) Input water (preferably seawater) is first filtered to remove living matter and debris, using stages of filtration membranes having successively smaller pores and flowed into a concentration vessel where evaporation is caused to occur by heating with a heating element; vapor evolved is collected as in distillation and stored. The liquid resulting from partial evaporation is then cooled, e.g. using refrigeration means, preferably to just above 0° C. to precipitate salts. Preferably, seeds of desired materials (e.g. CaCO₃ or MgCO₃) are provided in said concentration vessel to promote crystallization of desired materials thereon, and the liquid is caused to flow out of said concentration vessel leaving precipitated or crystallized material behind, combined with collected distilled water to restore initial volume and concentrations of other materials, and discharged. Carbonates thus obtained are then calcined and evolved CO₂ is collected and transferred for conversion, and the desired sorbents are obtained. Purity of sorbents is probably not critical in this application. Note that for systems according to the present invention implemented on the macroscale, a fraction of evaporated water recondensed and stored may be further redistilled and also purified and used as a drinking water or agricultural irrigation; in these cases, contents are preferably further purified, and analyzed for quality, e.g. using analyte detectors according to other aspects of the present invention. Since sorbents may be recycled, a calcium atom used here may enable the sequestration of more CO₂ than if it merely binds one CO₃ anion and forms sediment, as in nature.

In these and other applications, formation and containment of thermal gradients is often important, and it may also be desirable to channel thermal emissions or exhausts of any waste heat in particular directions. Although diamond is an excellent thermal conductor, systems with largely diamond structural material may maintain thermal gradients if walls comprising evacuated volumes effectively blanket volumes where particular temperatures are desired to be maintained. Accordingly, such systems preferably comprise walls or layers featuring voids which are evacuated, whereby thermally conductive cross-sectional area may be dramatically reduced, accomplished, for example, by expanding piston structures incorporated therein. Since silicon materials may be fabricated according to the present invention, silicon beams may be fabricated to suspend multiple concentric diamond enveloped vacuum insulating members. Similarly, diamond structures may serve as heat-pipes or structural members for heat pipes for conducting heat energy including waste heat to desired locations within or outside of systems according to the present invention.

MgO obtained as a precipitate according to the foregoing may be melted in an electrical arc furnace or more preferably a submerged arc furnace to yield the crystalline material. Most preferably, this is conducted with a preformed crystalline MgO seed held at a predetermined orientation to orient the crystallization of molten MgO for facilitating cutting ore cleavage and also for yielding a product with predetermined crystalline orientation. Cutting may, for example, be done with a diamond saw fabricated according to other aspects of the present invention, operated by actuators according to other aspects of the present invention. MgO bodies may thus be produced as sheets or bricks, and may further be used as optical materials with transmission from infrared to ultraviolet, especially if melting and crystallization is conducted under vacuum to minimize the formation of bubbles. Some uses are relatively indifferent to modest bubble formation, such as lenses or Fresnel lenses for concentrating solar radiation for heating heat engines or for distilling seawater or wastewater or for providing heat to a solar furnace. In these uses, any surfaces exposed to water or hydrogen are preferably coated with a protective layer, e.g. a diamond layer fabricated according to the present invention or alternatively a transparent polymer layer, e.g. polymethyl-methacrylate or polycyclohexyl-methacrylate or transparent polyurethane, or the like. Similarly, as refractory material, MgO is particularly useful as a lining and a structural material for high temperature furnaces for various materials processing applications such as smelting, melting or roasting, and so the foregoing operations and systems or subsystems for performing same are useful in systems for the processing of matter utilizing such operations. I believe the intake, purification and use of MgO in self-replicating systems for processing matter is novel to the present invention. Alternatively, a fresnel lens, fabricated from polymethylmethacrylate by art methods or of diamond composition according to the fabrication methods of the present invention, may be used as means for concentrating solar radiation on an absorber in thermal communication with a heat engine (preferably also comprising a heliostat for aiming concentrating means). Still alternatively, reflectors may be used; these may be fabricated by bulk methods of known art or alternatively by positional electrodeposition according to the present invention, and preferably further comprise a transparent protective layer. A heat engine powered by concentrated solar radiation concentrated by the foregoing solar concentrating means or other concentrating means, may favorably be of graphene, graphite, reinforced carbon carbon or extruded carbon composition and may utilize argon as a working fluid, (e.g. obtained from air or during the degasing intake of seawater,) and also surrounded with an argon atmosphere in an enclosure. Note that graphene fabricated according to the present invention yields a predetermined crystal orientation, and so a piston and ring or piston and cylinder or piston-ring and cylinder or piston and chamber maybe constructed having graphene surfaces articulating with other than 60 degree registry, whereby superlubricity without added lubricant is effected. Since the foregoing materials have excellent heat stability, and are only exposed to inert working fluids and atmospheres, the foregoing engine may be operated at high temperature and accordingly with high efficiency. Preferably, said enclosure is similarly of graphene composition, but protected from atmospheric oxygen by an additional coating such as silicon and SiO₂; since the hottest portions of this system are those receiving direct concentrated solar illumination, this stress on the enclosure is not maximized during ordinary operation, especially if a heliostat aims the entire assembly or at least the concentrating means therefor. Preferably heat engines comprise two or more of the foregoing piston-chamber assemblies in mutual thermal communication via a regenerator or a heat exchanger, more preferably a counterflow heat exchanger, most preferably of graphene or extruded carbon composition, for recovering heat after a work stroke and transferring thermal energy thereof for the heating of working fluid during the first thermodynamic branch of the thermodynamic cycle of a second piston-chamber. Alternatively a regenerator may be used with a single piston-chamber. Regenerators may favorably comprise thermal mass of MgO composition. Note that heat engines of this type utilizing solar thermal energy may yield efficiencies of conversion of heat to work (or, deriving an electrical generator, heat to electricity) competitive with or exceeding those presently realized with conventional solar-thermal systems or photovoltaic devices.

Thus, according to the foregoing, a system for capturing solar energy and conversion thereof to mechanical work, distillation of water, purification therefrom of useful materials and also capture of CO₂ and conversion thereof to useful materials or devices may be realized.

Alternatively or additionally, such as system may comprise energy collection and conversion means selected from: a heat engine heated by means for concentrating solar radiation driving an electrical generator; a pneumatic system utilizing gas expansion caused by solar radiation concentrated by concentrating means; wind energy collection means; wind energy collection means driving an electrical generator.

Systems such as the foregoing may further comprise flotation means (e.g. fabricated from graphene or extruded carbon, but also possibly of other compositions) enabling such systems to be deployed in marine or aquatic environments. In particular, this combination permits operations to be conducted without the cost of obtaining land. Such systems may straightforwardly be employed to produce further flotation means from materials obtained during their operations and structural members supported by same, whereby working areas may be supported, and also space for human habitation may be produced.

Other pollutants including water pollutants and gaseous pollutants may be treated by electrochemical reactions, as has been widely studied and employed, e.g. as noted in [Iba04]. Accordingly, systems according to the present embodiment of the present invention may be adapted to treat these pollutants as well, providing the advantages of inexpensive energy collection and self- or allo-reproductive capital equipment production.

CO₂ frequently occurs dissolved in seawater in millimolar concentrations (90 ppm, v. 7 ppm for O₂. and 12.5 ppm for N₂.) Additionally, if CO₂ is removed, equilibrium with CO₃⁻² species releases more CO₂. Thus, for removal of CO₂ from the atmosphere, the ocean itself may be exploited as a first purification stage for CO₂ in situations where further processing is facilitated by lower O₂ or N₂ partial pressures. Whether this is more efficient than direct capture from air will depend on specifics of implementation and also what other functions or operations the system in question performs. According to a preferred embodiment of the present invention, CO₂ may be collected from natural water by a subsystem according to the present invention. A subsystem according to the present invention comprises an inlet, an inlet pump, an outgassing vessel, a vacuum inlet connecting said vessel to a vacuum, a vacuum fitted to said outgassing vessel, a second vessel or chamber for gas collection, an outflow pump for causing processed water to flow out of said outgassing vessel for discharge, and an outlet. Such a subsystem operates by flowing or pumping water through an inlet into said outgassing vessel, causing reduced gas pressure in said outgassing vessel by means of said vacuum, collecting gas output by said vacuum to said second vessel, and pumping water out of said outgassing vessel; operation may be via continuous flow or in cycles comprising foregoing steps. Water is discharged, e.g. by a discharge pump having an inlet from said outgassing vessel and an outflow at a distance from said inlet to avoid reprocessing the much of the same water. Preferably, water may be sprayed into said outgassing vessel (e.g. by means of one or more nozzles fitted at inflows into an outgassing vessel or compartment with said vessel or compartment held at reduced pressure (e.g. by vacuum pumping means) such that a high surface-to-volume ratio facilitates more rapid outgassing. In this case, a vacuum inlets from said closed chamber are either situated in a region of said closed vessel where droplets are minimal, or comprise bends and drains and preferably cooling means for collecting any water droplets or vapor taken in. Note that flow rates and operating pressures may be varied over large ranges and should be optimized experimentally for any given system or subsystem design, including according to factors such as desired rate and desired yield of CO₂ collected versus energy requirements. Alternatively to the foregoing, U.S. Pat. No. 5,207,875 discloses a method for removing dissolved gases from water which may be performed by a subsystem of the present invention designed accordingly to implement this method, although in the present case the feature of recycling gases for formation of bubbles is undesirable and should be omitted. Note that removing CO₂ from seawater, particularly from the top kilometer of the ocean, may serve to counter acidification which threatens the dissolution of calcium-carbonate containing organisms and also release of more CO₂ into the atmosphere.

Additionally, use of nanoporous amine-modified filter membranes comprising pores on the order of 300 pm in diameter to filter gases removed from an input water stream according to the foregoing may further purify CO₂ from other gases, in analogy to amine-based CO₂ sorbents. Similarly, as a distinct embodiment, any input gases to any subsystems for CO₂ processing disclosed herein may comprise nanoporous amine-modified filter membranes for filtering an input gas stream, preferably, said nanoporous amine-modified filter membranes being fabricated or assembled according to the present invention, most preferably by the system of which said subsystem is a part or by a system according to the present invention which fabricated and assembled said subsystem.

### Self- or Allo-Replicating Systems Comprising Modifications or Means for Limiting Replication or Growth:

Although very likely overestimated, concerns regarding uncontrolled self-replication (most of which are base on the erroneous assumption that something like mutation and evolution would necessarily apply because replication occurs and might lead to loss of control over such systems,) greater market acceptance of such technology might be gained and reduced public concern provoked, particularly in this application, by various means which preclude unlimited replication, however unlikely it might in any event be for the present systems. For self-growing systems, a system may comprise a structure of beams with tracks situated therebetween and fabrication units sliding along said tracks, said fabrication units designed only to be able to fabricate structures from one face thereof, and sliding along said track in the course of fabrication. Once the fabrication unit reaches the end of the track which is constrained to slide upon or around, further motion is impeded by the second beam suspending said track. By this point, the assembly unit becomes inoperative because it is constrained on the track between the workpiece it has fabricated and said second beam. This class of mechanisms may be termed self-arresting fabrication or self-arresting assembly, and it is pointed out explicitly here that self-arrest may be used to limit both assembly and fabrication devices or systems. The foregoing example represents a severe case where strong materials effectively seize a moving part, a situation which, for devices not designed for disassembly, would prove intractable short of atomic disassembly or other operations which would destroy a properly designed system. If reusability of such systems is desired, such a system is designed instead to require human intervention or the intervention of some distinct autonomous agent (e.g. a robotic device) for removal of the fabricated workpiece (or translation of a beam and the fabrication unit,) if removal of the fabricated workpiece is even possible, then even if the workpiece in question comprised a plurality of identical or distinct fabrication units (similar to or different from the fabrication unit which fabricated them) replication remains completely limited by the action of human intervention or said autonomous agent (and even if one imagines an autonomous agent in an error state or of defective manufacture which wildly promotes the replication of fabrication units, if the autonomous agent does not itself replicate and if the fabrication unit is unable to fabricate agents with similar functionality, e.g. due to lack of a program for doing so or due to physical constraints, then even in the confabulated scenarios of a pro-replicative error condition of said autonomous agent, or of a defective autonomous agent, uncontrolled replication is limited by the capacity of this exceptional case, so is unlikely to lead to catastrophic consequences. Although this might be somewhat pedantic, the point is that it represents a case which is easily communicated and understood, which may be important for acceptance of a technology which enables the comparatively straightforward solutions of vital problems such as global warming, global poverty, threat of pandemic disease, etc.

More generally, replication of systems according to the present invention may, in a preferred embodiment, be limited in their replication by design such that a physical operation of which the self- or allo-replicating system or self-growing system is incapable of completing a replication cycle or growth phase or alternatively to enable any subsequent round of replication or phase of growth, where said physical operation is provided or not provided by and according to a decision of some independent agent or agency.

### REFERENCES

[Abe97] G. C. Abeln; et al.; 1997. Appl. Phys. Lett. 70(20):2747.
[Afz04] Afzali-Ardakani, A.; Kagan, C. R.; Murray, C. B.; Sep. 23, 2004; filed Mar. 21, 2003. “Solution processed pentacene-acceptor heterojunctions in diodes, photodiodes, and photovoltaic cells and methods of making same,” U.S. Patent Application Publication No. US 2004/0183070 A1
[Afz06] Afzali-Ardakani, A.; Kagan, C. R.; Murray, C. B.; Feb. 16, 2006; filed Oct. 22, 2004. “Solution processed pentacene-acceptor heterojunctions in diodes, photodiodes, and photovoltaic cells and methods of making same,” U.S. Patent Application Publication No. US 2006/0032530 A1

[AHD00] The American Heritage® Dictionary of the English Language, Fourth Edition; 2000. Houghton Mifflin Company. http://dictionary.reference.com/browse/adducted

[All05] Allis, D. G.; Drexler K. E.; 2005. Journal of Computational and Theoretical Nanoscience 2, 45-55.
[And62] Anderson, J. E.; 1962. “Arc Torch Chemical Reactions,” U.S. Pat. No. 3,051,639, filed on Sep. 25, 1958. See especially Example VIII therein.
[Ave82] Avenati, M.; Pilet, O.; Carrupt, P.-A.; Vogel, P.; 1982. Helv. Chim. Acta, 65:178-187.
[Bie80] (a.) Biermann D.; Schmidt W.; 1980. JACS 102:3163. (b.) Biermann D.; Schmidt W.; 1980. JACS 102:3173.
[Bil03] Ante Bilic', Jeffrey R. Reimers, Noel S. Hush; 2003. JOURNAL OF CHEMICAL PHYSICS 119(28):1115.
[Bob01] Bobrov, K.; Mayne, A. J.; Dujardin, G.; 2001. Nature 413:616-619.
[Bur02] Buriak J. M.; 2002. Chemical Reviews 102:1271.
[Cat01] Alessandra Catellani, Giulia Galli; 2001. Diamond and Related Materials 10:1259-1263.
[Cli63] Clifford, A. A.; Waters, W. A.; 1963. Journal of the Chemical Society (London) 1963:3056-3062.
[Col97] (a.) Collins, C. M.; 1997. “Self reproducing fundamental fabricating machines (F-Units),” U.S. Pat. No. 5,659,477. (b.) Collins, C. M.; 1997. “Self reproducing fundamental fabricating machine system,” U.S. Pat. No. 5,764,518.
[Cor87] Kevin M. Welsh, Joyce Y. Corey; 1987. Organometallics 6:1393-1398.

[Cos05] Francesca Costanzo, Pier Luigi Silvestrelli, and Francesco Ancilotto; 2005. J. Phys. Chem. B 109:819-824.
[Den04] Wei-Qiao Deng and William A. Goddard III; 2004. J. Phys. Chem. B, 108:8614-8621
[Der01] V. Derycke, P. Fonteneau, N. P. Pham, and P. Soukiassian; 2001. PHYSICAL REVIEW B 63:201305(R).
[Dew85+] AM1 Method: Dewar, M. J. S., et al.; 1985. J. Am. Chem. Soc. 107:3902; AM1 Parameters:
C, H, N, O: Dewar, M. J. S., et al.; 1985. J. Am. Chem. Soc. 107:3902;
Si: Dewar, M. J. S., Jie, C.; 1987. Organometallics 6: 1486-1490.
[Die03] Dietrich-Buchecker, C.; Jimenez-Molero, M. C.; Sartor, V.; Sauvage, J.-P.; 2003. Pure Appl. Chem. 75:1383.
[Dre91] Drexler, K. E.; 1991. J. Vac. Sci. Technol. B 9:1394.
[Dre92] Drexler K. E.; Nanosystems: Molecular Machinery, Manufacturing, and Computation, John Wiley & Sons, New York (1992).
[Dys01] Jeffrey M. Dysard, T. Don Tilley, Tom K. Woo; 2001. Organometallics 20:1195-1203.
[Eki04] E. A. Ekimov et al. Nature, 428, 542 (2004).
[Fan06] Fan, L.-S.; Gupta, H.; Feb. 23, 2006; filed Feb. 6, 2003. “Separation of Carbon Dioxide (CO2) from Gas Mixtures by Calcium Based Reaction Separation (CARS-CO2) Process.” U.S. Patent Application Pub. No. US 2006/0039853 A1
[Fre04] http://www.molecularassembler.com/Papers/PathDiamMolMfg.htm#FreitasProcess
[Fre04b] Robert A. Freitas Jr., “A Simple Tool for Positional Diamond Mechanosynthesis, and its Method of Manufacture,” U.S. Provisional Patent Application No. 60/543,802, filed 11 Feb. 2004; U.S. Patent Pending, 11 Feb. 2005. Permanent URL: http://www.MolecularAssembler.com/Papers/DMSToolbuildProvPat.htm
[Gab80] Raphy Gabioud and Pierre Vogel; 1980. Tetrahedron 36:149-154.
[Gra04] PC-GAMESS: (a) A. A. Granovsky, http://classic.chem.msu.su/gran/gamess/index.html (b) A. V. Nemukhin, B. L. Grigorenko, A. A. Granovsky; 2004. “Molecular modeling by using the PC GAMESS program: From diatomic molecules to enzymes,” Moscow University Chemistry Bulletin 45(2):75.
[Hag93] Hagedorn, N. H.; 1993. “Alkali Metal Carbon Dioxide Electrochemical System for Energy Storage and/or Conversion of Carbon Dioxide to Oxygen,” U.S. Pat. No. 5,213,908, filed Sep. 26, 1991.
[Hal80] Halmann, M. M.; 1980. “Photosynthetic Process,” U.S. Pat. No. 4,219,392.
[Her02] M C Hersam, N P Guisinger and J W Lyding; 2000. Nanotechnology 11:70-76.
[Hov97] J. S. Hovis, S. Lee, Ho. Liu, and R. J. Hamers; 1997. J. Vac. Sci. Technol. B15(4):1153.
[Hua04] Huang, H. G.; Lu, X.; Xiang, C. L.; Teo, T. L.; Lai, Y. H.; Xu, G. Q.; 2004. Chem. Phys. Lett. 398:11; see also reference 9 therein.
[Hub00] Hubin, T. J.; Busch, D. H.; 2000. Coordination Chemistry Reviews 200-202:5.
[Hug02] Greg Hughes; et al.; 2002. J. Vac. Sci. Technol. B 20(4):1620.
[Iba04] Ibanez, Jorge G.; March, 2004. “ENVIRONMENTAL ELECTROCHEMISTRY”, Electrochemistry Encyclopedia (http://electrochem.cwru.edu/ed/encycl/)
[JJPSte90] MOPAC 6: J. P. Stewart; 1990. J. Computer-Aided Molecular Design 4:1-105.
[Kin07] Kinjo, R.; 2007. “Studies on Chemistry of Silicon-Silicon Triple Bond Species: Synthesis, Characterization, and Reactivity,” Dissertation, University of Tsukuba.
[Kon00] Maynard J. Kong; et al.; 2000. J. Phys. Chem. B 2000, 104, 3000-3007.
[Lac95] Lackner, K. S.; Wendt, C. H.; 1995. Comput. Modelling 21:55.
[Leh82] LEHN, JEAN-MARIE, ZIESSEL, RAYMOND; 1982. Proc. Natl. Acad. Sci. USA 79:701-704.
[Lu04] Lu, X.; Zhu, M.; Wang, X.; Zhang Q.; 2004. J. Phys. Chem. B 108:4478.
[Lyd98] J. W. Lyding; et al.; 1998. Applied Surface Science 130-132:221-230.
[Man04] D. J. Mann, J. Peng, R. A. Freitas Jr., and R. C. Merkle, J. Comput. Theor. Nanosci. 1, 71 (2004).
[Mar98] Martin, R. E.; 1998. “Monodisperse Poly(triacetylene) Oligomers—Synthesis, Characterization, and Investigation of their Physical Properties as a Function of Chain-Length and Functionalization,” A dissertation submitted to the SWISS FEDERAL INSTITUTE OF TECHNOLOGY ZURICH, Diss. ETH No. 12821.
[McC84] William Z. McCarthy, Joyce Y. Corey and Eugene R. Corey; 1984. Organometallics 3:255-263.
[Mer97] Merkle, R. C.; 1997. “A proposed ‘metabolism’ for a hydrocarbon assembler.” Nanotechnology 8:149-162.
[Mer03] R. C. Merkle and R. A. Freitas Jr.; 2003. J. Nanosci. Nanotechnol. 3:319.
[Mid93] M. Mark Midland; et al.; 1993. Organic Syntheses, Coll. 8:391. (http://www.orgsyn.org)
[Min06] Mineva, T.; Nathaniel, R.; Kostov, K. L.; Widdraa, W.; 2006. J. Chem. Phys. 125:194712.
[Mon03] F. Montilla, E. Morallo'n, I. Duo, Ch. Comninellis, J. L. Va'zquez; 2003. Electrochimica Acta 48:3891-3897.
[Mos01] Moses, M.; 2001. “A PHYSICAL PROTOTYPE OF A SELF-REPLICATING UNIVERSAL CONSTRUCTOR,” Thesis, University of New Mexico. http://home.earthlink.net/˜mmoses152/SelfRep.doc
[Mul02] Muller, C.; Lachicotte, R. J.; Jones, W. D.; 2002. Organometallics 21:1975.
[Nar79] Narbel, Ph.; et al.; 1979. Inorg. Chim. Acta, 36:161.
[Nas05] A. G. Nasibulin; et al.; 2005. Chemical Physics Letters 417:179-184.
[Oka04] K. Okamura Y. Hosoi, Y. Kimuraa, H. Ishii, M. Niwano; 2004. Applied Surface Science, 237:439-443.
[Oba01] M. Oba, Y. Watanabe, K. Iwai, H. Ohtaki, K. Nishiyama; 2001. Journal of Organometallic Chemistry 629:44-46.
[Ope] http://www.opencores.org/
[Pay04] M. M. Payne, S. A. Odom, S. R. Parkin, and J. E. Anthony; 2004. ORGANIC LETTERS 6(19):3325-3328.
[Pen04] Peng, J.; Freitas, R. A. Jr.; Merkle, R. C.; 2004. Journal of Computational and Theoretical Nanoscience 1:62-70.
[Pen06] J. Peng; et al.; 2006. Journal of Computational and Theoretical Nanoscience 3:28-41.
[Rab97] Rabani, E. M.; 1997. WO 97/006468.
[Rai07] Rainbolt J. E.; Miller G. P.; 2007. J. Org. Chem. 72:3020.
[Rus05] M. Rusopa; et al.; 2005. Solar Energy 78:406-415.
[San00] Sanji, T.; Kawabata, K.; Sakurai, H.; 2000. Journal of Organometallic Chemistry 611:32.
[Sch93] GAMESS: M. W. Schmidt; et al.; 1993. J. Comput. Chem. 14:1347-1363.
[Scho00] J. H. Schon, Ch. Kloc, and B. Batlogg; 2000. APPLIED PHYSICS LETTERS 77:2473-2475.
[Sey61] Seyferth, D.; Weiner, M.; 1961. JACS 83:3583.
[Sri95] Sridhar, K. R.; Vaniman, B. T.; 1995 SAE TECHNICAL PAPER SERIES 951737
[Sta02] S. A. Grabovskii; et al.; 2002. Organometallics 21:3506-3510.
[Ste00] M. Sternberg, M. Kaukonen, R. M. Nieminen, Th. Frauenheim; 2000. arxiv/cond-mat:0010096vl 5 Oct. 2000.
[Tem06] Berhane Temelso; et al.; 2006. J. Phys. Chem. A 110:11160-11173.
[Wei06] Wei, S.; 2006. “A FPGA-based Soft Multiprocessor System for JPEG Compression,” via http://www.opencores.org
[Wu98] Wu P-H.; Lin D.-S.; 1998. Phys. Rev. B 57:12421.
[Wur06] Frank Wurthner and Rudiger Schmidt; 2003. Chem Phys Chem 7:793-797.
[Zyk05] Zykov, V.; Mytilinaios, E.; Adams, B.; Lipson, H.; 2005. “Self-reproducing machines”, Nature 435:163.

Note that any other methods or means enabling positional mechanosynthetic fabrication or assembly may serve in the fabrication and/or assembly of the many devices, subsystems and systems embodying aspects of the present invention disclosed herein, including those for the transformation of matter, and thus such devices, subsystems or systems according to embodiments disclosed herein fabricated or assembled by any other methods or means for positional mechanosynthetic fabrication or assembly including those as yet unknown, and corresponding applications thereof, fall fully within the scope of the present invention.

All citations, and teachings therein, are incorporated herein by reference, particularly teachings disclosed therein necessary or useful for forming precursors or intermediates used in the present invention and associated techniques therefor. Specific embodiments detailed are described for illustration rather than limitation. The appended claims will be understood to comprehend any equivalents, including those not presently known in the relevant arts where these may be operatively substituted. The present invention is limited only by the breadth of the appended claims.

1. A method for fabrication of materials, objects, devices, subsystems or systems comprising the steps of providing a first support, a platform moiety which may be in reactant loaded or reactant unloaded form, a reactant, a workpiece, and positioning means, said positioning means being operatively coupled to said first support; forming an adduct of said platform moiety to said first support, contacting said reactant to atoms of said platform moiety if said platform moiety is in reactant unloaded form, contacting atoms of said reactant with a target site on said workpiece and withdrawing said adduct of said platform moiety with said first support from said workpiece.

2. A device implementing the method of claim 1 comprising information processing and storage means for executing a program for controlling fabrication.

3. A method for manipulation of workpieces into assemblies, comprising the steps of providing a first support, a platform moiety which may be in reactant loaded or reactant unloaded form, a second support, a first workpiece and positioning means, said positioning means being operatively coupled to at least one of said first and said second supports; forming an adduct of said platform moiety to said first support, contacting atoms of said platform moiety with a target site on said workpiece to form at least a bond, and translating said first support to cause translation or rotation of said workpiece.

4. A method for assembly of workpieces into assemblies according to claim 3 additionally comprising the steps of providing a second workpiece, positioning said first workpiece in a desired location relative to said first workpiece, causing a transformation effecting weakening of said bond between said platform moiety and said workpiece, and withdrawing said first support from said first workpiece.

5. A system comprising one or more components fabricated by positional mechanosynthesis or assembled by nanomanipulation for causing one or more physical or chemical transformation of matter, wherein said positional mechanosynthesis or said nanomanipulation is performed by a device according to claim 2.

6. A system according to claim 5 where said matter comprises material selected from the group consisting of: one or more raw materials, one or more pollutants.

7. A system according to claim 5 where said pollutant is selected from the group consisting of: carbon dioxide, ozone, metals, chemical wastes.

8. A system according to claim 5 where said matter is selected from: carbon dioxide, ozone, ultrafine particulates, nanoparticulates, one or more metals, one or more ores, one or more minerals, one or more chemical wastes, a material comprising carbon atoms, a material comprising silicon atoms, silicates.

9. A system according to claim 5 where said transformation is selected from the group consisting of: separation, filtration, heating, cooling, evaporation, vaporizing, degassing, melting a solid or glass, solidifying a liquid, liquefying a gas, subliming a gas, crystallization, chemical reaction, an arc reaction, one or more catalyzed chemical reactions, one or more chemical reactions catalyzed by a metal or metal particle, a metal oxide or metal oxide particle, or complex comprising a metal, one or more electrochemical reaction, one or more chemical reactions caused by actinic radiation, one or more photoassisted chemical or electrochemical or electrocatalyzed reaction.

10. An actuator device fabricated according to claim 4 comprising at least two conductive, semiconductive or superconductive regions and an actuation member.

11. A method for fabrication of materials, objects, devices, subsystems or systems comprising the steps of providing a first support comprising a material capable of binding a reactant at a location from which passivating atoms or groups, if any are associated therewith, have been removed to form a reactant binding site, wherein in reactant unbound form the structure of a reactant binding site is identical to the bulk structure of said material or of an ordinary surface reconstruction thereof, said material being provided in reactant-loaded or reactant-unloaded form, a reactant, a workpiece, and positioning means, said positioning means being operatively coupled to said first support; contacting said reactant to atoms of said material if said first support is in reactant unloaded form, contacting atoms of said reactant with a target site on said workpiece and withdrawing said support from said workpiece.

12. A method according to claim 11 where said material is selected from the group consisting of: beta-SiC, carbide materials, binary materials, metals including main-group metals and transition metals, transition-metal carbides, transition-metal nitrides, transition-metal oxides, transition-metal sulfides, transition-metal tellurides, metal carbides, metal nitrides, metal oxides, metal sulfides, metal tellurides, halite or B1 structured materials, ionic materials, materials comprising compounds said compound comprising titanium, zirconium, tantalum, vanadium, chromium, cobalt, rhodium, rhenium, iridium, platinum, palladium, silver, nickel, copper and zinc.

13. A device implementing the method of claim 1 comprising a platform moiety or addition tool the structure of which comprises a ring comprising at least one atom for binding to a reactant and at least one atom of said ring is bonded to an atom outside of said ring via a partially or fully unsaturated bond.

14. A photovoltaic device comprising at least one component or material produced by positional mechanosynthesis according to the method of claim 1.

15. A method for fabrication according to claim 1 where said fabrication is conducted in the presence of water or in pure water or in aqueous solution.

16. A device implementing the method of claim 1 comprising one or more feed chains for delivering a reactant or reactant fragment or reactant precursor or a reagent to a tool for performing a mechanosynthetic operation.

17. A device according to claim 16 where at least one of said one or more feed chains is selected from the group consisting of: [n]rotaxanes; [n]catenanes; polycatenanes; polyrotaxanes; oligocatenanes; oligorotaxanes; oligomers; polymers; mechanically linked chains.

18. A system according to claim 5 where said component is of a composition different from said matter.

19. A system according to claim 5 further comprising energy collection means.

20. A system according to claim 19 where said energy collection means is selected from:
photovoltaic devices, a heat engine heated by means for concentrating solar radiation, a heat engine heated by means for concentrating solar radiation driving an electrical generator; a pneumatic system utilizing gas expansion caused by solar radiation concentrated by concentrating means; wind energy collection means; wind energy collection means driving an electrical generator.
